(19) United States
(12) Patent Application Publication
(10) Pub. No.: US 2026/0206317 A1
(43) Pub. Date: Jul. 16, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Yukinori SHIMA, Tatebayashi, Gunma (JP); Masayoshi DOBASHI, Shimotsuga, Tochigi (JP); Marie MATSUMOTO, Kanuma, Tochigi (JP); Rai SATO, Tochigi, Tochigi (JP); Junichi KOEZUKA, Tochigi, Tochigi (JP); Masami JINTYOU, Shimotsuga, Tochigi (JP)

(21) Appl. No.: 19/134,800

(22) PCT Filed: Dec. 18, 2023
(86) PCT No.: PCT/IB2023/062851

§ 371 Date: Jun. 2, 2025

(30) Foreign Application Priority Data
Dec. 23, 2022 (JP) 2022-206895

(51) Int. Cl. H10D 86/40; H10D 30/01; H10D 30/67; H10D 86/01; H10D 86/60; H10H 29/32; H10K 59/121

(52) U.S. Cl. CPC H10D 86/471; H10D 30/6728; H10D 30/6731; H10D 30/6734; H10D 30/6736; H10D 30/6757; H10D 86/421; H10D 86/431; H10D 30/0312; H10D 30/0318; H10D 86/0231; H10D 86/60; H10H 29/32; H10K 59/1213

(57) ABSTRACT

A transistor having a minute size is provided. A semiconductor device includes a semiconductor layer, a first conductive layer, a second conductive layer, a third conductive layer, a first insulating layer, and a second insulating layer. At least one of the first conductive layer and the second conductive layer includes two conductive layers containing different metals from each other; the upper one of the two conductive layers covers at least part of a top surface of the lower conductive layer and at least part of a side surface of the lower conductive layer. The first insulating layer is positioned over the first conductive layer. The second conductive layer is positioned over the first insulating layer. The semiconductor layer is in contact with a top surface of the first conductive layer, a top surface and a side surface of the second conductive layer, and a side surface of the first insulating layer. The second insulating layer is positioned over the semiconductor layer. The third conductive layer is positioned over the second insulating layer and overlaps with the semiconductor layer with the second insulating layer therebetween.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic devices. In a display device, for example, when transistors occupy smaller areas, the pixel size can be smaller and higher definition can be achieved. Therefore, miniaturization of transistors has been required.

As devices requiring high-definition display devices, for example, devices for virtual reality (VR), augmented reality (AR), substitutional reality (SR), and mixed reality (MR) have been actively developed.

As display devices, for example, light-emitting apparatuses that include organic EL (Electro Luminescence) elements or light-emitting diodes (LEDs) have been developed.

Patent Document 1 discloses a high-definition display device using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a transistor having a minute size. Another object is to provide a transistor having a short channel length. Another object is to provide a transistor having a high on-state current. Another object is to provide a transistor having favorable electrical characteristics. Another object is to provide a semiconductor device that occupies a small area. Another object is to provide a semiconductor device having low wiring resistance. Another object is to provide a semiconductor device or a display device having low power consumption. Another object is to provide a transistor, a semiconductor device, or a display device having high reliability. Another object is to provide a display device that can easily achieve higher definition. Another object is to provide a method for manufacturing a semiconductor device or a display device having high productivity. Another object is to provide a novel transistor, a novel semiconductor device, a novel display device, and manufacturing methods thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a semiconductor layer, a first conductive layer, a second conductive layer, a third conductive layer, a first insulating layer, and a second insulating layer; the first insulating layer is positioned over the first conductive layer, the second conductive layer is positioned over the first insulating layer; the second conductive layer includes a fourth conductive layer and a fifth conductive layer; the fourth conductive layer and the fifth conductive layer include different metals from each other; the fifth conductive layer covers at least part of a top surface of the fourth conductive layer and at least part of a side surface of the fourth conductive layer; the semiconductor layer is in contact with a top surface of the first conductive layer, a top surface and a side surface of the fifth conductive layer, and a side surface of the first insulating layer; the second insulating layer is positioned over the semiconductor layer; and the third conductive layer is positioned over the second insulating layer and overlaps with the semiconductor layer with the second insulating layer therebetween.

One embodiment of the present invention is a semiconductor device including a semiconductor layer, a first conductive layer, a second conductive layer, a third conductive layer, a first insulating layer, and a second insulating layer; the first insulating layer is positioned over the first conductive layer and includes a first opening; the second conductive layer is positioned over the first insulating layer and includes a second opening overlapping with the first opening; the second conductive layer includes a fourth conductive layer and a fifth conductive layer; the fourth conductive layer and the fifth conductive layer include different metals from each other; the fifth conductive layer covers at least part of a top surface of the fourth conductive layer and at least part of a side surface of the fourth conductive layer; the semiconductor layer is in contact with a top surface of the first conductive layer via the first opening and the second opening and is in contact with each of a top surface of the fifth conductive layer, a side surface of the fifth conductive layer in the second opening, and a side surface of the first insulating layer in the first opening; the second insulating layer is positioned over the semiconductor layer; and the third conductive layer is positioned over the second insulating layer and overlaps with the semiconductor layer with the second insulating layer therebetween.

The fourth conductive layer may include a third opening. In this case, the fifth conductive layer preferably includes the second opening inside the third opening in a top view.

It is preferable that the first conductive layer include a sixth conductive layer and a seventh conductive layer, that the sixth conductive layer and the seventh conductive layer include different metals from each other, and that the seventh conductive layer cover at least part of a top surface of the sixth conductive layer and at least part of a side surface of the sixth conductive layer.

It is preferable that the semiconductor layer include a metal oxide in a channel formation region, that the fifth conductive layer include a first oxide conductor layer, that the seventh conductive layer include a second oxide conductor layer, and that the semiconductor layer be in contact with the first oxide conductor layer and the second oxide conductor layer.

It is preferable that conductivity of the fourth conductive layer be higher than conductivity of the fifth conductive layer and that conductivity of the sixth conductive layer be higher than conductivity of the seventh conductive layer.

It is preferable that the first conductive layer include an eighth conductive layer, that the sixth conductive layer be positioned over the eighth conductive layer, and that the seventh conductive layer and the eighth conductive layer be in contact with each other outside an end portion of the sixth conductive layer.

It is preferable that the second conductive layer include a ninth conductive layer, that the fourth conductive layer be positioned over the ninth conductive layer, and that the fifth conductive layer and the ninth conductive layer be in contact with each other outside an end portion of the fourth conductive layer.

It is preferable that the fifth conductive layer include a first metal layer and a first metal oxide layer over the first metal layer, that the first metal layer and the first metal oxide layer include the same metal, that the first metal layer be electrically connected to the semiconductor layer through the first metal oxide layer, that the seventh conductive layer include a second metal layer and a second metal oxide layer over the second metal layer, that the second metal layer and the second metal oxide layer include the same metal, and that the second metal layer be electrically connected to the semiconductor layer through the second metal oxide layer.

It is preferable that the sixth conductive layer include an eighth conductive layer and a ninth conductive layer over the eighth conductive layer and that a top-view shape of the eighth conductive layer be the same or substantially the same as a top-view shape of the ninth conductive layer.

It is preferable that the fourth conductive layer include a tenth conductive layer and an eleventh conductive layer over the tenth conductive layer and that a top-view shape of the eleventh conductive layer be the same or substantially the same as a top-view shape of the tenth conductive layer.

It is preferable that the first insulating layer include a first layer including nitrogen and silicon over the first conductive layer, a second layer including oxygen and silicon over the first layer, and a third layer including nitrogen and silicon over the second layer.

It is preferable that the first insulating layer include a fourth layer positioned between the first conductive layer and the first layer and a fifth layer over the third layer, that the fourth layer include a region having a higher hydrogen content than the first layer, and that the fifth layer include a region having a higher hydrogen content than the third layer.

### Effect of the Invention

With one embodiment of the present invention, a transistor having a minute size can be provided. A transistor having a short channel length can be provided. A transistor having a high on-state current can be provided. A transistor having favorable electrical characteristics can be provided. A semiconductor device that occupies a small area can be provided. A semiconductor device having low wiring resistance can be provided. A semiconductor device or a display device having low power consumption can be provided. A transistor, a semiconductor device, or a display device having high reliability can be provided. A display device that can easily achieve higher definition can be provided. A method for manufacturing a semiconductor device or a display device having high productivity can be provided. A novel transistor, a novel semiconductor device, a novel display device, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2A is a top view illustrating an example of a semiconductor device. FIG. 2B is a cross-sectional view illustrating the example of the semiconductor device.

FIG. 3A to FIG. 3C are cross-sectional views illustrating examples of a semiconductor device.

FIG. 4A and FIG. 4B are cross-sectional views illustrating an example of a semiconductor device.

FIG. 5A to FIG. 5C are cross-sectional views illustrating examples of a semiconductor device.

FIG. 6A to FIG. 6C are cross-sectional views illustrating examples of a semiconductor device.

FIG. 7A to FIG. 7C are cross-sectional views illustrating examples of a semiconductor device.

FIG. 8A and FIG. 8B are cross-sectional views illustrating an example of a semiconductor device.

FIG. 9A is a top view illustrating an example of a semiconductor device. FIG. 9B and FIG. 9C are cross-sectional views illustrating the example of the semiconductor device.

FIG. 10A is a top view illustrating an example of a semiconductor device. FIG. 10B and FIG. 10C are cross-sectional views illustrating the example of the semiconductor device.

FIG. 11A and FIG. 11B are cross-sectional views illustrating examples of a semiconductor device.

FIG. 12A is a cross-sectional view illustrating an example of a semiconductor device. FIG. 12B is a top view illustrating the example of the semiconductor device.

FIG. 13A to FIG. 13I are circuit diagrams illustrating examples of semiconductor devices.

FIG. 14A and FIG. 14B are cross-sectional views illustrating examples of a semiconductor device.

FIG. 15A is a top view illustrating an example of a semiconductor device. FIG. 15B is a cross-sectional view illustrating the example of the semiconductor device.

FIG. 16A is a top view illustrating an example of a semiconductor device. FIG. 16B is a cross-sectional view illustrating the example of the semiconductor device.

FIG. 17A is a top view illustrating an example of a semiconductor device. FIG. 17B is a cross-sectional view illustrating the example of the semiconductor device.

FIG. 18A is a top view illustrating an example of a semiconductor device. FIG. 18B is a cross-sectional view illustrating the example of the semiconductor device.

FIG. 19A to FIG. 19D are cross-sectional views illustrating an example of a method for manufacturing a semiconductor device.

FIG. 20A to FIG. 20C are cross-sectional views illustrating the example of the method for manufacturing the semiconductor device.

FIG. 21A and FIG. 21B are cross-sectional views illustrating the example of the method for manufacturing the semiconductor device.

FIG. 22 is a perspective view illustrating an example of a display device.

FIG. 23A and FIG. 23B are cross-sectional views illustrating examples of display devices.

FIG. 24 is a cross-sectional view illustrating an example of a display device.

FIG. 25A to FIG. 25C are cross-sectional views each illustrating an example of a display device.

FIG. 26A and FIG. 26B are cross-sectional views illustrating examples of display devices.

FIG. 27 is a cross-sectional view illustrating an example of a display device.

FIG. 28A to FIG. 28D are diagrams illustrating examples of electronic devices.

FIG. 29A to FIG. 29F are diagrams illustrating examples of electronic devices.

FIG. 30A to FIG. 30G are diagrams illustrating examples of electronic devices.

FIG. 31A to FIG. 31C are cross-sectional STEM images of samples in Example 1.

FIG. 32 is a graph showing Id-Vg characteristics and field-effect mobility of transistors in Example 1.

FIG. 33 is a graph showing Id-Vg characteristics and field-effect mobility of transistors in Example 1.

FIG. 34 is a graph showing Id-Vg characteristics and field-effect mobility of transistors in Example 1.

FIG. 35 is a graph showing Id-Vg characteristics and field-effect mobility of transistors in Example 2.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

A transistor is a kind of semiconductor element and can achieve a function of amplifying a current or a voltage, switching operation for controlling conduction or non-conduction, and the like. An IGFET (Insulated Gate Field Effect Transistor) and a thin film transistor (TFT) are in the category of a transistor in this specification.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

In this specification and the like, the expression “electrically connected” includes the case where components are connected to each other through an “object having any electric function”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

Unless otherwise specified, an off-state current in this specification and the like refers to a leakage current between a source and a drain generated when a transistor is in an off state (also referred to as a non-conducting state or a cutoff state). Unless otherwise specified, an off state in an n-channel transistor refers to a state where a voltage Vgs between its gate and source is lower than a threshold voltage Vₜₕ (in a p-channel transistor, higher than Vₜₕ).

In this specification and the like, “normally on” means a state where a channel exists without application of a voltage to a gate and a current flows through the transistor. Furthermore, “normally off” means a state where a current does not flow through a transistor when no potential or a ground potential is applied to a gate.

In this specification and the like, the expression “having substantially the same top-view shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top-view shapes are substantially the same”. In the case where top-view shapes are the same or substantially the same, it can be said that end portions are aligned with each other or substantially aligned with each other”.

In this specification and the like, a top-view shape of a component means the outline shape of the component in a plan view (also referred to as a top view). A plan view means that the component is observed from a normal direction of a surface where the component is formed or a surface of a support (e.g., a substrate) where the component is formed.

In this specification and the like, a tapered shape refers to such a shape that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is greater than 0 degree and less than 90 degrees. Note that the side surface, the substrate surface, and the formation surface of the component are not necessarily completely flat and may have a substantially planar shape with a small curvature or a substantially planar shape with slight unevenness.

Note that in this specification and the like, an oxynitride refers to a material that contains more oxygen than nitrogen in its composition. A nitride oxide refers to a material that contains more nitrogen than oxygen in its composition.

The content of hydrogen, oxygen, nitrogen, or any other element can be analyzed by secondary ion mass spectrometry (SIMS) or X-ray photoelectron spectroscopy (XPS). XPS is suitable when the content percentage of a target element is high (e.g., higher than or equal to 0.5 atomic %, or higher than or equal to 1 atomic %). By contrast, SIMS is suitable when the content percentage of a target element is low (e.g., lower than or equal to 0.5 atomic %, or lower than or equal to 1 atomic %). To compare the contents of elements, analysis with a combination of SIMS and XPS is preferably used.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A overlaps with B” is used, at least part of A overlaps with B. In other words, A includes a region overlapping with B, for example.

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

Note that in this specification and the like, step disconnection refers to a phenomenon in which a layer, a film, or an electrode is split because of the shape of the formation surface (e.g., a step).

### Embodiment 1

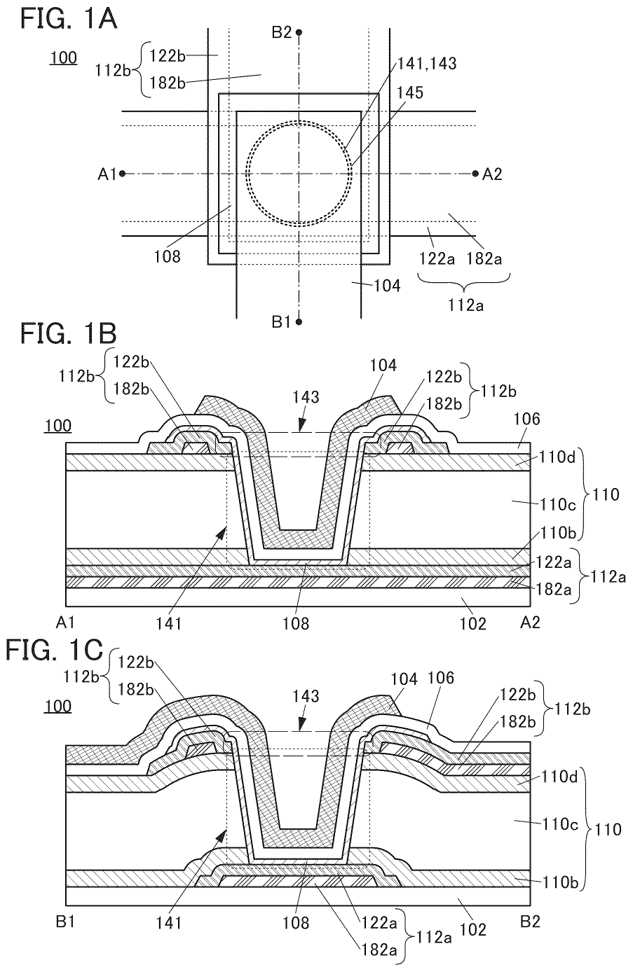

In this embodiment, a semiconductor device of one embodiment of the present invention will be described with reference to FIG. 1 to FIG. 18.

The semiconductor device of one embodiment of the present invention includes a semiconductor layer, a first conductive layer, a second conductive layer, a third conductive layer, a first insulating layer, and a second insulating layer.

The first insulating layer is positioned over the first conductive layer, and the second conductive layer is positioned over the first insulating layer. The oxide semiconductor layer is in contact with the top surface of the first conductive layer, the top surface and the side surface of the second conductive layer, and the side surface of the first insulating layer. The second insulating layer is positioned over the semiconductor layer. The third conductive layer is positioned over the second insulating layer and overlaps with the semiconductor layer with the second insulating layer therebetween.

The second insulating layer functions as a gate insulating layer. The third conductive layer functions as a gate electrode of the transistor.

The first insulating layer may include a first opening reaching the first conductive layer. The second conductive layer may include a second opening overlapping with the first opening. In that case, the third conductive layer preferably overlaps with the semiconductor layer with the second insulating layer therebetween at a position overlapping with the first opening and the second opening.

In the transistor of one embodiment of the present invention, the source electrode and the drain electrode are positioned at different levels, and a current flowing in the semiconductor layer flows in the height direction. In other words, the channel length direction includes a component of the height direction (vertical direction); accordingly, the transistor of one embodiment of the present invention can also be referred to as a VFET (Vertical Field Effect Transistor), a vertical transistor, a vertical-channel transistor, a vertical-channel-type transistor, or the like.

In the transistor of one embodiment of the present invention, the source electrode, the semiconductor layer, and the drain electrode can be provided to overlap with each other; thus, the area occupied by the transistor can be significantly smaller than the area occupied by what is called a planar transistor in which a semiconductor layer is provided in a planar shape.

The first conductive layer functions as one of the source electrode and the drain electrode of the transistor. The first conductive layer preferably includes a fourth conductive layer and a fifth conductive layer over the fourth conductive layer. The fourth conductive layer and the fifth conductive layer contain different metals from each other. The fifth conductive layer covers at least part of the top surface of the fourth conductive layer and at least part of the side surface of the fourth conductive layer. In this case, the semiconductor layer is preferably in contact with the top surface of the fifth conductive layer. There is continuity between the fourth conductive layer and the semiconductor layer through the fifth conductive layer. In other words, the fourth conductive layer is electrically connected to the semiconductor layer through the fifth conductive layer.

The second conductive layer functions as the other of the source electrode and the drain electrode of the transistor. The second conductive layer preferably includes a sixth conductive layer and a seventh conductive layer over the sixth conductive layer. The sixth conductive layer and the seventh conductive layer contain different metals from each other. The seventh conductive layer covers at least part of the top surface of the sixth conductive layer and at least part of the side surface of the sixth conductive layer. In this case, the semiconductor layer is preferably in contact with the top surface and the side surface of the seventh conductive layer. There is continuity between the sixth conductive layer and the semiconductor layer through the seventh conductive layer. In other words, the sixth conductive layer is electrically connected to the semiconductor layer through the seventh conductive layer.

The source electrode and the drain electrode each include a portion in contact with the semiconductor layer. In the case where a metal oxide is used for the semiconductor layer, for example, a conductive material that is not easily oxidized, a conductive material that maintains low electric resistance even after being oxidized, a conductive metal oxide (also referred to as an oxide conductor (OC)), or the like is preferably used for the portions of the source electrode and the drain electrode that are in contact with the semiconductor layer. Meanwhile, the source electrode or the drain electrode also functions as a wiring in some cases. Thus, a material having higher conductivity than an oxide conductor, such as a metal, an alloy, or a nitride thereof, is preferably used. Although copper is given as an example of a material that is low in resistance and suitable for a wiring and an electrode of the transistor, copper diffusion into the semiconductor layer might adversely affect the transistor characteristics.

Thus, in one embodiment of the present invention, at least one of the source electrode and the drain electrode has a stacked-layer structure of two or more layers in which the top surface and the side surface of a first layer are covered with a second layer. In the electrode, the uppermost layer in contact with the semiconductor layer is formed using a conductive material with low contact resistance with the semiconductor layer, and the conductive layer covered with the uppermost layer is formed using a material with high conductivity, whereby the transistor can have high reliability and a high on-state current.

Since the semiconductor layer is positioned over the first conductive layer and the second conductive layer, the transistor of one embodiment of the present invention can be regarded as a bottom-contact transistor. In manufacture of the transistor of one embodiment of the present invention, the semiconductor layer can be formed after the second conductive layer is formed (e.g., after a film to be the second conductive layer is processed or after the second opening is formed); thus, damage to the semiconductor layer can be inhibited. In addition, formation steps of the first opening and the second opening can be successively performed (with no film formation step or the like performed therebetween) and accordingly the openings can be easily formed, which is preferable.

Note that grooves (slits) may be provided instead of the first opening and the second opening.

### Transistor 100

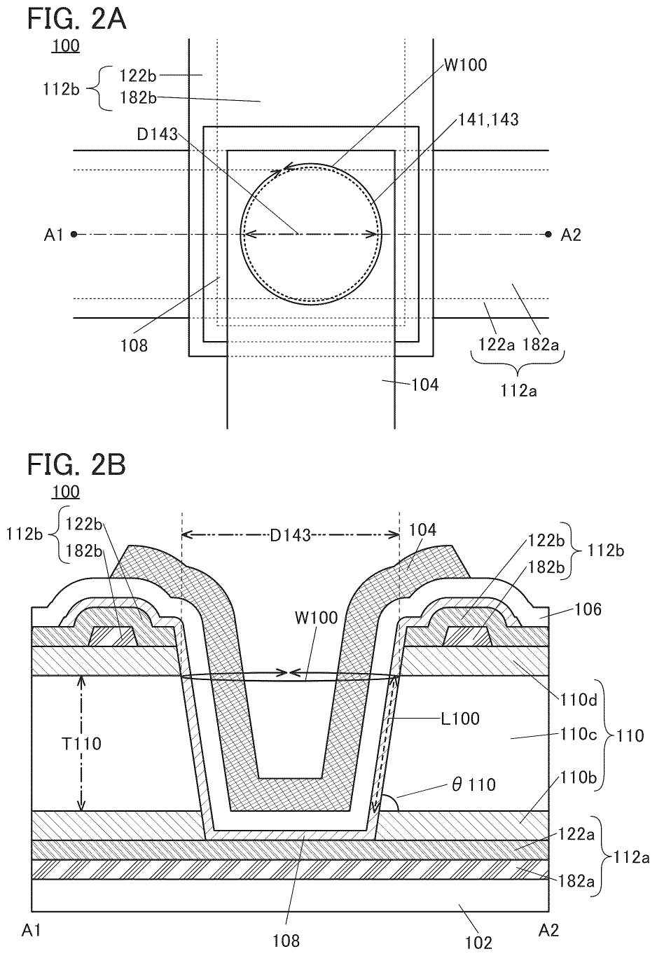

FIG. 1A and FIG. 2A are top views of a transistor 100. FIG. 2A is different from FIG. 1A in that a diameter D143 and a channel width W100 are illustrated and an opening 145 and dashed-dotted line B1-B2 are not illustrated. FIG. 1A and FIG. 2A omit illustration of insulating layers. Other top views also omit illustration of some components.

FIG. 1B and FIG. 2B are cross-sectional views along dashed-dotted lines A1-A2 in FIG. 1A and FIG. 2A, respectively. FIG. 2B may be regarded as an enlarged view of FIG. 1B. FIG. 1B illustrates openings 141, 143, and 145, and FIG. 2B illustrates the diameter D143, the channel width W100, a channel length L100, a thickness T110, and an angle 0110. The other components are common between FIG. 1B and FIG. 2B. FIG. 1C is a cross-sectional view along dashed-dotted line B1-B2 in FIG. 1A.

The transistor 100 is provided over a substrate 102. The transistor 100 includes a conductive layer 112a (a conductive layer 182a and a conductive layer 122a), an insulating layer 110 (an insulating layer 110b, an insulating layer 110c, and an insulating layer 110d), a semiconductor layer 108, a conductive layer 112b (a conductive layer 182b and a conductive layer 122b), an insulating layer 106, and a conductive layer 104. The layers constituting the transistor 100 may each have a single-layer structure or a stacked-layer structure. The insulating layer 110 is not necessarily regarded as a component of the transistor 100. In other words, the semiconductor device of one embodiment of the present invention can be regarded as including the transistor 100 and the insulating layer 110.

This embodiment is described mainly taking a case in which an oxide semiconductor is used for the semiconductor layer 108 as an example.

The conductive layer 112a is provided over the substrate 102. The conductive layer 112a functions as one of a source electrode and a drain electrode of the transistor 100. The conductive layer 112a includes the conductive layer 182a and the conductive layer 122a. As illustrated in FIG. 1C, the conductive layer 122a is provided to be in contact with the top surface and the side surface of the conductive layer 182a and to cover the top surface and the side surface thereof. The conductive layer 122a is in contact with the semiconductor layer 108.

The insulating layer 110 is positioned over the substrate 102 and the conductive layer 112a. The insulating layer 110 is in contact with the conductive layer 112a. The opening 141 reaching the conductive layer 112a is provided in the insulating layer 110.

The insulating layer 110 has a stacked-layer structure of the insulating layer 110b over the substrate 102 and the conductive layer 112a, the insulating layer 110c over the insulating layer 110b, and the insulating layer 110d over the insulating layer 110c.

The conductive layer 112b is positioned over the insulating layer 110. An opening 143 overlapping with the opening 141 is provided in the conductive layer 112b. The conductive layer 112b functions as the other of the source electrode and the drain electrode of the transistor 100. The conductive layer 112b includes the conductive layer 182b and the conductive layer 122b. As illustrated in FIG. 1B and FIG. 1C, the conductive layer 122b is provided in contact with the top surface and the side surface of the conductive layer 182b and to cover the top surface and the side surface thereof. The conductive layer 122b is in contact with the semiconductor layer 108. The conductive layer 182b includes the opening 145. In a top view, the opening 141 and the opening 143 are each positioned inside the opening 145 provided in the conductive layer 182b.

The semiconductor layer 108 is in contact with the top surface of the conductive layer 112a, the side surface of the insulating layer 110, and the top surface and the side surface of the conductive layer 112b. More specifically, the semiconductor layer 108 is in contact with the top surface of the conductive layer 122a, the side surface of the insulating layer 110, and the top surface and the side surface of the conductive layer 122b. The semiconductor layer 108 is provided in contact with an end portion of the insulating layer 110 on the opening 141 side (which can also be referred to as the side surface of the insulating layer 110 in the opening 141 or a sidewall of the opening 141) and an end portion of the conductive layer 112b on the opening 143 side (which can also be referred to as the side surface of the conductive layer 112b in the opening 143 or a sidewall of the opening 143). The semiconductor layer 108 is in contact with the conductive layer 112a via the opening 141 and the opening 143.

The insulating layer 106 is positioned over the insulating layer 110, the semiconductor layer 108, and the conductive layer 112b. The insulating layer 106 is provided along the sidewall of the opening 141 and the sidewall of the opening 143 with the semiconductor layer 108 between the insulating layer 106 and the side walls. The insulating layer 106 functions as a gate insulating layer (which can also be referred to as a first gate insulating layer) of the transistor 100.

The conductive layer 104 is positioned over the insulating layer 106. The conductive layer 104 overlaps with the semiconductor layer 108 with the insulating layer 106 therebetween, inside the opening 141 and the opening 143. The conductive layer 104 functions as a gate electrode (also referred to as a first gate electrode) of the transistor 100.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small semiconductor device.

When the semiconductor device of one embodiment of the present invention is used for a pixel circuit of a display device, the area occupied by the pixel circuit can be reduced and a high-resolution display device can be provided, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel, for example.

The channel length, channel width, and the like of the transistor 100 are described with reference to FIG. 2A and FIG. 2B.

In the semiconductor layer 108, a region in contact with the conductive layer 112a functions as one of a source region and a drain region, a region in contact with the conductive layer 112b functions as the other of the source region and the drain region, and a region between the source region and the drain region functions as a channel formation region.

In FIG. 2B, the channel length L100 of the transistor 100 is indicated by a dashed double-headed arrow. It can be said that in a cross-sectional view, the channel length L100 is the shortest distance between, in the semiconductor layer 108, a portion in contact with the insulating layer 110b and a portion in contact with the insulating layer 110d.

The channel length L100 of the transistor 100 corresponds to the length of the side surface of the insulating layer 110c on the opening 141 side in a cross-sectional view. In other words, the channel length L100 is determined by the thickness T110 of the insulating layer 110c and the angle θ110 formed by the side surface of the insulating layer 110c on the opening 141 side and the formation surface of the insulating layer 110c (the top surface of the insulating layer 110b here). Thus, for example, the channel length L100 can have a value smaller than that of the resolution limit of a light-exposure apparatus, which enables a transistor having a minute size. Specifically, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, a transistor with a channel length less than 10 nm can also be achieved without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

When the channel length L100 is short, the transistor 100 can have a high on-state current. With use of the transistor 100, a circuit capable of high-speed operation can be manufactured. Furthermore, the area occupied by the circuit can be reduced. Thus, a small semiconductor device can be obtained. The application of the semiconductor device of one embodiment of the present invention to a large display device or a high-resolution display device can reduce signal delay in wirings and reduce display unevenness even if the number of wirings is increased, for example. In addition, since the area occupied by the circuit can be reduced, the bezel of the display device can be narrowed.

The channel length L100 can be controlled by adjusting the thickness T110 of the insulating layer 110c and the angle θ110. Note that in FIG. 2B, the thickness T110 of the insulating layer 110c is indicated by the dashed-dotted double-headed arrow.

The thickness T110 of the insulating layer 110c can be, for example, greater than or equal to 10 nm, greater than or equal to 50 nm, greater than or equal to 100 nm, greater than or equal to 150 nm, greater than or equal to 200 nm, greater than or equal to 300 nm, greater than or equal to 400 nm, or greater than or equal to 500 nm and less than 3.0 μm, less than or equal to 2.5 μm, less than or equal to 2.0 μm, less than or equal to 1.5 μm, less than or equal to 1.2 μm, or less than or equal to 1.0 μm.

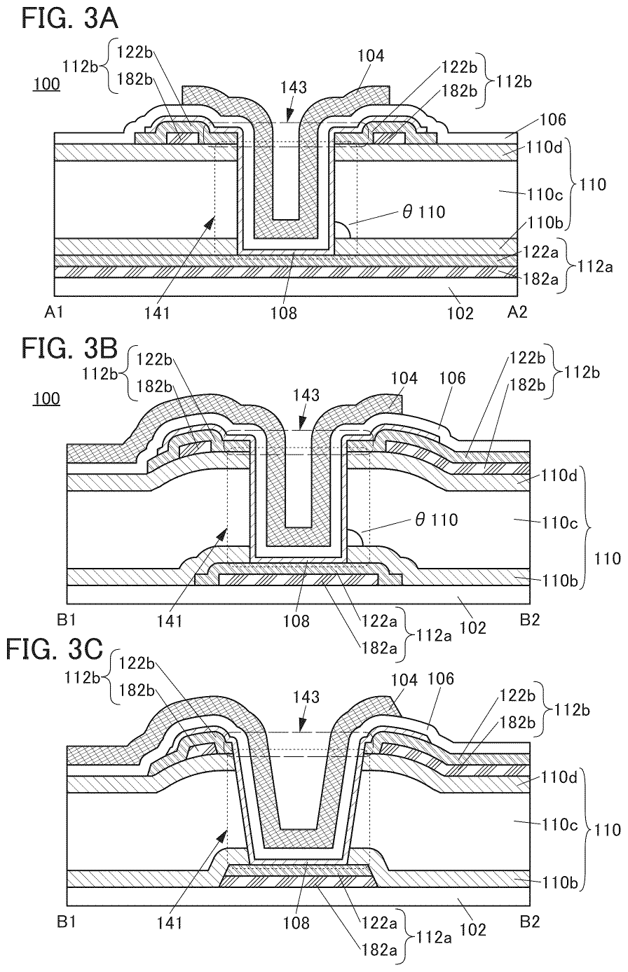

The side surface of the insulating layer 110c on the opening 141 side preferably has a vertical shape or a tapered shape. The angle θ110 formed between the side surface of the insulating layer 110c on the opening 141 side and the formation surface of the insulating layer 110c (here, the top surface of the insulating layer 110b) is preferably less than or equal to 90 degrees. When the angle θ110 is small, the coverage with a layer provided over the insulating layer 110c (e.g., the semiconductor layer 108) can be increased. The smaller the angle θ110 is, the longer the channel length L100 can be, and the larger the angle θ110 is, the shorter the channel length L100 can be. FIG. 1B, FIG. 1C, and FIG. 2B illustrate an example in which the side surface of the insulating layer 110c on the opening 141 side has a tapered shape (the angle θ110 is less than 90 degrees). FIG. 3A and FIG. 3B illustrates an example in which the side surface of the insulating layer 110c on the opening 141 side has a vertical shape (the angle θ110 is 90 degrees).

The angle θ110 can be, for example, greater than or equal to 30 degrees, greater than or equal to 35 degrees, greater than or equal to 40 degrees, greater than or equal to 45 degrees, greater than or equal to 50 degrees, greater than or equal to 55 degrees, greater than or equal to 60 degrees, greater than or equal to 65 degrees, or greater than or equal to 70 degrees and less than or equal to 90 degrees, less than or equal to 85 degrees, or less than or equal to 80 degrees. The angle θ110 may be less than or equal to 75 degrees, less than or equal to 70 degrees, less than or equal to 65 degrees, or less than or equal to 60 degrees.

In the case where the angle θ110 is greater than or equal to 80 degrees and less than or equal to 90 degrees, a film to cover the insulating layer 110 is preferably formed by a film formation method that enables favorable coverage. For example, it is preferable that the conductive layer 104 be formed by a CVD method and the insulating layer 106 and the semiconductor layer 108 be formed by an ALD method. For another example, it is preferable that the conductive layer 104, the insulating layer 106, and the semiconductor layer 108 be formed by an ALD method. In the case where the angle θ110 is greater than or equal to 60 degrees and less than or equal to 85 degrees, a film to cover the insulating layer 110 may be formed by a film formation method with higher productivity. For example, it is preferable that the semiconductor layer 108 be formed by a sputtering method.

The angle θ110 is defined with reference to the insulating layer 110c here but may be defined with reference to the whole insulating layer 110. In other words, the angle θ110 may be an angle formed between the side surface of the insulating layer 110 on the opening 141 side and the formation surface of the insulating layer 110 (the top surface of the conductive layer 112a here).

In the case where, in the semiconductor layer 108, a region in contact with the insulating layer 110b and a region in contact with the insulating layer 110d are included in the channel formation region, it can be said that the channel length L100 is the shortest distance between, in the semiconductor layer 108, a portion in contact with the conductive layer 112a and a portion in contact with the conductive layer 112b in a cross-sectional view. The channel length L100 corresponds to the sum of the lengths of side surfaces of the insulating layers 110b, 110c, and 110d on the opening 141 side in a cross-sectional view.

In FIG. 2A and FIG. 2B, the diameter D143 of the opening 143 is indicated by the dashed-two dotted double-headed arrow. In the example illustrated in FIG. 2A, the top-view shape of each of the opening 141 and the opening 143 is a circle having the diameter D143. Here, the channel width W100 of the transistor 100 is equal to the length of the circumference of this circle. That is, the channel width W100 is π×D143. In the case where the opening 141 and the opening 143 have circular top-view shapes as described above, a transistor with a small channel width can be obtained as compared with the case where the opening 141 and the opening 143 have any other shape.

Note that the opening 141 and the opening 143 sometimes have different diameters from each other. The diameter of each of the opening 141 and the opening 143 sometimes varies in the depth direction. As the diameter of the opening 141, for example, the average value of the following three diameters can be used: the diameter at the highest level of the insulating layer 110 (or the insulating layer 110c) in a cross-sectional view, the diameter at the lowest level of the insulating layer 110 (or the insulating layer 110c) in a cross-sectional view, and the diameter at the midpoint between these levels. For another example, any of the diameter at the highest level of the insulating layer 110 (or the insulating layer 110c) in a cross-sectional view, the diameter at the lowest level of the insulating layer 110 (or the insulating layer 110c) in a cross-sectional view, and the diameter at the midpoint between these levels can be used as the diameter of the opening 141. Similarly, as the diameter of the opening 143, for example, any of the diameter at the highest level of the conductive layer 112b in a cross-sectional view, the diameter at the lowest level of the conductive layer 112b in a cross-sectional view, and the diameter at the midpoint between these levels or the average value of the three diameters can be used.

In the case where the opening 143 is formed by a photolithography method, the diameter D143 of the opening 143 is greater than or equal to the resolution limit of a light-exposure apparatus. The diameter D143 can be, for example, greater than or equal to 20 nm, greater than or equal to 50 nm, greater than or equal to 100 nm, greater than or equal to 200 nm, greater than or equal to 300 nm, greater than or equal to 400 nm, or greater than or equal to 500 nm and less than 5.0 μm, less than or equal to 4.5 μm, less than or equal to 4.0 μm, less than or equal to 3.5 μm, less than or equal to 3.0 μm, less than or equal to 2.5 μm, less than or equal to 2.0 μm, less than or equal to 1.5 μm, or less than or equal to 1.0 μm.

There is no limitation on the top-view shapes of the opening 141 and the opening 143, and the top-view shapes can each be a circle, an ellipse, a polygon such as a triangle, a quadrangle (including a rectangle, a rhombus, and a square), a pentagon, or a star polygon, or any of these polygons with rounded corners, for example. Note that the polygon may be a concave polygon (a polygon at least one of the interior angles of which is greater than 180 degrees) or a convex polygon (a polygon all the interior angles of which are less than or equal to 180 degrees). The top-view shapes of the opening 141 and the opening 143 are preferably circular as illustrated in FIG. 1A and the like. When the top-view shapes of the openings are each circular, processing accuracy at the time of forming the openings can be high, whereby the openings can be formed to have minute sizes. Note that in this specification and the like, a circular shape is not necessarily a perfect circular shape.

In this specification and the like, the top-view shape of the opening 141 refers to the shape of an end portion of the top surface of the insulating layer 110 on the opening 141 side. The top-view shape of the opening 143 refers to the shape of an end portion of the bottom surface of the conductive layer 112b on the opening 143 side.

As illustrated in FIG. 1A and the like, the top-view shape of the opening 141 and the top-view shape of the opening 143 can be the same or substantially the same. In that case, it is preferable that the end portion of the bottom surface of the conductive layer 112b on the opening 143 side be aligned with or substantially aligned with the end portion of the top surface of the insulating layer 110 on the opening 141 side as illustrated in FIG. 1B, FIG. 1C, and the like. The bottom surface of the conductive layer 112b refers to the surface thereof on the insulating layer 110 side. The top surface of the insulating layer 110 refers to the surface thereof on the conductive layer 112b side.

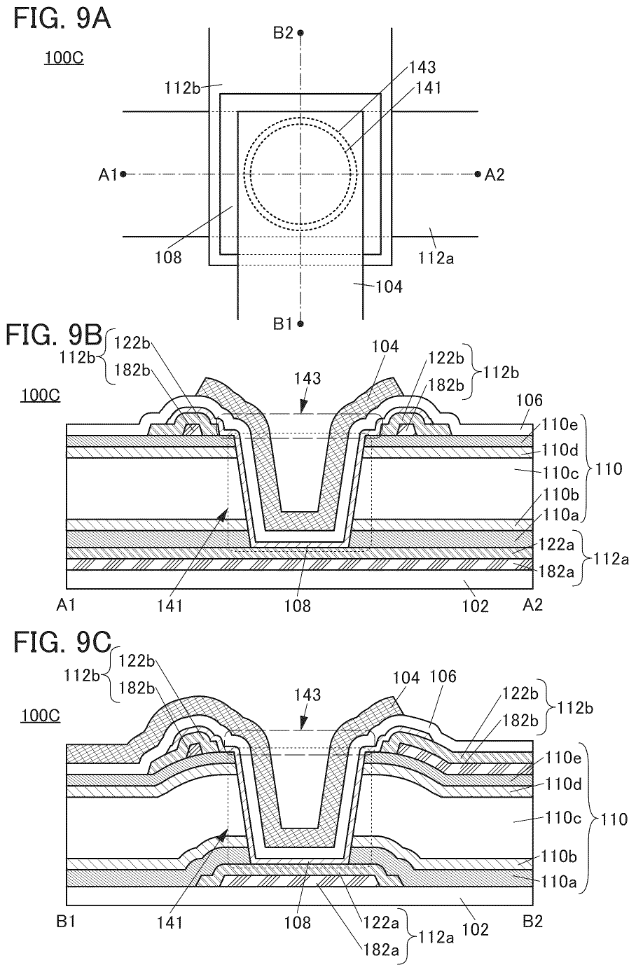

Note that the opening 141 and the opening 143 do not necessarily have the same top-view shape (see a later-described transistor 100C (FIG. 9A and the like)). In the case where the top-view shapes of the opening 141 and the opening 143 are circular, the opening 141 and the opening 143 may or may not be concentric with each other.

### Conductive Layer 112a and Conductive Layer 112b

The conductive layer 112a includes the conductive layer 182a and the conductive layer 122a over the conductive layer 182a. The conductive layer 182a and the conductive layer 122a contain different metals from each other. There is continuity between the conductive layer 182a and the semiconductor layer 108 through the conductive layer 122a. The conductive layer 122a is preferably provided in a portion of the conductive layer 112a that is in contact with the semiconductor layer 108.

Similarly, the conductive layer 112b includes the conductive layer 182b and the conductive layer 122b over the conductive layer 182b. The conductive layer 182b and the conductive layer 122b contain different metals from each other. There is continuity between the conductive layer 182b and the semiconductor layer 108 through the conductive layer 122b. The conductive layer 122b is preferably provided in a portion of the conductive layer 112b that is in contact with the semiconductor layer 108.

A conductive material that is not easily oxidized, a conductive material that maintains low electric resistance even after being oxidized, or an oxide conductor is preferably used for each of the conductive layer 122a and the conductive layer 122b. Accordingly, an increase in contact resistance between the semiconductor layer 108 and the conductive layer 112a or the conductive layer 112b can be inhibited.

Examples of the conductive material that is not easily oxidized or the conductive material that maintains low electric resistance even after being oxidized include titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, and an oxide containing lanthanum and nickel.

Examples of the oxide conductor include indium oxide, zinc oxide, In-Sn oxide (ITO), In—Zn oxide (also referred to as IZO (registered trademark)), In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. A conductive oxide containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layer 122a and the conductive layer 122b may be formed using the same material or different materials.

Each of the conductive layer 122a and the conductive layer 122b may have a single-layer structure or a stacked-layer structure. In the case where the conductive layer 122a or the conductive layer 122b has a stacked-layer structure, a conductive material that is not easily oxidized, a conductive material that maintains low electric resistance even after being oxidized, or an oxide conductor is preferably used for the layer in contact with the semiconductor layer 108, and any of a variety of conductive materials can be used for the other layers. That is, materials that can be used for the conductive layer 182a and the conductive layer 182b described later can also be used for the layers included in the conductive layer 122a and the conductive layer 122b.

For the conductive layer 182a, a material having higher conductivity (which can also be referred to as a material having lower resistivity) than the conductive layer 122a is preferably used. Similarly, for the conductive layer 182b, a material having higher conductivity than the conductive layer 122b is preferably used. In that case, the conductive layer 112a and the conductive layer 112b can be suitable as wirings.

The conductive layer 182a and the conductive layer 182b can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. The use of the conductive layer containing a metal or an alloy can reduce the wiring resistance. For each of the conductive layer 182a and the conductive layer 182b, a low-resistance conductive material that contains one or more of copper, silver, gold, and aluminum can be suitably used. Copper or aluminum is particularly preferable because of its high mass-productivity.

A Cu—X alloy film (X is Mn, Ni, Cr, Fe, Co, Mo, Ta, or Ti) may be used for each of the conductive layer 182a and the conductive layer 182b. The use of a Cu—X alloy film results in lower manufacturing cost because the film can be processed by a wet etching process.

The conductive layer 182a and the conductive layer 182b may be formed using the same material or different materials.

Each of the conductive layer 182a and the conductive layer 182b may have a single-layer structure or a stacked-layer structure. In the case where the conductive layer 182a or the conductive layer 182b has a stacked-layer structure, a material having higher conductivity than the conductive layer 122a or the conductive layer 122b can be used for at least one layer, and any of a variety of conductive materials can be used for the other layers. That is, the above-described materials that can be used for the conductive layer 122a and the conductive layer 122b can also be used for the layers included in the conductive layer 182a and the conductive layer 182b.

As described above, in each of the conductive layer 112a and the conductive layer 112b, a conductive material that is not easily oxidized, a conductive material that maintains low electric resistance even after being oxidized, or an oxide conductor is preferably used for the layer in contact with the semiconductor layer 108, and a material having higher conductivity than the material used for the layer in contact with the semiconductor layer 108 is preferably used for at least one of the other layers. Thus, the contact resistance between the semiconductor layer 108 and the conductive layer 112a and the contact resistance between the semiconductor layer 108 and the conductive layer 112b can be inhibited from being increased. In addition, the wiring resistance of the conductive layer 112a and the conductive layer 112b can be reduced.

Specifically, in the structures of the conductive layer 112a and the conductive layer 112b, a metal film is preferably used as each of the conductive layer 182a and the conductive layer 182b, and an oxide conductor film is preferably used as each of the conductive layer 122a and the conductive layer 122b, for example. Examples of the metal film include a single-layer structure of a tungsten film, a single-layer structure of a titanium film, a single-layer structure of a copper film, a two-layer structure of a titanium film and an aluminum film, and a three-layer structure of a titanium film, an aluminum film, and a titanium film. Examples of the oxide conductor film include a single-layer structure of an In-Zn oxide film, a single-layer structure of an ITO film, and a single-layer structure of an ITSO film.

### Conductive Layer 104

The conductive layer 104 can have a single-layer structure or a stacked-layer structure of two or more layers. The conductive layer 104 can be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For the conductive layer 104, a conductive material with low resistance that contains one or more of copper, silver, gold, and aluminum can be suitably used. Copper or aluminum is particularly preferable because of its high mass-productivity.

An oxide conductor can be used for the conductive layer 104. Examples of the oxide conductor include indium oxide, zinc oxide, In—Sn oxide (ITO), In—Zn oxide, In—W oxide, In—W—Zn oxide, In—Ti oxide, In—Ti—Sn oxide, In—Sn—Si oxide (ITSO), zinc oxide to which gallium is added, and In—Ga—Zn oxide. A conductive oxide containing indium is particularly preferable because of its high conductivity.

The conductive layer 104 may have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for the conductive layer 104. The use of a Cu-X alloy film results in lower manufacturing cost because the film can be processed by a wet etching process.

It is preferable that the conductive layer 104 have a three-layer structure of a titanium film, an aluminum film, and a titanium film, for example.

### Insulating Layer 110

The insulating layer 110 can have a single-layer structure or a stacked-layer structure, and preferably has a stacked-layer structure of three or more layers.

The layers constituting the insulating layer 110 are preferably formed using inorganic insulating films. Examples of the inorganic insulating films include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film.

The insulating layer 110 includes a portion that is in contact with the semiconductor layer 108. In the case where the semiconductor layer 108 is formed using an oxide semiconductor, at least part of the portion that is of the insulating layer 110 and in contact with the semiconductor layer 108 is preferably formed using an oxide to improve the characteristics of the interface between the semiconductor layer 108 and the insulating layer 110. Specifically, the portion that is of the insulating layer 110 and in contact with the channel formation region of the semiconductor layer 108 is preferably formed using an oxide. The channel formation region is a high-resistance region having a low carrier concentration. The channel formation region can be regarded as being i-type (intrinsic) or substantially i-type.

As the insulating layer 110c, which is in contact with the channel formation region of the semiconductor layer 108, a layer including oxygen is preferably used. It is preferable that the insulating layer 110c include a region having a higher oxygen content than one or both of the insulating layer 110b and the insulating layer 110d.

The insulating layer 110c is preferably formed using any one or more of the oxide insulating films and oxynitride insulating films described above. Specifically, the insulating layer 110c is preferably formed using one or both of a silicon oxide film and a silicon oxynitride film. By having a high oxygen content, the insulating layer 110c can facilitate formation of an i-type region in a region of the semiconductor layer 108 that is in contact with the insulating layer 110c and the vicinity of this region.

It is further preferable that a film from which oxygen is released by heating be used for the insulating layer 110c. When the insulating layer 110c releases oxygen by being heated during the manufacturing process of the transistor 100, the oxygen can be supplied to the semiconductor layer 108. The oxygen supply from the insulating layer 110c to the semiconductor layer 108, particularly to the channel formation region of the semiconductor layer 108, reduces the amount of oxygen vacancies in the semiconductor layer 108, so that the transistor can have favorable electrical characteristics and high reliability.

For example, heat treatment in an oxygen-containing atmosphere or plasma treatment in an oxygen-containing atmosphere can supply oxygen to the insulating layer 110c. Alternatively, an oxide film may be formed over the top surface of the insulating layer 110c by a sputtering method in an oxygen atmosphere to supply oxygen. After that, the oxide film may be removed. Note that Embodiment 2 describes an example in which oxygen is supplied to the insulating layer 110c through nitrous oxide (N₂O) plasma treatment and the formation of a metal oxide layer 149.

The insulating layer 110c is preferably formed by a film formation method such as a sputtering method or a plasma-enhanced chemical vapor deposition (PECVD) method. In particular, a sputtering method does not need to use hydrogen as a film formation gas and enables a film having an extremely low hydrogen content to be formed. In that case, supply of hydrogen to the semiconductor layer 108 is inhibited and the electrical characteristics of the transistor 100 can be stabilized.

For each of the insulating layer 110b and the insulating layer 110d, a film that does not easily allow diffusion of oxygen is preferably used. In that case, it is possible to prevent oxygen included in the insulating layer 110c from being diffused toward the substrate 102 side through the insulating layer 110b and being diffused toward the conductive layer 112b and the insulating layer 106 side through the insulating layer 110d owing to heating. In other words, when the insulating layer 110b and the insulating layer 110d that do not easily allow diffusion of oxygen are respectively provided below and above the insulating layer 110c so that the insulating layer 110c is held therebetween, oxygen can be enclosed in the insulating layer 110c. Accordingly, oxygen can be effectively supplied to the semiconductor layer 108.

For each of the insulating layer 110b and the insulating layer 110d, a film that does not easily allow diffusion of hydrogen is preferably used. In that case, hydrogen can be inhibited from being diffused from outside of the transistor to the semiconductor layer 108 through the insulating layer 110b or the insulating layer 110d.

It is preferable that the insulating layer 110b and the insulating layer 110d be each formed using any one or more of the oxide insulating film, the nitride insulating film, the oxynitride insulating film, and the nitride oxide insulating film described above. Specifically, for each of the insulating layer 110b and the insulating layer 110d, one or more of a silicon nitride film, a silicon nitride oxide film, a silicon oxynitride film, an aluminum oxide film, an aluminum oxynitride film, an aluminum nitride film, a hafnium oxide film, and a hafnium aluminate film are preferably used.

It is preferable that the insulating layer 110b and the insulating layer 110d be each formed using any one or more of the nitride insulating film and nitride oxide insulating film described above. Specifically, it is preferable that the insulating layer 110b and the insulating layer 110d be each formed using one or both of a silicon nitride film and a silicon nitride oxide film.

A silicon nitride film and a silicon nitride oxide film are suitable for the insulating layer 110b and the insulating layer 110d because they each release fewer impurities (e.g., water and hydrogen) and do not easily transmit oxygen and hydrogen.

For the insulating layer 110b and the insulating layer 110d, the above-described aluminum-including films may be used, for example. For example, for each of the insulating layer 110b and the insulating layer 110d, an aluminum oxide film is preferably used. An aluminum oxide film is suitable because it can have a lower hydrogen content than a silicon nitride film.

The thickness of each of the insulating layer 110b and the insulating layer 110d is preferably greater than or equal to 5 nm and less than or equal to 150 nm, further preferably greater than or equal to 5 nm and less than or equal to 100 nm, still further preferably greater than or equal to 5 nm and less than or equal to 70 nm, yet still further preferably greater than or equal to 10 nm and less than or equal to 70 nm, yet still further preferably greater than or equal to 10 nm and less than or equal to 50 nm, yet still further preferably greater than or equal to 20 nm and less than or equal to 50 nm. When the thickness of each of the insulating layer 110 b and the insulating layer 110d is in the above-described range, the amount of oxygen vacancies in the semiconductor layer 108, or specifically in the channel formation region, can be reduced. The insulating layer 110b and the insulating layer 110d may have the same thickness or different thicknesses.

It is preferable that, for example, silicon nitride films or silicon nitride oxide films be used for the insulating layer 110b and the insulating layer 110d, and a silicon oxide film or a silicon oxynitride film be used for the insulating layer 110c.

### Semiconductor Layer 108

The semiconductor layer 108 includes a metal oxide exhibiting semiconductor characteristics (also referred to as an oxide semiconductor).

There is no particular limitation on the crystallinity of the semiconductor material used for the semiconductor layer 108, and any of an amorphous semiconductor, a single crystal semiconductor, and a semiconductor having other crystallinity than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The band gap of a metal oxide used for the semiconductor layer 108 is preferably 2.0 eV or more, further preferably 2.5 eV or more.

Examples of the metal oxide that can be used for the semiconductor layer 108 include indium oxide, gallium oxide, and zinc oxide. The metal oxide preferably contains at least indium or zinc. The metal oxide preferably contains two or three elements selected from indium, an element M, and zinc. The element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more of the above elements, further preferably one or more selected from aluminum, gallium, tin, and yttrium, still further preferably gallium. In this specification and the like, a metal element and a metalloid element may be collectively referred to as a “metal element”, and a “metal element” described in this specification and the like may refer to a metalloid element.

For example, the semiconductor layer 108 can be formed using an indium zinc oxide (also referred to as an In—Zn oxide or an IZO (registered trademark)), an indium tin oxide (an In—Sn oxide), an indium titanium oxide (an In—Ti oxide), an indium gallium oxide (an In—Ga oxide), an indium gallium aluminum oxide (an In—Ga—Al oxide), an indium gallium tin oxide (an In—Ga—Sn oxide), a gallium zinc oxide (also referred to as a Ga-Zn oxide or a GZO), an aluminum zinc oxide (also referred to as an Al—Zn oxide or an AZO), an indium aluminum zinc oxide (also referred to as an In—Al—Zn oxide or an IAZO), an indium tin zinc oxide (also referred to as an In—Sn—Zn oxide or an ITZO (registered trademark)), an indium titanium zinc oxide (an In—Ti—Zn oxide), an indium gallium zinc oxide (also referred to as an In—Ga—Zn oxide or an IGZO), an indium gallium tin zinc oxide (also referred to as an In—Ga—Sn—Zn oxide or an IGZTO), or an indium gallium aluminum zinc oxide (also referred to as an In—Ga—Al—Zn oxide, an IGAZO, an IGZAO, or an IAGZO). Alternatively, it is possible to use indium tin oxide containing silicon, gallium tin oxide (Ga—Sn oxide), aluminum tin oxide (Al—Sn oxide), or the like.

By increasing the proportion of the number of indium atoms in the total number of atoms of all the metal elements contained in the metal oxide, the field-effect mobility of the transistor can be increased. In addition, the transistor can have a high on-state current.

Note that the metal oxide may contain, instead of indium or in addition to indium, one or more kinds of metal elements belonging to a period of a higher number in the periodic table. The larger the overlap between orbits of metal elements is, the more likely it is that the metal oxide will have high carrier conductivity. Thus, a transistor including a metal element belonging to a period of a higher number in the periodic table can have high field-effect mobility in some cases. Examples of the metal element belonging to a period of a higher number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a nonmetallic element, the metal oxide sometimes has an increased carrier concentration, a reduced band gap, or the like, in which case the transistor can have higher field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is suppressed, and the reliability of the transistor can be increased.

The composition of the metal oxide used for the semiconductor layer 108 affects the electrical characteristics and reliability of the transistor. Thus, by varying the composition of the metal oxide in accordance with the electrical characteristics and reliability required for the transistor, the semiconductor device can have both good electrical characteristics and high reliability.

When the metal oxide is an In—M—Zn oxide, the proportion of the number of In atoms is preferably higher than or equal to that of the number of M atoms in the In—M—Zn oxide. Examples of the atomic ratio of the metal elements of such an In-M-Zn oxide include In:M:Zn=1:1:1, In: M:Zn=1:1:1.2, In:M:Zn=2:1:3, In:M:Zn=3:1:1, In:M:Zn=3:1:2, In:M:Zn=4:2:3, In:M: Zn=4:2:4.1, In:M:Zn=5:1:3, In:M:Zn=5:1:6, In:M:Zn=5:1:7, In:M:Zn=5:1:8, In:M:Zn =6:1:6, In:M:Zn=5:2:5, and a composition in the neighborhood of any of the above atomic ratios. Note that the vicinity of the atomic ratio includes ±30% of an intended atomic ratio. By increasing the proportion of the number of indium atoms in the metal oxide, the on-state current, field-effect mobility, or the like of the transistor can be increased.

The proportion of the number of In atoms may be less than that of the number of M atoms in the In—M—Zn oxide. Examples of the atomic ratio of the metal elements in such an In—M—Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of the metal elements can be the proportion of the number of element M atoms.

In this specification and the like, the proportion of the number of indium atoms in the total number of atoms of all the metal elements contained is sometimes referred to as the content percentage of indium. The same applies to other metal elements.

A sputtering method or an atomic layer deposition (ALD) method can be suitably used to form the metal oxide. Note that in the case where the metal oxide is formed by a sputtering method, the composition of the formed metal oxide film may be different from the composition of a target. In particular, the content percentage of zinc in the formed metal oxide film may be reduced to approximately 50% of that of the target.

The semiconductor layer 108 may have a stacked-layer structure of two or more metal oxide layers. The two or more metal oxide layers included in the semiconductor layer 108 may have the same composition or substantially the same compositions as each other. When the compositions of the stacked metal oxide layers are the same, they can be formed using the same sputtering target, for example, and the manufacturing cost can thus be reduced.

The two or more metal oxide layers included in the semiconductor layer 108 may have different compositions from each other. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In addition, it is particularly preferable to use gallium, aluminum, or tin as the element M. For example, a stacked-layer structure of any one selected from indium oxide, indium gallium oxide, and IGZO, and any one selected from IAZO, IAGZO, and ITZO (registered trademark) may be employed.

It is preferable that the semiconductor layer 108 include a metal oxide layer having crystallinity. Examples of the structure of a metal oxide having crystallinity include a CAAC (c-axis aligned crystal) structure, a polycrystalline structure, and a nano-crystal (nc) structure. With use of a metal oxide layer having crystallinity as the semiconductor layer 108, the density of defect states in the semiconductor layer 108 can be reduced, which enables the semiconductor device to have high reliability.

The higher the crystallinity of the metal oxide layer used for the semiconductor layer 108 is, the lower the density of defect states in the semiconductor layer 108 can be. By contrast, with the use of a metal oxide layer having low crystallinity, a large amount of current can flow through the transistor.

In the case where the metal oxide layer is formed by a sputtering method, the higher the substrate temperature (the stage temperature) in the formation is, the higher the crystallinity of the formed metal oxide layer can be. Furthermore, the higher the proportion of the flow rate of an oxygen gas to the total flow rate of the film formation gas (also referred to as an oxygen flow rate ratio) used in the formation is, the higher the crystallinity of the formed metal oxide layer can be.

The semiconductor layer 108 may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

The thickness of the semiconductor layer 108 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm.

In the case where an oxide semiconductor is used for the semiconductor layer 108, hydrogen contained in the oxide semiconductor reacts with oxygen bonded to a metal atom to be water, and thus forms an oxygen vacancy (Vo) in the oxide semiconductor, in some cases. In some cases, a defect that is an oxygen vacancy into which hydrogen enters (hereinafter referred to as V_{O}H) functions as a donor and generates an electron serving as a carrier. In other cases, bonding of part of hydrogen to oxygen bonded to a metal atom generates electrons serving as carriers. Thus, a transistor including an oxide semiconductor that contains a large amount of hydrogen is likely to have normally-on characteristics (that is, the threshold voltage is likely to be a negative value). Moreover, hydrogen in the oxide semiconductor is easily transferred by a stress such as heat or an electric field; thus, a large amount of hydrogen in the oxide semiconductor might reduce the reliability of the transistor.

In the case where an oxide semiconductor is used for the semiconductor layer 108, the amount of VoH in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as V_{O}H is used for the channel formation region of the transistor, the transistor can have stable electrical characteristics. Note that repairing oxygen vacancies by supplying oxygen to an oxide semiconductor is sometimes referred to as oxygen adding treatment.

When an oxide semiconductor is used for the semiconductor layer 108, the carrier concentration of the oxide semiconductor in the region functioning as the channel formation region is preferably lower than or equal to 1×10¹⁸ cm⁻3, further preferably lower than 1×10¹⁷ cm⁻3, still further preferably lower than 1×10¹⁶cm⁻3, yet still further preferably lower than 1×10¹³ cm⁻3, yet still further preferably lower than 1×10¹²cm⁻3. Note that the lower limit of the carrier concentration of the oxide semiconductor in the region functioning as the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for a long period. Furthermore, a semiconductor device can have lower power consumption by including the OS transistor.

A change in electrical characteristics of an OS transistor due to irradiation with radiation is small; in other words, an OS transistor has high resistance to radiation. Thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, proton beams, and neutron beams).

Other examples of the semiconductor material that can be used for the semiconductor layer 108 include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may include an impurity as a dopant.

Examples of silicon that can be used for the semiconductor layer 108 include single crystal silicon, polycrystalline silicon, microcrystalline silicon, and amorphous silicon. An example of polycrystalline silicon is low-temperature polysilicon (LTPS).

The transistor including amorphous silicon in the semiconductor layer 108 can be formed over a large-sized glass substrate, thereby reducing the manufacturing cost. The transistor including polycrystalline silicon in the semiconductor layer 108 has high field-effect mobility and enables high-speed operation. The transistor including microcrystalline silicon in the semiconductor layer 108 has higher field-effect mobility and enables higher speed operation than the transistor including amorphous silicon.

The semiconductor layer 108 may include a layered substance functioning as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### Insulating Layer 106

The insulating layer 106 can have a single-layer structure or a stacked-layer structure of two or more layers. The insulating layer 106 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 106 includes a portion that is in contact with the semiconductor layer 108. In the case where the semiconductor layer 108 is formed using an oxide semiconductor, at least the film of the insulating layer 106 that is in contact with the semiconductor layer 108 is preferably any of the above-described oxide insulating films and oxynitride insulating films. A film which releases oxygen by heating is further preferably used as the insulating layer 106.

Specifically, in the case where the insulating layer 106 has a single-layer structure, the insulating layer 106 is preferably formed using a silicon oxide film or a silicon oxynitride film.

The insulating layer 106 can have a stacked-layer structure of an oxide insulating film or an oxynitride insulating film that is in contact with the semiconductor layer 108 and a nitride insulating film or a nitride oxide insulating film that is in contact with the conductive layer 104. As the oxide insulating film or the oxynitride insulating film, for example, a silicon oxide film or a silicon oxynitride film is preferably used. As the nitride insulating film or the nitride oxide insulating film, a silicon nitride film or a silicon nitride oxide film is preferably used.

A silicon nitride film and a silicon nitride oxide film can be suitably used as the insulating layer 106 because the amount of impurities (e.g., water and hydrogen) released from the silicon nitride film and the silicon nitride oxide film themselves is small and the silicon nitride film and the silicon nitride oxide film have a feature of not easily transmitting oxygen and hydrogen. Inhibiting diffusion of impurities from the insulating layer 106 to the semiconductor layer 108 results in favorable electrical characteristics and high reliability of the transistor.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### Substrate 102

Although there is no significant limitation on the material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or a resin substrate may be used as the substrate 102. The substrate 102 may be provided with a semiconductor element. Note that the shape of the semiconductor substrate and an insulating substrate may be circular or square.

A flexible substrate may be used as the substrate 102, and the transistor 100 and the like may be formed directly on the flexible substrate. Alternatively, a separation layer may be provided between the substrate 102 and the transistor 100 and the like. The separation layer can be used for separation of part or the whole of a semiconductor device completed thereover from the substrate 102 and transferring the part or the whole of the semiconductor device onto another substrate. In that case, the transistor 100 and the like can be transferred onto a substrate having low heat resistance or a flexible substrate as well.

### Variation Example of Transistor 100

FIG. 3C and FIG. 4 to FIG. 12 illustrate variation examples of the transistor 100.

Note that in the semiconductor device of one embodiment of the present invention, at least one of the conductive layer 112a and the conductive layer 112b has a stacked-layer structure of two or more layers in which the top surface and the side surface of a first layer (the conductive layer 182a or the conductive layer 182b) are covered with a second layer (the conductive layer 122a or the conductive layer 122b).

For example, as illustrated in FIG. 3C, a structure in which the conductive layer 122a is in contact with the top surface of the conductive layer 182a and is not in contact with the side surface of the conductive layer 182a can be employed. In that case, the conductive layer 122a and the conductive layer 182a can be formed through processing using the same mask pattern. Consequently, manufacturing steps and costs can be reduced. In this case, the conductive layer 122a and the conductive layer 182a can be regarded as having the same or substantially the same top-view shapes or having aligned or substantially aligned end portions.

### Transistor 100A

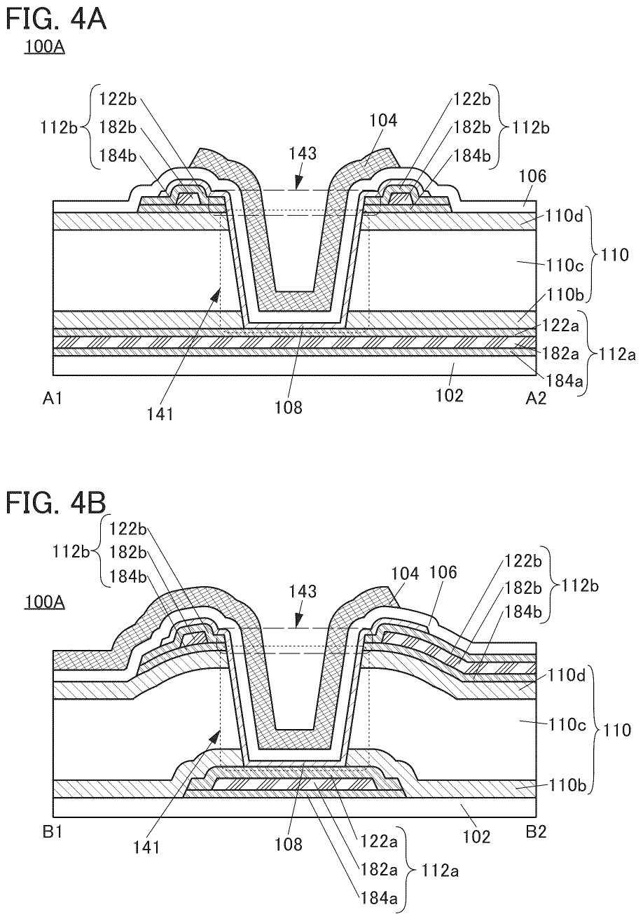

FIG. 4A and FIG. 4B are cross-sectional views of a transistor 100A. A top view of the transistor 100A is similar to the top view of the transistor 100; thus, FIG. 1A can be referred to.

The transistor 100A is different from the transistor 100 in that the conductive layer 112a and the conductive layer 112b each have a three-layer structure.

The conductive layer 112a in the transistor 100A includes a conductive layer 184a, the conductive layer 182a over the conductive layer 184a, and the conductive layer 122a over the conductive layer 182a. As illustrated in FIG. 4B, an end portion of the conductive layer 182a and an end portion of the conductive layer 122a are positioned over the conductive layer 184a. The conductive layer 122a is provided to be in contact with the top surface and the side surface of the conductive layer 182a and to cover the top surface and the side surface thereof. The conductive layer 122a is in contact with the semiconductor layer 108. The conductive layer 122a is in contact with the top surface of the conductive layer 184a, outside the end portion of the conductive layer 182a. In other words, the top surface, the side surface, and the bottom surface of the conductive layer 182a are surrounded by the conductive layer 184a and the conductive layer 122a.

Depending on the material of the conductive layer 182a, adhesion to the formation surface (here, the substrate 102) might be low and the manufacturing yield of the semiconductor device might be low. Therefore, the conductive layer 184a having higher adhesion to the base than the conductive layer 182a is preferably provided.

For example, it is preferable that ITSO be used for the conductive layer 184a, copper be used for the conductive layer 182a, and ITSO be used for the conductive layer 122a. The adhesion between a glass substrate and an ITSO film is higher than that between the glass substrate and a copper film. Since the conductive layer 184a and the conductive layer 122a can be processed in the same step, the manufacturing yield of the semiconductor device can be increased while a significant increase in the number of manufacturing steps is prevented.

The conductive layer 112b in the transistor 100A includes a conductive layer 184b, the conductive layer 182b over the conductive layer 184b, and the conductive layer 122b over the conductive layer 182b. As illustrated in FIG. 4B, an end portion of the conductive layer 182b and an end portion of the conductive layer 122b are positioned over the conductive layer 184b. The conductive layer 122b is provided to be in contact with the top surface and the side surface of the conductive layer 182b and to cover the top surface and the side surface thereof. The conductive layer 122b and the conductive layer 184b are in contact with the semiconductor layer 108. The conductive layer 122b is in contact with the top surface of the conductive layer 184b, outside the end portion of the conductive layer 182b. In other words, the top surface, the side surface, and the bottom surface of the conductive layer 182b are surrounded by the conductive layer 184b and the conductive layer 122b.

Copper is preferably used for the conductive layer 182b, in which case the wiring resistance of the conductive layer 112b can be reduced; however, diffusion of copper into the insulating layer 110 and furthermore into the semiconductor layer 108 might adversely affect the characteristics of the transistor. Thus, providing the conductive layer 184b can inhibit diffusion of copper from the conductive layer 182b into the insulating layer 110 and furthermore into the semiconductor layer 108.

For example, it is preferable that ITSO be used for the conductive layer 184b, copper be used for the conductive layer 182b, and ITSO be used for the conductive layer 122b. Since the conductive layer 184b and the conductive layer 122b can be processed in the same step, the reliability of the transistor can be increased while a significant increase in the number of manufacturing steps is prevented.

Note that in the semiconductor device of one embodiment of the present invention, at least one of the conductive layer 112a and the conductive layer 112b has a stacked-layer structure of two or more layers in which the top surface and the side surface of a first layer (the conductive layer 182a or the conductive layer 182b) are covered with a second layer (the conductive layer 122a or the conductive layer 122b).

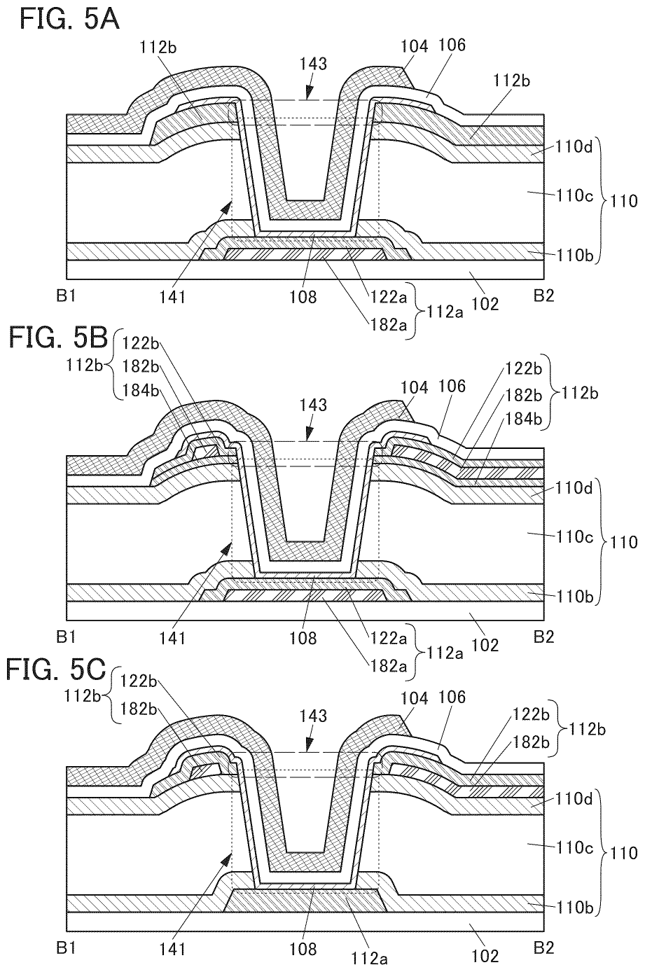

Next, examples of the combination of the conductive layer 112a and the conductive layer 112b are described with reference to FIG. 5 to FIG. 7.

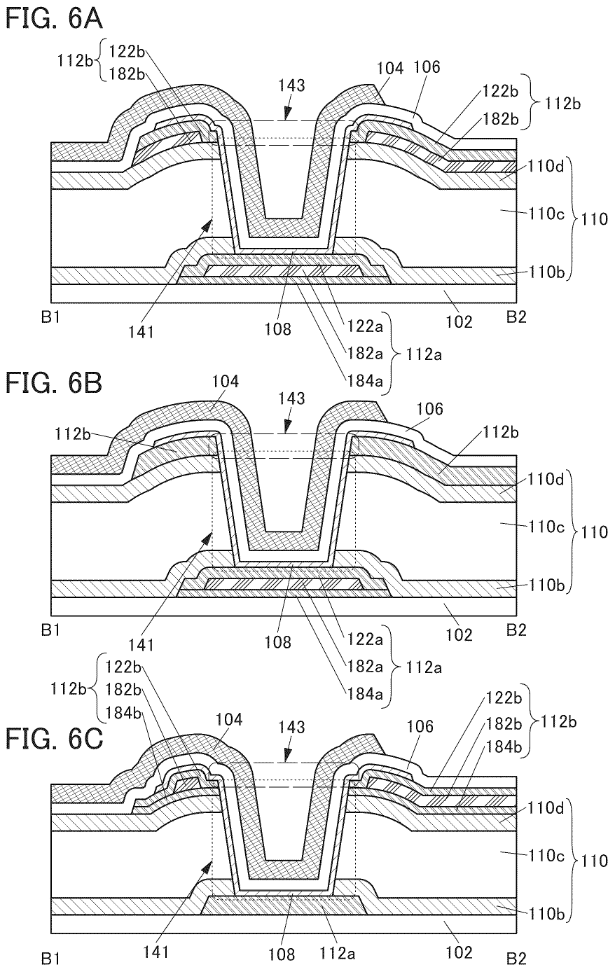

FIG. 5A illustrates an example where the conductive layer 112a has a two-layer structure and the conductive layer 112b has a single-layer structure. FIG. 5B illustrates an example in which the conductive layer 112a has a two-layer structure and the conductive layer 112b has a three-layer structure. FIG. 5C illustrates an example in which the conductive layer 112a has a single-layer structure and the conductive layer 112b has a two-layer structure. FIG. 6A illustrates an example in which the conductive layer 112a has a three-layer structure and the conductive layer 112b has a two-layer structure. FIG. 6B illustrates an example in which the conductive layer 112a has a three-layer structure and the conductive layer 112b has a single-layer structure. FIG. 6C illustrates an example in which the conductive layer 112a has a single-layer structure and the conductive layer 112b has a three-layer structure.

A conductive material that is not easily oxidized, a conductive material that maintains low electric resistance even after being oxidized, or an oxide conductor is preferably used for the conductive layer 112a having a single-layer structure; specifically, ITSO is preferably used. Accordingly, an increase in contact resistance between the conductive layer 112a and the semiconductor layer 108 can be inhibited.

For the structure example of the conductive layer 112a having a two-layer structure, the description of the transistor 100 (FIG. 1 to FIG. 3) can be referred to.

For the structure example of the conductive layer 112a having a three-layer structure, the description of the transistor 100A (FIG. 4A and FIG. 4B) can be referred to.

A conductive material that is not easily oxidized, a conductive material that maintains low electric resistance even after being oxidized, or an oxide conductor is preferably used for the conductive layer 112b having a single-layer structure; specifically, ITSO is preferably used. Accordingly, an increase in contact resistance between the conductive layer 112b and the semiconductor layer 108 can be inhibited.

For the structure example of the conductive layer 112b having a two-layer structure, the description of the transistor 100 (FIG. 1 to FIG. 3) can be referred to.

For the structure example of the conductive layer 112b having a three-layer structure, the description of the transistor 100A (FIG. 4A and FIG. 4B) can be referred to.

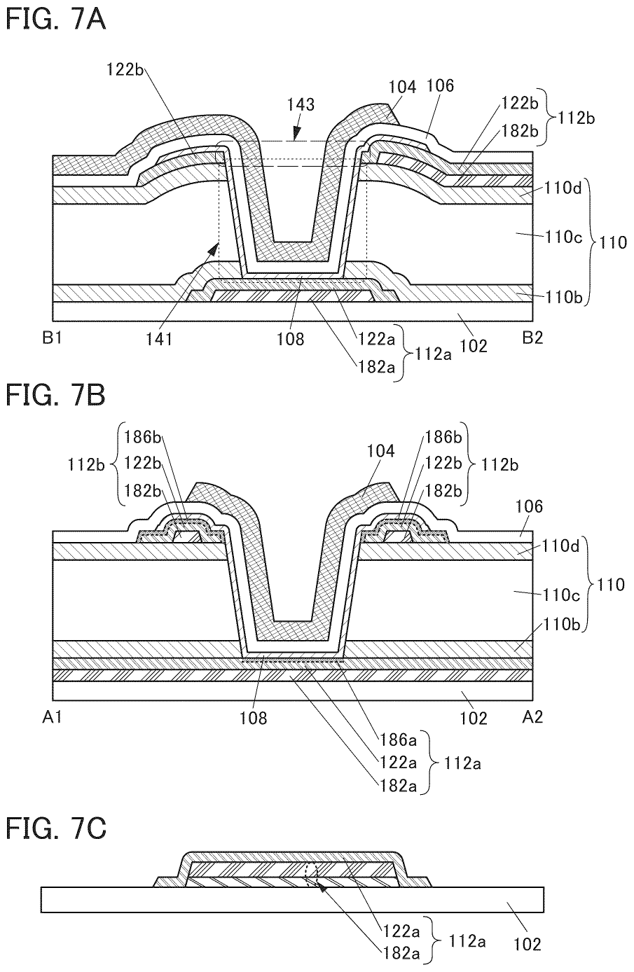

Note that the conductive layer 182b does not necessarily include the opening 145. In a cross-sectional view, the conductive layer 182b may exist on the left side and the right side of the opening 143 as illustrated in FIG. 1B, FIG. 1C, and the like; or the conductive layer 182b may exist only on one of the left side and the right side of the opening 143 as illustrated in FIG. 7A. FIG. 7A illustrates an example in which the end portion of the conductive layer 182b is positioned on the right side of the opening 143 and the conductive layer 182b does not exist on the left side of the opening 143.

As illustrated in FIG. 7B, the conductive layer 112a may include a conductive layer 186a. The conductive layer 112b may include a conductive layer 186b.

It is preferable that the conductive layer 122a be a metal layer, the conductive layer 186a be a metal oxide layer, and the conductive layer 122a and the conductive layer 186a contain the same metal. For example, part of the conductive layer 122a is oxidized by the formation step of the semiconductor layer 108 and/or the heating step performed in a state where the conductive layer 122a and the semiconductor layer 108 are in contact with each other, so that the conductive layer 186a which is a metal oxide layer is formed. After the conductive layer 122a is formed, oxidation treatment may be performed to oxidize part of the conductive layer 122a and form the conductive layer 186a which is a metal oxide layer.

The conductive layer 186a is positioned between the conductive layer 122a and the semiconductor layer 108. It can also be said that the conductive layer 186a covers part of the top surface of the conductive layer 122a.

Similarly, it is preferable that the conductive layer 122b be a metal layer, the conductive layer 186b be a metal oxide layer, and the conductive layer 122b and the conductive layer 186b contain the same metal. For example, part of the conductive layer 122b is oxidized by one or both of the formation step of the semiconductor layer 108 and the heating step performed in a state where the conductive layer 122b and the semiconductor layer 108 are in contact with each other, so that the conductive layer 186b which is a metal oxide layer is formed. After the conductive layer 122b is formed, oxidation treatment may be performed to oxidize part of the conductive layer 122b and form the conductive layer 186b which is a metal oxide layer.

The conductive layer 186b is positioned between the conductive layer 122b and the semiconductor layer 108. It can also be said that the conductive layer 186b covers the top surface and the side surface of the conductive layer 122b.

The conductive layer 122a, the conductive layer 122b, the conductive layer 186a, and the conductive layer 186b each preferably contain titanium. Accordingly, high conductivity of the conductive layer 122a and the conductive layer 122b can be maintained, and an increase in contact resistance due to formation of the conductive layer 186a and the conductive layer 186b can be inhibited.

For example, a single-layer structure of an aluminum film, a single-layer structure of a tungsten film, or a stacked-layer structure of a titanium film and an aluminum film can be used for the conductive layer 182a, a titanium film can be used for the conductive layer 122a, and a titanium oxide film can be used for the conductive layer 186a. Similarly, a single-layer structure of an aluminum film, a single-layer structure of a tungsten film, or a stacked-layer structure of a titanium film and an aluminum film can be used for the conductive layer 182b, a titanium film can be used for the conductive layer 122b, and a titanium oxide film can be used for the conductive layer 186b.

Furthermore, each of the conductive layer 122a and the conductive layer 122b includes a portion that is in contact with the insulating layer 110. In FIG. 7B, the conductive layer 122a and the insulating layer 110b are in contact with each other, and the conductive layer 122b and the insulating layer 110d are in contact with each other. A nitride is preferably used for each of the insulating layer 110b and the insulating layer 110d. Specifically, silicon nitride or silicon nitride oxide is preferably used. Thus, formation of an oxide between the insulating layer 110 and the conductive layer 122a or the conductive layer 122b can be inhibited, and an increase in the electric resistance of the conductive layer 112a and the conductive layer 112b can be inhibited. In the case where titanium is used for the conductive layer 122a and the conductive layer 112b, in terms of adhesion, the conductive layer 122a and the conductive layer 112b are preferably in contact with silicon nitride or silicon nitride oxide rather than silicon oxide or silicon oxynitride.

In the case where a nitride is used for the insulating layer 110b, a metal nitride layer is sometimes formed between the conductive layer 122a and the insulating layer 110b. Similarly, in the case where a nitride is used for the insulating layer 110d, a metal nitride layer is sometimes formed between the conductive layer 122b and the insulating layer 110d. Thus, it is preferable to use, for the conductive layer 122a and the conductive layer 112b, a metal that maintains low electric resistance even if it becomes a nitride. For example, titanium is preferably used for the conductive layer 122a and the conductive layer 112b, in which case a titanium nitride layer is formed as the metal nitride layer.

FIG. 7C illustrates an example in which the conductive layer 182a has a two-layer structure. In the case where the conductive layer 182a has a stacked-layer structure, at least two layers are preferably formed through processing using the same mask pattern. Consequently, manufacturing steps and costs can be reduced. In this case, two or more layers constituting the conductive layer 182a can be regarded as having the same or substantially the same top-view shapes or having aligned or substantially aligned end portions.

### Transistor 100B

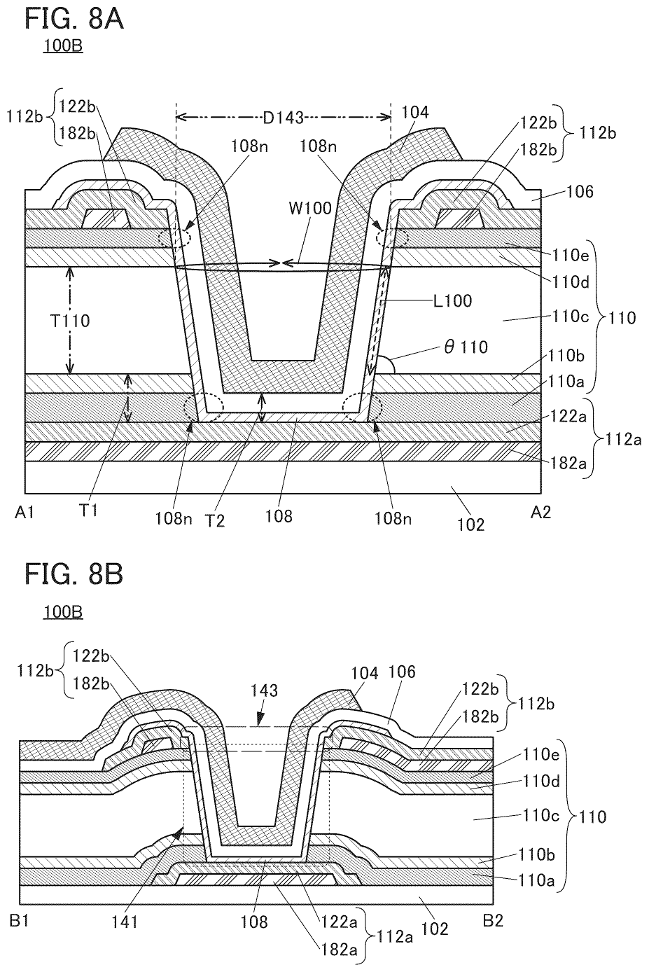

FIG. 8A and FIG. 8B are cross-sectional views of a transistor 100B. A top view of the transistor 100B is similar to the top view of the transistor 100; thus, FIG. 1A can be referred to.

The transistor 100 with the insulating layer 110 having a three-layer structure has been described as an example, and the transistor 100B with the insulating layer 110 having a five-layer structure is described as another example. Specifically, the insulating layer 110 illustrated in FIGS. 8A and 8B has a stacked-layer structure of an insulating layer 110a over the substrate 102 and the conductive layer 112a, the insulating layer 110b over the insulating layer 110a, the insulating layer 110c over the insulating layer 110b, the insulating layer 110d over the insulating layer 110c, and an insulating layer 110e over the insulating layer 110d.

The semiconductor layer 108 includes a region (offset region) to which a gate electric field is not easily applied. The insulating layer 110a is preferably provided to be in contact with the offset region.

The insulating layer 110a includes a region with a higher hydrogen content than the insulating layer 110b. The insulating layer 110a preferably includes a region with a higher hydrogen content than the insulating layer 110d.

When the offset region has high resistance, the field-effect mobility of the transistor might decrease. When the insulating layer 110a is a layer having a high hydrogen content, the resistances of a region of the semiconductor layer 108 that is in contact with the insulating layer 110a and the vicinity of the region (see lower two regions 108n illustrated in FIG. 8A) can be reduced. Accordingly, a decrease in field-effect mobility due to the offset region can be inhibited.

The insulating layer 110a is preferably a layer from which hydrogen is released by heating. When the insulating layer 110a releases hydrogen by being heated during the manufacturing process of the transistor 100B, the hydrogen can be supplied to the semiconductor layer 108. When the offset region of the semiconductor layer 108 is supplied with hydrogen, the offset region can have lower resistance, whereby the field-effect mobility can be inhibited from decreasing.

Likewise, the insulating layer 110e includes a region with a higher hydrogen content than the insulating layer 110d. The insulating layer 110e preferably includes a region with a higher hydrogen content than the insulating layer 110b.

When the insulating layer 110e is a layer having a high hydrogen content, the resistances of a region of the semiconductor layer 108 that is in contact with the insulating layer 110e and the vicinity of the region (see upper two regions 108n illustrated in FIG. 8A) can be reduced.

The insulating layer 110e is preferably a layer from which hydrogen is released by heating. When the insulating layer 110e releases hydrogen by being heated during the manufacturing process of the transistor 100B, the hydrogen can be supplied to the semiconductor layer 108. Thus, a low-resistance region can be formed in the vicinity of the region of the semiconductor layer 108 that is in contact with the conductive layer 112b.

In the semiconductor layer 108 of the transistor 100B, the region in contact with the insulating layer 110a, which is a low-resistance region, is provided between the region in contact with the conductive layer 112a and the region in contact with the insulating layer 110c, which is an i-type region. Here, in the case where the conductive layer 112a functions as the drain electrode and the conductive layer 112b functions as the source electrode, the semiconductor layer 108 can be regarded as including the low-resistance region between a region in contact with the drain electrode and the channel formation region. Thus, a high electric field is not easily generated in the vicinity of a drain region, and generation of hot carriers and degradation of the transistor can be inhibited.

Likewise, in the semiconductor layer 108 of the transistor 100B, the region in contact with the insulating layer 110e, which is a low-resistance region, is provided between the region in contact with the conductive layer 112b and the region in contact with the insulating layer 110c, which is an i-type region. Here, in the case where the conductive layer 112a functions as the source electrode and the conductive layer 112b functions as the drain electrode, the semiconductor layer 108 can be regarded as including the low-resistance region between a region in contact with the drain electrode and the channel formation region. Thus, a high electric field is not easily generated in the vicinity of a drain region, and generation of hot carriers and degradation of the transistor can be inhibited.

As described above, the transistor of one embodiment of the present invention can have high reliability irrespective of whether the conductive layer 112a or the conductive layer 112b is the drain electrode. Accordingly, the design flexibility of the semiconductor device can be increased.

The insulating layer 110b has a lower hydrogen content than the insulating layer 110a. The insulating layer 110d has a lower hydrogen content than the insulating layer 110e. It is thus possible to inhibit diffusion of hydrogen from the insulating layer 110b or the insulating layer 110d to the insulating layer 110c and a region of the semiconductor layer 108 to which a gate electric field is sufficiently applied (a region that is intended to be of an i-type).

As described above, for each of the insulating layer 110b and the insulating layer 110d, a film that does not easily allow diffusion of hydrogen is preferably used. In that case, hydrogen can be inhibited from being diffused from the insulating layer 110a to the semiconductor layer 108 through the insulating layer 110b. Furthermore, hydrogen can be inhibited from being diffused from the insulating layer 110e to the semiconductor layer 108 through the insulating layer 110d.

It is preferable that the insulating layer 110a and the insulating layer 110e be each formed using any one or more of the oxide insulating film, the nitride insulating film, the oxynitride insulating film, and the nitride oxide insulating film described above. Specifically, for each of the insulating layer 110a and the insulating layer 110e, one or more of a silicon nitride film, a silicon nitride oxide film, a silicon oxynitride film, an aluminum oxide film, an aluminum oxynitride film, an aluminum nitride film, a hafnium oxide film, and a hafnium aluminate film are preferably used.

It is preferable that the insulating layer 110a and the insulating layer 110e be each formed using any one or more of the nitride insulating film and nitride oxide insulating film described above. Specifically, it is preferable that the insulating layer 110a and the insulating layer 110e be each formed using one or both of a silicon nitride film and a silicon nitride oxide film.

The amount of hydrogen released from a silicon nitride film or a silicon nitride oxide film by heating can be adjusted by changing the film formation conditions (e.g., any one or more of power at the time of film formation (power density at the time of film formation), the pressure at the time of film formation, the kind of film formation gas, the flow rate ratio of the film formation gas, the film formation temperature, and the distance between the substrate and the electrode). Accordingly, a silicon nitride film or a silicon nitride oxide film can be suitably used as each of the insulating layer 110a and the insulating layer 110e. In addition, a silicon nitride film or a silicon nitride oxide film is also suitable as each of the insulating layer 110b and the insulating layer 110d.

For example, when an insulating layer is formed under conditions where the proportion of the flow rate of a NH₃ gas to the total flow rate of the film formation gas is high, the insulating layer can have a high hydrogen content. Accordingly, the amount of hydrogen in the insulating layer to be released by heating can be increased. By contrast, when an insulating layer is formed under conditions where the proportion of the flow rate of a NH₃ gas to the total flow rate of the film formation gas is low or a NH₃ gas is not used in the film formation gas, the amount of hydrogen in the insulating layer to be released by heating can be reduced. For example, the insulating layer 110a is preferably formed under conditions where the proportion of the flow rate of a NH₃ gas to the total flow rate of the film formation gas is higher than that for the insulating layer 110b. For example, the insulating layer 110e is preferably formed under conditions where the proportion of the flow rate of a NH₃ gas to the total flow rate of the film formation gas is higher than that for the insulating layer 110d.

For example, when an insulating layer is formed under conditions where the power density at the time of film formation is low, the hydrogen content in the insulating layer can be increased. For example, the insulating layer 110a is preferably formed under conditions where the power density at the time of film formation is lower than that for the insulating layer 110b. For example, the insulating layer 110e is preferably formed under conditions where the power density at the time of film formation is lower than that for the insulating layer 110d.

In the semiconductor layer 108, the region in contact with the insulating layer 110b preferably has higher resistance than the region in contact with the insulating layer 110a and lower resistance than the region in contact with the insulating layer 110c. In the semiconductor layer 108, the region in contact with the insulating layer 110b can be referred to as an n-type region or an n region. In the semiconductor layer 108, oxygen supplied from the insulating layer 110c sometimes reaches not only the region in contact with the insulating layer 110c but also the region in contact with the insulating layer 110b and the vicinity of this region. Likewise, in the semiconductor layer 108, hydrogen supplied from the insulating layer 110a sometimes reaches not only the region in contact with the insulating layer 110a but also the region in contact with the insulating layer 110b and the vicinity of this region. In the case where the insulating layer 110a is not provided, the region of the semiconductor layer 108 that is in contact with the insulating layer 110b and the vicinity of the region are supplied with oxygen from the insulating layer 110c to have relatively high resistance. When the semiconductor layer 108 includes such a high-resistance region between the channel formation region and the region that is in contact with the drain electrode, the on-state current of the transistor might decrease. In the case where the insulating layer 110a with a high hydrogen content is provided, by contrast, the hydrogen supply can inhibit an increase in the resistances of the region of the semiconductor layer 108 that is in contact with the insulating layer 110b and the vicinity of the region; thus, a reduction in the on-state current of the transistor can be inhibited, which is preferable.

It is preferable that, for example, the insulating layer 110a, the insulating layer 110b, the insulating layer 110d, and the insulating layer 110e be each formed using a silicon nitride film or a silicon nitride oxide film, and the insulating layer 110c be formed using a silicon oxide film or a silicon oxynitride film.

Alternatively, it is preferable that, for example, the insulating layer 110a and the insulating layer 110e be each formed using a silicon nitride film or a silicon nitride oxide film, the insulating layer 110b and the insulating layer 110d be each formed using an aluminum oxide film, and the insulating layer 110c be formed using a silicon oxide film or a silicon oxynitride film.

As described above, when the semiconductor layer 108 is provided in contact with the insulating layer 110a to the insulating layer 110e, the channel formation region of the semiconductor layer 108 can be provided at a position to which a gate electric field is sufficiently applied. Furthermore, the resistance of the offset region of the semiconductor layer 108 can be reduced. Thus, the field-effect mobility of the transistor can be inhibited from decreasing, and the transistor can have favorable electrical characteristics.

In the semiconductor layer 108, the region in contact with the insulating layer 110 is provided between the region in contact with the conductive layer 112a and the region in contact with the conductive layer 112b. The insulating layer 110 has a structure in which the insulating layer 110b and the insulating layer 110d having a low hydrogen content are respectively provided below and above the insulating layer 110c so that the insulating layer 110c is held therebetween, and the insulating layer 110a and the insulating layer 110e having a high hydrogen content are respectively provided below and above this three-layer structure so that the three-layer structure is held therebetween. That is, the structure of the insulating layer 110 has symmetry with respect to a line perpendicular to the vertical direction (the stacking direction). This enables the semiconductor layer 108 to have an appropriate carrier concentration distribution in the channel length direction. Accordingly, the transistor can have favorable electrical characteristics and high reliability.

The hydrogen contents of the insulating layers 110a, 110b, 110d, and 110e are preferably compared through SIMS analysis because the hydrogen content is lower than the content of each of the main components (e.g., nitrogen and silicon in a silicon nitride layer) in each of the insulating layers.

Even when layers having the same main component (e.g., silicon nitride layers) are used as the insulating layer 110a and the insulating layer 110b, these insulating layers can be distinguished from each other through cross-sectional observation in some cases. For example, in a transmitted electron (TE) image obtained by a scanning transmission electron microscope (STEM: Scanning Transmission Electron Microscopy), the insulating layer 110a is observed as having higher lightness than the insulating layer 110b. Likewise, even when layers having the same main component are used as the insulating layer 110d and the insulating layer 110e, these insulating layers can be distinguished from each other through cross-sectional observation in some cases. For example, in a TE image obtained by STEM, the insulating layer 110e is observed as having higher lightness than the insulating layer 110d.

As illustrated in FIG. 8A, a shortest distance T1 from the top surface of the conductive layer 112a to the portion of the semiconductor layer 108 that is in contact with the insulating layer 110c is longer than a shortest distance T2 from the top surface of the conductive layer 112a to the bottom surface of the conductive layer 104. That is, in a cross-sectional view, the bottom surface of the conductive layer 104 inside the opening 141 is positioned at a lower level (the substrate 102 side) than the portion of the insulating layer 110c that is in contact with the semiconductor layer 108 is. This makes it possible to ensure application of a gate electric field to the channel formation region of the semiconductor layer 108, whereby the transistor can have favorable electrical characteristics.

It can be said that the shortest distance TI depends on the sum of the thickness of the insulating layer 110a and the thickness of the insulating layer 110b, and the shortest distance T2 depends on the sum of the thickness of the semiconductor layer 108 and the thickness of the insulating layer 106. Accordingly, it can be said that the sum of the thickness of the insulating layer 110a and the thickness of the insulating layer 110b is preferably larger than the sum of the thickness of the semiconductor layer 108 and the thickness of the insulating layer 106. The shortest distance Tl is preferably more than or equal to 0.5 times the shortest distance T2, further preferably more than or equal to 1.0 times the shortest distance T2, still further preferably more than 1.0 times the shortest distance T2.

The thickness of the insulating layer 110a can be set such that the above relationship between the shortest distances T1 and T2 is established. The thickness of each of the insulating layer 110a and the insulating layer 110e is preferably greater than or equal to 10 nm and less than or equal to 200 nm, further preferably greater than or equal to 20 nm and less than or equal to 150 nm, still further preferably greater than or equal to 50 nm and less than or equal to 100 nm. The insulating layer 110a and the insulating layer 110e may have the same thickness or different thicknesses.

The channel length, the channel width, and the like of the transistor 100B are described with reference to FIG. 8A. The description of contents similar to those of the transistor 100 is omitted in some cases.

In the semiconductor layer 108, the region in contact with the insulating layer 110a and the region in contact with the insulating layer 110e each function as a low-resistance region (also referred to as an n⁺-type region or an n⁺region), and the region that is in contact with the insulating layer 110c functions as a channel formation region. In the semiconductor layer 108, the region in contact with the insulating layer 110b has higher resistance than the region in contact with the insulating layer 110a and lower resistance than the region in contact with the insulating layer 110c, in some cases. In the semiconductor layer 108, the region in contact with the insulating layer 110d has higher resistance than the region in contact with the insulating layer 110e and lower resistance than the region in contact with the insulating layer 110c, in some cases. In this embodiment, the region of the semiconductor layer 108 that is in contact with the insulating layer 110b and the region of the semiconductor layer 108 that is in contact with the insulating layer 110d are described as not being included in the channel formation region; however, these regions can be included in the channel formation region. Alternatively, the region of the semiconductor layer 108 that is in contact with the insulating layer 110b and the region of the semiconductor layer 108 that is in contact with the insulating layer 110d can be referred to as low-resistance regions. Note that the low-resistance region can also function as a source region or a drain region.

In FIG. 8A, the channel length L100 of the transistor 100B is indicated by a dashed double-headed arrow. It can be said that in a cross-sectional view, the channel length L100 is the shortest distance between, in the semiconductor layer 108, a portion in contact with the insulating layer 110b and a portion in contact with the insulating layer 110d.

The channel length L100 can be controlled by adjusting the thickness T110 of the insulating layer 110c and the angle 0110. Note that in FIG. 8A, the thickness T110 of the insulating layer 110c is indicated by the dashed-dotted double-headed arrow.

In the case where, in the semiconductor layer 108, the region in contact with the insulating layer 110b and the region in contact with the insulating layer 110d are included in the channel formation region, it can be said that the channel length L100 is the shortest distance between, in the semiconductor layer 108, the portion in contact with the insulating layer 110a and the portion in contact with the insulating layer 110e in a cross-sectional view. The channel length L100 corresponds to the sum of the lengths of side surfaces of the insulating layers 110b, 110c, and 110d on the opening 141 side in a cross-sectional view.

In FIG. 8A, the diameter D143 of the opening 143 is indicated by the dashed-two dotted double-headed arrow. In the example illustrated in FIG. 1A, the top-view shape of each of the opening 141 and the opening 143 is a circle having the diameter D143. Here, the channel width W100 of the transistor 100B is equal to the length of the circumference of this circle.

The above description can be referred to for the channel length L100, the thickness T110, the angle θ110, the diameter D143, and the channel width W100.

### Transistor 100C

FIG. 9A illustrates a top view of the transistor 100C. FIG. 9B is a cross-sectional view along dashed-dotted line A1-A2 in FIG. 9A. FIG. 9C is a cross-sectional view along dashed-dotted line B1-B2 in FIG. 9A.

The transistor 100C is different from the transistor 100B mainly in that the opening 143 is larger than the opening 141 in a top view.

The end portion of the conductive layer 112b on the opening 143 side is positioned outside the end portion of the insulating layer 110 on the opening 141 side.

The semiconductor layer 108 is in contact with the top surface and the side surface of the conductive layer 112b, the top surface and a side surface of the insulating layer 110d, the side surface of the insulating layer 110c, the side surface of the insulating layer 110b, the side surface of the insulating layer 110a, and the top surface of the conductive layer 112a.

### Transistor 100d

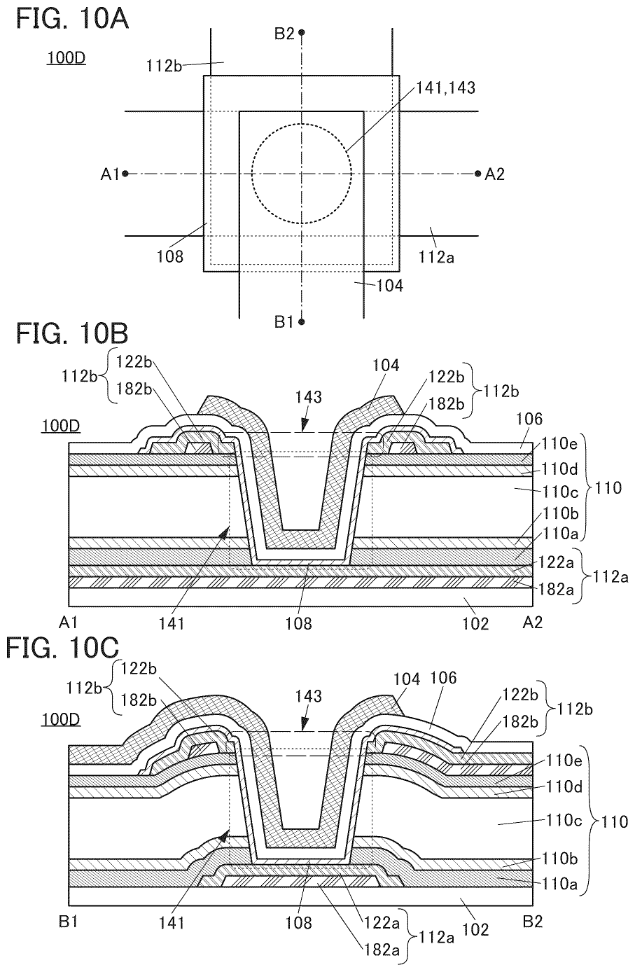

FIG. 10A illustrates a top view of a transistor 100D. FIG. 10B is a cross-sectional view along dashed-dotted line A1-A2 in FIG. 10A, and FIG. 10C is a cross-sectional view along dashed-dotted line B1-B2 in FIG. 10A.

The transistor 100D is different from the transistor 100B in that the semiconductor layer 108 is in contact with the side surface of the conductive layer 112b on the side not facing the opening 143 (the side opposite to the opening 143).

There is no particular limitation on the top-view shapes and sizes of the semiconductor layer 108 and the conductive layer 112b. The end portion of the semiconductor layer 108 may be aligned with the end portion of the conductive layer 112b, positioned inside the end portion of the conductive layer 112b, or positioned outside the end portion of the conductive layer 112b.

As illustrated in FIG. 10B, the semiconductor layer 108 of the transistor 100D covers the side surface of the conductive layer 112b on the side not facing the opening 143. The end portion of the semiconductor layer 108 is positioned outside the end portion of the conductive layer 112b and is over and in contact with the insulating layer 110. Furthermore, the end portion on the left side in FIG. 10C of the semiconductor layer 108 covers the end portion of the conductive layer 112b and is over and in contact with the insulating layer 110. The end portion on the right side in FIG. 10C of the semiconductor layer 108 is over and in contact with the conductive layer 112b.

### Transistor 100E

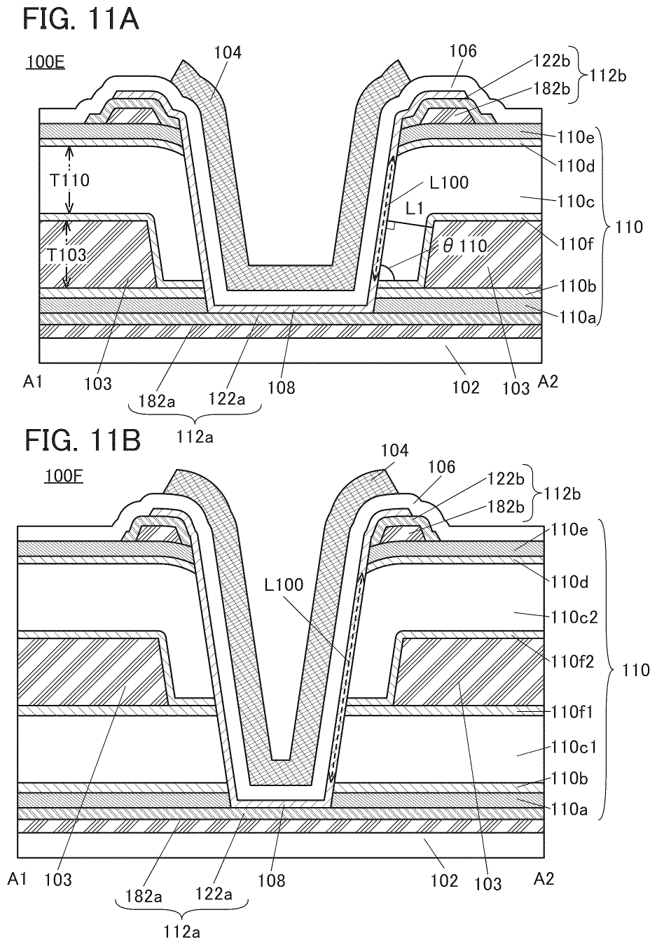

FIG. 11A illustrates a cross-sectional view of a transistor 100E.

The transistor 100E is different from the transistor 100B mainly in that a conductive layer 103 is provided over the conductive layer 112a and the insulating layer 110 has a six-layer structure.

The conductive layer 103 is positioned over the insulating layer 110b. The conductive layer 112a and the conductive layer 103 are electrically insulated from each other by the insulating layer 110a and the insulating layer 110b. The conductive layer 103 is provided with an opening at position that overlaps with the conductive layer 112a.

The conductive layer 103 may be electrically connected to the conductive layer 112a. For example, the conductive layer 112a and the conductive layer 103 may be in contact with each other through an opening provided in the insulating layer 110a and the insulating layer 110b. Alternatively, the conductive layer 103 may be provided over and in contact with the conductive layer 112a without the insulating layer 110a and the insulating layer 110b provided. In that case, the insulating layer 110 preferably includes at least an insulating layer 110f and the insulating layers 110c and 110d, and further preferably also includes the insulating layer 110e.

The insulating layer 110 includes the insulating layer 110a over the conductive layer 112a, the insulating layer 110b over the insulating layer 110a, an insulating layer 110f over the insulating layer 110b and the conductive layer 103, the insulating layer 110c over the insulating layer 110f, the insulating layer 110d over the insulating layer 110c, and the insulating layer 110e over the insulating layer 110d.

The insulating layer 110f covers the top surface and the side surface of the conductive layer 103. The insulating layer 110f is provided to cover part of the opening of the conductive layer 103. The insulating layer 110f is in contact with the insulating layer 110b via the opening.

The insulating layer 110f preferably has a structure similar to that of the insulating layer 110b or 110d. Specifically, a film that does not easily allow diffusion of oxygen is preferably used for the insulating layer 110f. For the insulating layer 110f, a film that does not easily allow diffusion of hydrogen is preferably used.

The semiconductor layer 108 of the transistor 100E has a region overlapping with the conductive layer 104 with the insulating layer 106 therebetween and overlapping with the conductive layer 103 with part of the insulating layer 110 (specifically, the insulating layer 110f and the insulating layer 110c) therebetween. In other words, a region of the semiconductor layer 108 is interposed between the conductive layer 104 and the conductive layer 103 with the insulating layer 106 positioned between the region and the conductive layer 104 and with part of the insulating layer 110 (specifically, the insulating layer 110f and the insulating layer 110c) positioned between the region and the conductive layer 103.

The conductive layer 103 functions as a back gate electrode of the transistor 100E. Part of the insulating layer 110 functions as a back gate insulating layer of the transistor 100E.

Since a back gate electrode is provided in the transistor 100E, the potential of the semiconductor layer 108 on the back gate side (also referred to as a back channel) can be fixed. Thus, the saturation of the Id-Vd characteristics of the transistor 100E can be improved.

In this specification and the like, the state where the change in current is small (i.e., the slope is gentle) in a saturation region of the Id-Vd characteristics of a transistor is sometimes described using the expression “favorable saturation”.

Since the transistor 100E includes the back gate electrode, the potential of the back channel of the semiconductor layer 108 can be fixed, so that a negative shift of the threshold voltage can be inhibited. Accordingly, the transistor can have normally-off characteristics (i.e., a positive threshold voltage value).

FIG. 11A illustrates an example in which the thickness of the insulating layer 110b is uniform regardless of the place. The thickness of the insulating layer 110b sometimes differ between a region overlapping with the conductive layer 103 and a region not overlapping with the conductive layer 103. For example, the insulating layer 110b in the region not overlapping with the conductive layer 103 is sometimes partly removed to have a reduced thickness at the time of processing of a film to be the conductive layer 103.

In the semiconductor layer 108, the region in contact with the conductive layer 112a functions as one of a source region and a drain region, and the region in contact with the conductive layer 112b functions as the other of the source region and the drain region. In the semiconductor layer 108, the region in contact with the insulating layer 110a and the region in contact with the insulating layer 110e function as low-resistance regions. In the semiconductor layer 108, at least the region in contact with the insulating layer 110c functions as a channel formation region. In this embodiment, the region of the semiconductor layer 108 that is in contact with the insulating layer 110b, 110d, and 110f is described as not being included in the channel formation region; however, the region may be included in the channel formation region.

In FIG. 11A, the channel length L100 of the transistor 100E is indicated by a dashed double-headed arrow. It can be said that in a cross-sectional view, the channel length L100 is the shortest distance between, in the semiconductor layer 108, a portion in contact with the insulating layer 110f and a portion in contact with the insulating layer 110d.

In general, a transistor with a short channel length tends to have poor saturation of Id-Vd characteristics; however, the transistor 100E can have favorable saturation because of including the back gate.

The favorable ranges of the values of the channel length L100, the thickness T110, and the angle θ110 are as described above.

A thickness T103 of the conductive layer 103 is preferably more than or equal to 0.5 times the channel length L100, further preferably more than or equal to 1.0 times the channel length L100, still further preferably more than 1.0 times the channel length L100. In that case, the region of the semiconductor layer 108 that overlaps with the conductive layer 104 with the insulating layer 106 therebetween and overlaps with the conductive layer 103 with the insulating layer 110 therebetween can be wide. As a result, the electric field applied to the back channel of the semiconductor layer 108 can be controlled more reliably.

In a region of the transistor 100E, the conductive layer 103, the insulating layer 110, the semiconductor layer 108, the insulating layer 106, and the conductive layer 104 are stacked in this order in one direction with no any other layer provided between these layers. The direction can be perpendicular to the channel length L100 direction. When the above region is wide, the electric field applied to the back channel of the semiconductor layer 108 can be controlled more reliably.

A distance L1, which is the shortest distance between the conductive layer 103 and the semiconductor layer 108, is preferably shorter than the channel length L100, further preferably shorter than or equal to 0.5 times the channel length L100, still further preferably shorter than or equal to 0.1 times the channel length L100. The shorter the distance between the conductive layer 103 and the semiconductor layer 108 is, the more favorable the saturation of the Id-Vd characteristics of the transistor 100E can be.

In a cross-sectional view, the shortest distances between the conductive layer 103 and the semiconductor layer 108 may be different between the right side and the left side of the opening in the insulating layer 110. In that case, the distance LI satisfies the above-described range preferably on at least one of the left side and the right side of the opening, further preferably on both the left side and the right side of the opening. In a given cross section, the shortest distance between the conductive layer 103 and the semiconductor layer 108 on the left side of the opening is preferably greater than or equal to 50% and less than or equal to 150%, further preferably greater than or equal to 30% and less than or equal to 130%, still further preferably greater than or equal to 10% and less than or equal to 110% of the shortest distance on the right side of the opening.

As illustrated in FIG. 11A, the channel length L100 is sometimes affected by the thickness T103 of the conductive layer 103, depending on the shortest distance L1 between the conductive layer 103 and the semiconductor layer 108.

The channel length L100 of the transistor 100E corresponds to the length of a side surface of the insulating layer 110c on the opening side in a cross-sectional view. When the distance between the conductive layer 103 and the semiconductor layer 108 is made close (i.e., when the distance L1 is made short), the channel length L100 may be large, being affected by the thickness of the conductive layer 103. Thus, the channel length L100 can be more than or equal to 1 times, 1.5 times, or 2 times the thickness T110.

The conductive layer 103 can have a single-layer structure or a stacked-layer structure of two or more layers. For the conductive layer 103, a material that can be used for the conductive layer 112a, the conductive layer 112b, and the conductive layer 104 can be used.

### Transistor 100F

FIG. 11B illustrates a cross-sectional view of a transistor 100F.

The transistor 100F is different from the transistor 100E mainly in that the insulating layer 110 has an eight-layer structure.

The insulating layer 110 includes the insulating layer 110a over the conductive layer 112a, the insulating layer 110b over the insulating layer 110a, an insulating layer 110c1 over the insulating layer 110b, an insulating layer 110f1 over the insulating layer 110c1, an insulating layer 110f2 over the insulating layer 110f1 and the conductive layer 103, an insulating layer 110c2 over the insulating layer 110f2, the insulating layer 110d over the insulating layer 110c2, and the insulating layer 110e over the insulating layer 110d.

Each of the insulating layer 110c1 and the insulating layer 110c2 can employ a structure similar to the structure applicable to the insulating layer 110c. Specifically, it is preferable that each of the insulating layer 110c1 and the insulating layer 110c2 be formed using a layer including oxygen and include a region having a higher oxygen content than at least one of the insulating layers 110a, 110b, 110d, 110e, 110f1, and 110f2.

Each of the insulating layer 110f1 and the insulating layer 110f2 can employ a structure similar to the structure applicable to the insulating layer 110f. Specifically, for each of the insulating layer 110f1 and the insulating layer 110f2, a film that does not easily allow diffusion of oxygen is preferably used. For each of the insulating layer 110f1 and the insulating layer 110f2, a film that does not easily allow diffusion of hydrogen is preferably used.

The above-described structure can be applied to each of the insulating layers 110a, 110b, 110d, and 110e.

It can be said that in FIG. 11B, the channel length L100 is the shortest distance between, in the semiconductor layer 108, the portion in contact with the insulating layer 110b and the portion in contact with the insulating layer 110d.

In the above-described structure, the upper part and the lower part of the insulating layer 110 can be symmetric with respect to the conductive layer 103. Furthermore, both the insulating layers 110c1 and 110c2 can supply oxygen to the semiconductor layer 108; thus, the transistor can have improved characteristics.

### Transistor 100g

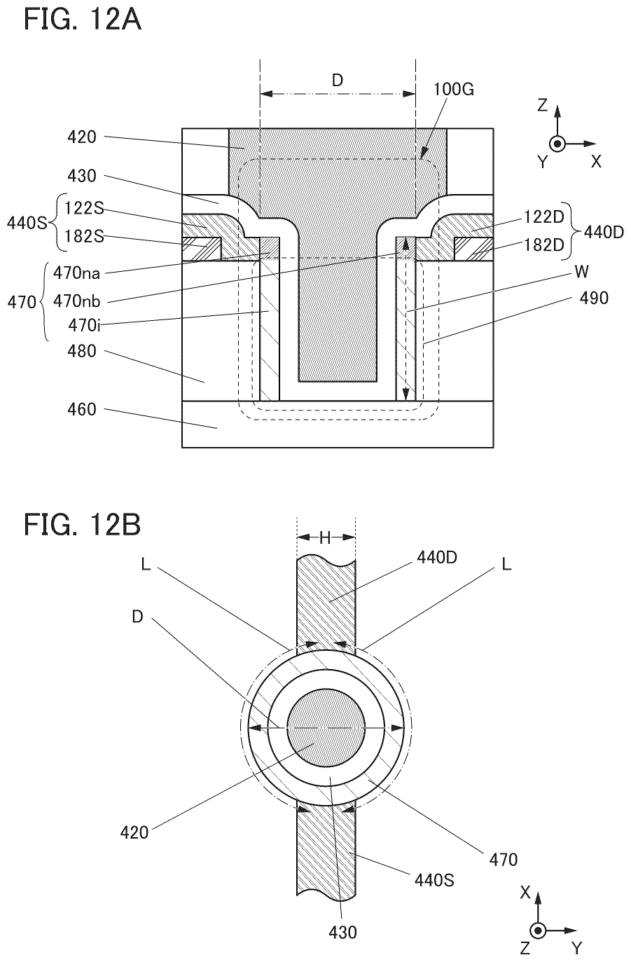

FIG. 12A illustrates a cross-sectional view of a transistor 100G on the XZ plane, and FIG. 12B illustrates a cross-sectional view of the transistor 100G on the XY plane.

The transistor 100G includes an oxide semiconductor layer 470, an insulating layer 430, a conductive layer 420, a wiring 440S, and a wiring 440D. The insulating layer 430 functions as a gate insulating layer, the conductive layer 420 functions as a gate electrode, the wiring 440S functions as a source electrode, and the wiring 440D functions as a drain electrode.

The wiring 440S includes a conductive layer 182S and a conductive layer 122S over the conductive layer 182S. The conductive layer 122S is provided in contact with the top surface and the side surface of the conductive layer 182S and to cover the top surface and the side surface thereof. The conductive layer 122S is in contact with the oxide semiconductor layer 470.

The wiring 440D includes a conductive layer 182D and a conductive layer 122D over the conductive layer 182D. The conductive layer 122D is provided in contact with the top surface and the side surface of the conductive layer 182D and to cover the top surface and the side surface thereof. The conductive layer 122D is in contact with the oxide semiconductor layer 470.

For the materials that can be used for the layers, the description of the transistor 100 can be referred to. Specifically, the oxide semiconductor layer 470 corresponds to the semiconductor layer 108, the insulating layer 430 corresponds to the insulating layer 106, the conductive layer 420 corresponds to the conductive layer 104, and the wiring 440S and the wiring 440D correspond to the conductive layer 112a and the conductive layer 112b.

An opening portion 490 reaching an insulating layer 460 is provided in an insulating layer 480. The opening portion 490 has a pillar shape with a substantially circular top surface. With this structure, the transistor 100G can be miniaturized or highly integrated. Note that the side surface of the opening portion 490 is preferably perpendicular to the top surface of the insulating layer 480.

The oxide semiconductor layer 470 has a ring shape. Specifically, the oxide semiconductor layer 470 includes a region in contact with the side surface of the wiring 440S, a region in contact with the side surface of the wiring 440D, and a region in contact with the side surface of the insulating layer 480 in the opening portion 490. Here, the oxide semiconductor layer 470 is not in contact with the top surfaces of the wiring 440S and the wiring 440D. The oxide semiconductor layer 470 having such a shape can be formed by processing by anisotropic etching, for example.

The insulating layer 430 is placed so as to at least partly cover the opening portion 490. The conductive layer 420 is placed such that at least part of the conductive layer 420 is positioned in the opening portion 490. Although FIG. 12A illustrates an example in which the conductive layer 420 is provided to be embedded in the opening portion 490, the conductive layer 420 may be provided along the sidewall of the opening portion 490 like the conductive layer 104.

As illustrated in FIG. 12A, the oxide semiconductor layer 470 includes a region 470i, a region 470na over the region 470i, and a region 470nb over the region 470i.

The region 470na is a region in contact with the wiring 440S in the oxide semiconductor layer 470. At least part of the region 470na functions as a source region of the transistor 100G. The region 470nb is a region in contact with the wiring 440D in the oxide semiconductor layer 470. At least part of the region 470 nb functions as a drain region of the transistor 100G.

At least part of the region 470i functions as a channel formation region of the transistor 100G. It can be said that the channel formation region of the transistor 100G is positioned in a region in contact with the insulating layer 480 or a region in the vicinity thereof in the oxide semiconductor layer 470.

Thus, the channel formation region, the source region, and the drain region can be formed in the opening portion 490. Thus, the area occupied by the transistor 100G can be reduced as compared with a conventional transistor in which the channel formation region, the source region, and the drain region are provided separately on the XY plane. Accordingly, the pixel density can be increased.

As illustrated in FIG. 12B, a width H of the wiring 440S and the wiring 440D is smaller than a maximum width D of the opening portion 490. In that case, the circumferential direction of the opening portion 490 corresponds to the channel length direction of the transistor 100G. Here, since the oxide semiconductor layer 470 has a ring shape, there are two kinds of current paths (i.e., channels) from the wiring 440S to the wiring 440D. Note that the oxide semiconductor layer 470 does not necessarily have a ring shape and may have a structure in contact with both the wiring 440S and the wiring 440D.

The channel length can be controlled by the shape and size of the opening portion 490. For example, in the case where the channel length is desired to be large, the perimeter of the opening portion 490 is made long. Although an example in which the opening portion 490 is circular in the plan view is described in this embodiment, the present invention is not limited thereto. For example, the opening portion 490 can have an elliptical shape or a quadrangular shape with rounded corners besides the circular shape in the plan view. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180 degrees, such as a star polygonal shape, the channel width can be increased. Alternatively, an elliptical shape, a polygonal shape with rounded corners, a closed curve in which a straight line and a curve are combined, or the like can be employed. In that case, the maximum width of the opening portion 490 can be calculated as appropriate in accordance with the shape of the uppermost portion of the opening portion 490. For example, in the case where the opening portion is square or rectangular in the plan view, the maximum width of the opening portion 490 can be the length of a diagonal line of the uppermost portion of the opening portion 490.

As illustrated in FIG. 12A, the height of the oxide semiconductor layer 470 is a channel width W of the transistor 100G. Thus, the channel width W of the transistor 100G can be controlled by the thickness of the insulating layer 480. For example, the transistor 100G can have an extremely small channel width smaller than or equal to the light exposure limit of photolithography (e.g., smaller than or equal to 60 nm, smaller than or equal to 50 nm, smaller than or equal to 40 nm, smaller than or equal to 30 nm, smaller than or equal to 20 nm, or smaller than or equal to 10 nm, and larger than or equal to 1 nm, or larger than or equal to 5 nm).

The transistor 100 to the transistor 100F described above are each a transistor having an extremely small channel length and capable of having a large channel width, and thus can each have a high on-state current. Meanwhile, the transistor 100G is a transistor having an extremely small channel width and capable of having a large channel length; thus, the transistor 100G can have an appropriate on-state current and can be easily designed. Some of the manufacturing steps of the transistor 100G can also serve as some of the manufacturing steps of the transistor 100 to the transistor 100F, and the transistor 100G and the transistor 100 to the transistor 100F can be formed separately over the same substrate. For example, in a display device, the transistor 100G can be used as a driving transistor for controlling a current flowing through a light-emitting element, and any of the transistor 100 to the transistor 100F can be used as a transistor functioning as a switch.

### Specific Example of Semiconductor Device

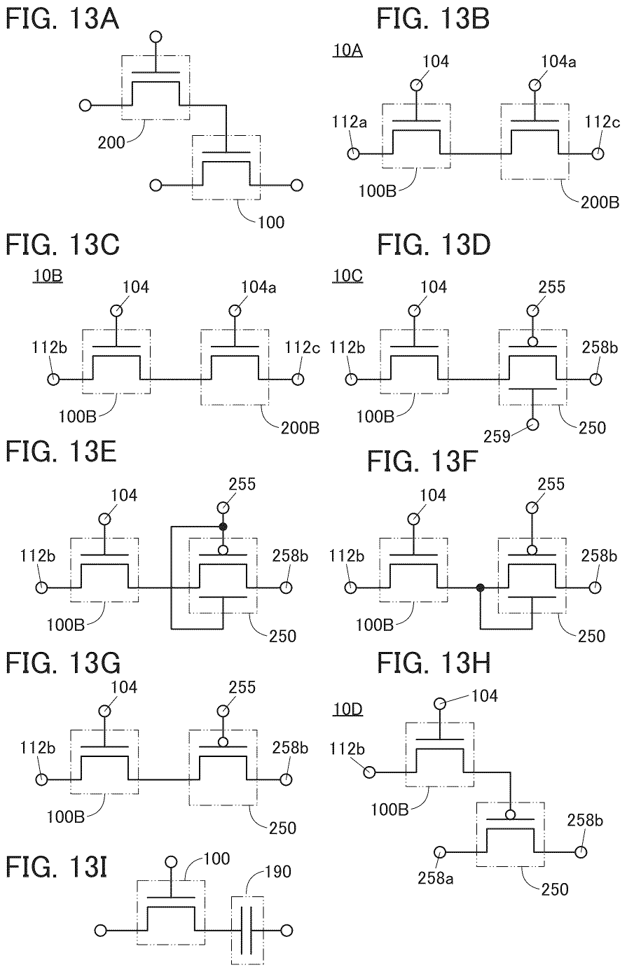

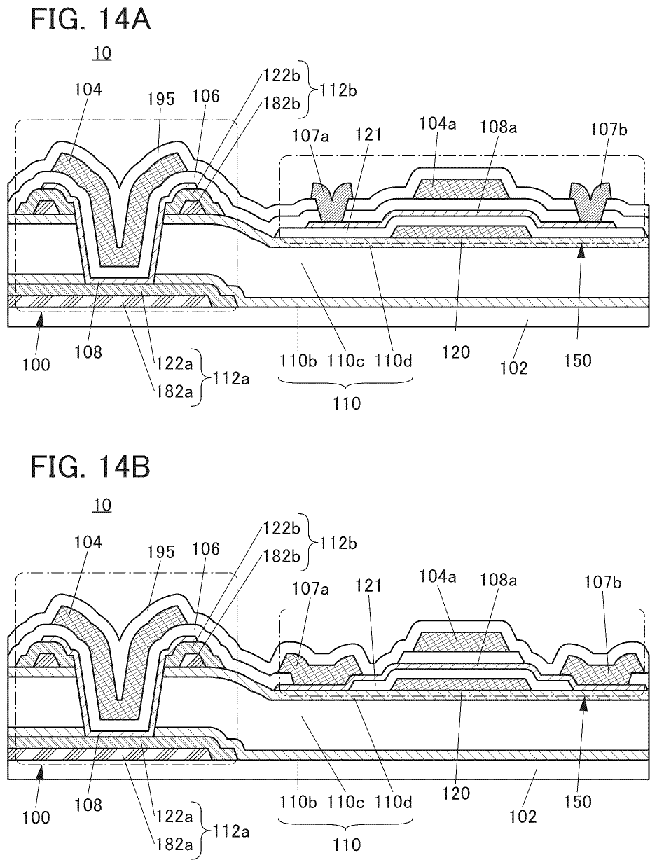

FIG. 13 illustrates circuit diagrams of semiconductor devices of embodiments of the present invention. FIG. 14 to FIG. 18 illustrate top views and cross-sectional views of the semiconductor devices of embodiments of the present invention. In the following description, the transistor 100 or the transistor 100B is mainly used as an example of a transistor included in the semiconductor devices of embodiments of the present invention. A semiconductor device of one embodiment of the present invention may include any one or more of the transistor 100A and the transistor 100C to the transistor 100G described above, instead of the transistor 100 or the transistor 100B.

The semiconductor device of one embodiment of the present invention includes at least two transistors, and any of a gate, a source, and a drain of one transistor is electrically connected to any of a gate, a source, and a drain of another transistor.

For example, the semiconductor device in FIG. 13A includes the transistor 100 and a transistor 200. One of a source and a drain of the transistor 200 is electrically connected to a gate of the transistor 100.

Although each of the transistors illustrated in FIG. 13A to FIG. 13C is an n-channel transistor, one embodiment of the present invention is not limited thereto. One or both of the transistor 100 (100B) and the transistor 200 (200B) may be a p-channel transistor(s).

### Semiconductor Device 10

FIG. 14A and FIG. 14B illustrate cross-sectional views of a semiconductor device 10. The semiconductor device 10 includes the transistor 100 and a transistor 150. In the semiconductor device 10, any of the gate, the source, and the drain of the transistor 100 can be electrically connected to a gate, a source, or a drain of the transistor 150.

The transistor 100 is provided over the substrate 102. The transistor 100 has the above-described structure; thus, detailed description thereof is omitted (see FIG. 1 to FIG. 2).

The transistor 150 includes a conductive layer 120, an insulating layer 121, a semiconductor layer 108a, the insulating layer 106, a conductive layer 107a, a conductive layer 107b, and a conductive layer 104a. The layers forming the transistor 150 may each have a single-layer structure or a stacked-layer structure.

The conductive layer 120 functions as a back gate electrode of the transistor 150. Here, the back gate electrode of the transistor 150 may be formed using the same material in the same step as the conductive layer 112a. Accordingly, the number of manufacturing steps of the semiconductor device 10 can be reduced. Meanwhile, the conductive layer 120 provided over the insulating layer 110 is positioned closer to the semiconductor layer 108a than a conductive layer that can be formed in the same step as the conductive layer 112a is. Accordingly, an electric field is easily applied to the semiconductor layer 108a, whereby favorable electrical characteristics can be obtained. The transistor 150 does not necessarily include a back gate electrode.

The insulating layer 121 is provided to cover the top surface and the side surface of the conductive layer 120. The insulating layer 121 functions as a back gate insulating layer of the transistor 150. The insulating layer 121 is a layer in contact with a channel formation region in the semiconductor layer 108a and thus is preferably an insulating layer including oxygen. A material suitable for the insulating layer 110c can be used for the insulating layer 121, for example.

The semiconductor layer 108a is provided over the insulating layer 121. The semiconductor layer 108a includes a region overlapping with the conductive layer 120 with the insulating layer 121 therebetween.

FIG. 14A illustrates an example in which an end portion of the semiconductor layer 108a is positioned on the top surface of the insulating layer 121, and FIG. 14B illustrates an example in which the semiconductor layer 108a covers the top surface and the side surface of the insulating layer 121.

The semiconductor layer 108a can be formed using the same material in the same step as the semiconductor layer 108.

Here, for the semiconductor layer 108 and the semiconductor layer 108a, the same material or different materials may be used. For the semiconductor layer 108 and the semiconductor layer 108a, materials with different compositions may be used. For example, In—Ga—Zn oxides having the same composition may be used for the semiconductor layer 108 and the semiconductor layer 108a. In—Ga—Zn oxides may be used for the semiconductor layer 108 and the semiconductor layer 108a; the proportion of the number of In atoms in one of the In—Ga—Zn oxides may be higher than that in the other. An In—Ga—Zn oxide may be used for one of the semiconductor layer 108 and the semiconductor layer 108a and an In—Zn oxide may be used for the other.

The insulating layer 106 is provided to cover the insulating layer 121 and the semiconductor layer 108a. The insulating layer 106 functions as a gate insulating layer of the transistor 150.

The conductive layer 104a is provided over the insulating layer 106. The conductive layer 104a includes a region overlapping with the semiconductor layer 108a with the insulating layer 106 therebetween. The conductive layer 104a functions as a gate electrode of the transistor 150. The conductive layer 104a and the conductive layer 104 can be formed using the same material in the same step.

In FIG. 14A, an insulating layer 195 is provided to cover the conductive layer 104a, and the conductive layer 107a and the conductive layer 107b are provided over the insulating layer 195. The conductive layer 107a and the conductive layer 107b are in contact with the semiconductor layer 108a via openings provided in the insulating layer 106 and the insulating layer 195.

FIG. 14B illustrates an example in which the conductive layer 107a and the conductive layer 107b are formed using the same material in the same step as the conductive layer 104a and the conductive layer 104. The conductive layer 107a and the conductive layer 107b are in contact with the semiconductor layer 108a via openings provided in the insulating layer 106.

One of the conductive layer 107a and the conductive layer 107b functions as the source electrode of the transistor 150 and the other functions as the drain electrode of the transistor 150.

The insulating layer 195 functions as a protective layer. For the insulating layer 195, a material that does not easily allow diffusion of impurities is preferably used. Providing the insulating layer 195 can effectively inhibit diffusion of impurities into the transistors from the outside and increase the reliability of the semiconductor device. Examples of the impurities include water and hydrogen. The insulating layer 195 includes, for example, one or both of an inorganic insulating layer and an organic insulating layer. The insulating layer 195 may have a stacked-layer structure of an inorganic insulating layer and an organic insulating layer.

Examples of the inorganic insulating film usable for the insulating layer 195 include an oxide insulating film, a nitride insulating film, an oxynitride insulating film, and a nitride oxide insulating film. Specific examples of these inorganic insulating films are as listed in the description of the insulating layer 110. More specifically, one or more of silicon nitride, silicon nitride oxide, silicon oxynitride, aluminum oxide, aluminum oxynitride, aluminum nitride, hafnium oxide, and hafnium aluminate can be used for the insulating layer 195. One or more of an acrylic resin and a polyimide resin, which are organic materials, can be used for the insulating layer 195, for example.

The conductive layer 104a may be connected to the conductive layer 120 via an opening provided in the insulating layer 106 and the insulating layer 110. Accordingly, the same potential is supplied to the gate and the back gate, so that the amount of current that can flow through the transistor 150 in an on state can be increased. Furthermore, the amount of current flowing through the transistor 150 in an off state can be reduced.

The conductive layer 104a is not necessarily electrically connected to the conductive layer 120. For example, a constant potential is supplied to the back gate, and a signal for driving the transistor 150 can be supplied to the gate. Accordingly, the potential supplied to the back gate enables control of the threshold voltage in driving the transistor 150.

The conductive layer 107a or the conductive layer 107b may be connected to the conductive layer 120 via an opening provided in the insulating layer 106 and the insulating layer 110. The same potential is supplied to the source and the back gate, whereby the potential of the back channel can be stabilized and the saturation in the Id-Vd characteristics of the transistor can be improved.

The transistor 150 is what is called a top-gate transistor including the gate electrode above the semiconductor layer 108a. For example, an impurity element is added to the semiconductor layer 108a with the conductive layer 104a functioning as the gate electrode used as a mask, so that a source region and a drain region can be formed in a self-aligned manner. The transistor 150 can be referred to as a TGSA (Top Gate Self-Aligned) transistor.

In the transistor 150, the channel length can be controlled by the width of the conductive layer 104a in the channel length direction. Accordingly, the channel length of the transistor 150 is greater than or equal to the resolution limit of a light exposure apparatus used for manufacturing the transistor. A large channel length leads to a transistor with high saturation characteristics.

In manufacturing the semiconductor device 10, the transistor 100 with a small channel length and the transistor 150 with a large channel length can be formed over the same substrate by the formation steps some of which are shared. For example, the transistor 100 is used as a transistor required to have a high on-state current and the transistor 150 is used as a transistor required to have high saturation characteristics, whereby a high-performance semiconductor device can be provided.

### Semiconductor Device 10a

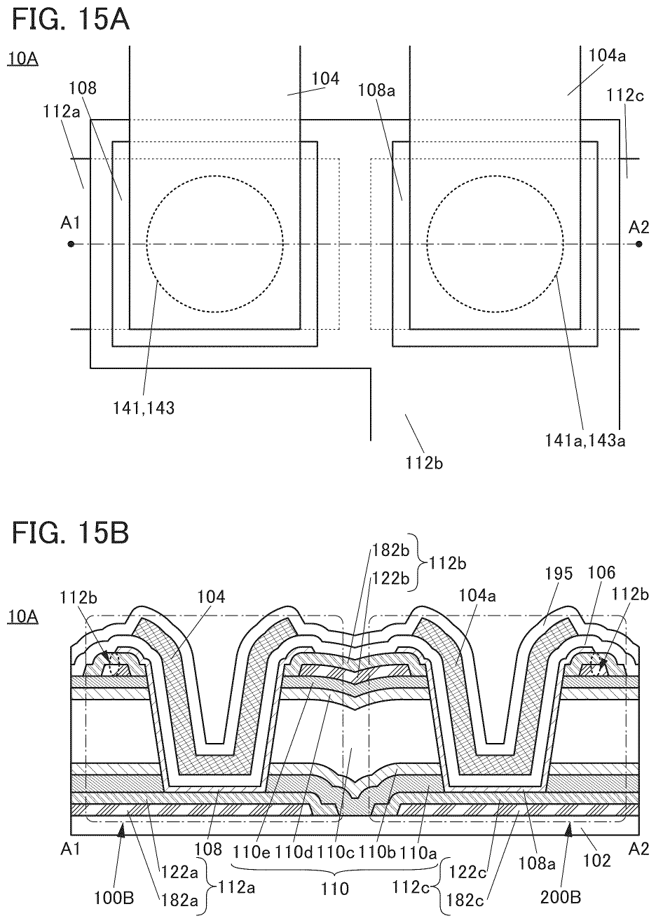

FIG. 13B illustrates a circuit diagram of a semiconductor device 10A. FIG. 15A illustrates a top view of the semiconductor device 10A. FIG. 15B is a cross-sectional view taken along dashed-dotted line A1-A2 in FIG. 15A.

The semiconductor device 10A includes the transistor 100B and the transistor 200B. The other of a source and a drain of the transistor 200B is electrically connected to the other of a source and a drain of the transistor 100B.

The transistor 100B and the transistor 200B are each provided over the substrate 102.

The transistor 100B has the above-described structure; thus, detailed description thereof is omitted (see FIG. 8).

The transistor 200B includes a conductive layer 112c (a conductive layer 182c and a conductive layer 122c), the insulating layer 110 (the insulating layers 110a, 110b, 110c, 110d, and 110e), the semiconductor layer 108a, the conductive layer 112b (the conductive layer 182b and the conductive layer 122b), the insulating layer 106, and the conductive layer 104a.

The conductive layer 112c functions as one of a source electrode and a drain electrode of the transistor 200B. The conductive layer 112c and the conductive layer 112a can be formed using the same material in the same step.

The semiconductor layer 108a and the semiconductor layer 108 can be formed using the same material in the same step. Alternatively, the semiconductor layer 108 and the semiconductor layer 108a may be formed using different materials in different steps. For the structures of the semiconductor layer 108 and the semiconductor layer 108a, the description of the semiconductor layer of the semiconductor device 10 can also be referred to.

The conductive layer 112b functions as the other of a source electrode and a drain electrode of the transistor 100B and the other of the source electrode and the drain electrode of the transistor 200B. Since the transistor 100B and the transistor 200B share the conductive layer 112b, the semiconductor device occupies a smaller area.

The conductive layer 104a functions as the gate electrode of the transistor 200B. The conductive layer 104a and the conductive layer 104 can be formed using the same material in the same step.

The shape and size (e.g., diameter) of the opening 141 provided in the insulating layer 110 may be the same as or different from those of an opening 141a provided in the insulating layer 110. Likewise, the shape and size (e.g., diameter) of the opening 143 provided in the conductive layer 112b may be the same as or different from those of an opening 143a provided in the conductive layer 112b.

### Semiconductor Device 10B

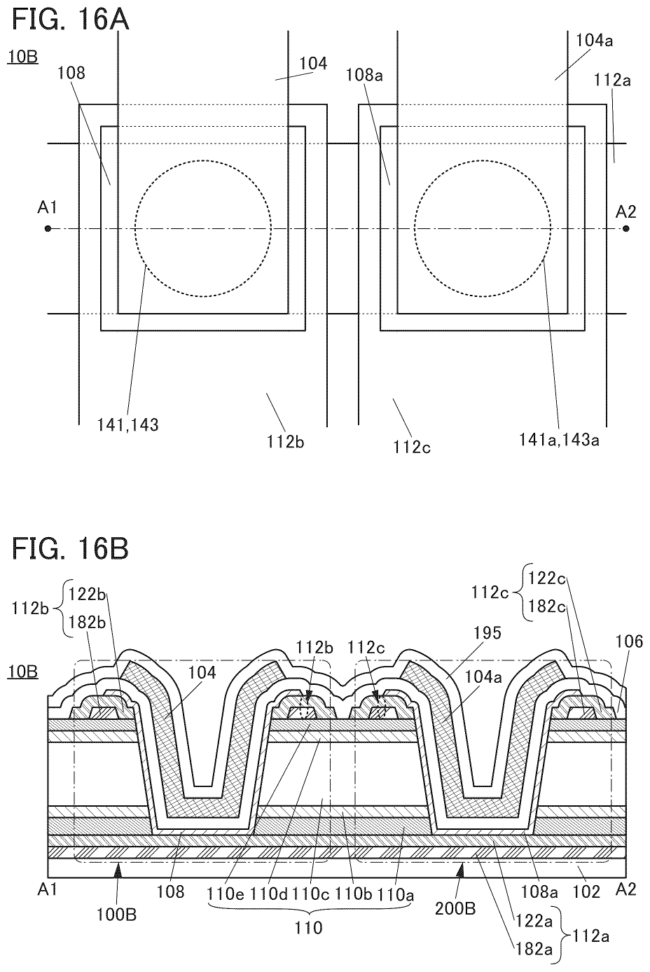

FIG. 13C illustrates a circuit diagram of a semiconductor device 10B. FIG. 16A illustrates a top view of the semiconductor device 10B. FIG. 16B is a cross-sectional view taken along dashed-dotted line A1-A2 in FIG. 16A.

The semiconductor device 10B includes the transistor 100B and the transistor 200B. One of the source and the drain of the transistor 200B is electrically connected to one of the source and the drain of the transistor 100B.

The transistor 100B and the transistor 200B are each provided over the substrate 102.

The transistor 100B has the above-described structure; thus, detailed description thereof is omitted.

The transistor 200B includes the conductive layer 112c (the conductive layer 182c and the conductive layer 122c), the insulating layer 110 (the insulating layers 110a, 110b, 110c, 110d, and 110e), the semiconductor layer 108a, the conductive layer 112a (the conductive layer 182a and the conductive layer 122a), the insulating layer 106, and the conductive layer 104a.

The conductive layer 112c functions as one of the source electrode and the drain electrode of the transistor 200B. The conductive layer 112c and the conductive layer 112b can be formed using the same material in the same step.

The conductive layer 112a functions as the other of the source electrode and the drain electrode of the transistor 100B and the other of the source electrode and the drain electrode of the transistor 200B. Since the transistor 100B and the transistor 200B share the conductive layer 112a, the semiconductor device occupies a smaller area.

The conductive layer 104a functions as the gate electrode of the transistor 200B. The conductive layer 104a and the conductive layer 104 can be formed using the same material in the same step.

The shape and size (e.g., diameter) of the opening 141 provided in the insulating layer 110 may be the same as or different from those of the opening 141a provided in the insulating layer 110. Likewise, the shape and size (e.g., diameter) of the opening 143 provided in the conductive layer 112b may be the same as or different from those of the opening 143a provided in the conductive layer 112c.

### Semiconductor Device 10c

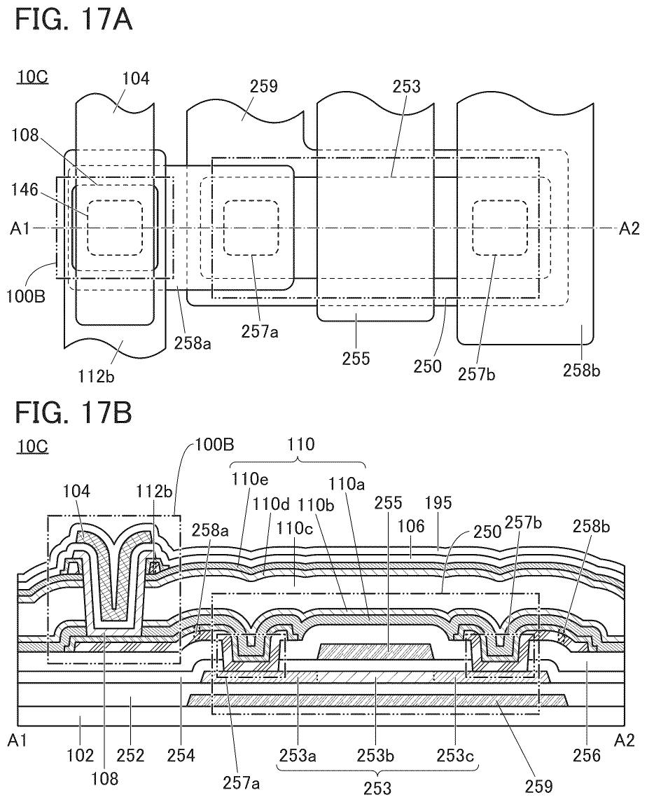

FIG. 13D illustrates a circuit diagram of a semiconductor device 10C. FIG. 17A illustrates a top view of the semiconductor device 10C. FIG. 17B is a cross-sectional view taken along dashed-dotted line A1-A2 in FIG. 17A.

The semiconductor device 10C includes the transistor 100B and a transistor 250. One of a source and a drain of the transistor 250 is electrically connected to one of the source and the drain of the transistor 100B.

Although the transistor 100B being an n-channel transistor and the transistor 250 being a p-channel transistor are illustrated in FIG. 13D to FIG. 13H, one embodiment of the present invention is not limited to these examples. Both the transistor 100B and the transistor 250 may be n-channel transistors or p-channel transistors. Alternatively, the transistor 100B may be a p-channel transistor and the transistor 250 may be an n-channel transistor.

The transistor 100B and the transistor 250 are each provided over the substrate 102.

The semiconductor device 10C includes a conductive layer 259 over the substrate 102, an insulating layer 252 over the substrate and the conductive layer 259, and a semiconductor layer 253 over the insulating layer 252. Furthermore, an insulating layer 254 is provided over the insulating layer 252 and the semiconductor layer 253, and a conductive layer 255 is provided over the insulating layer 254. The semiconductor layer 253 and the conductive layer 255 overlap with each other in a region.

Furthermore, an insulating layer 256 is provided over the insulating layer 254 and the conductive layer 255. The insulating layer 254 and the insulating layer 256 are provided with an opening 257a in a region overlapping with part of the semiconductor layer 253. The insulating layer 254 and the insulating layer 256 are provided with an opening 257b in a region overlapping with another part of the semiconductor layer 253.

A conductive layer 258a is provided over the insulating layer 256 and in the opening 257a, and a conductive layer 258b is provided over the insulating layer 256 and in the opening 257b. The conductive layer 258a is electrically connected to the semiconductor layer 253 in the opening 257a. The conductive layer 258b is electrically connected to the semiconductor layer 253 in the opening 257b.

The semiconductor layer 253 includes a drain region 253a, a channel formation region 253b, and a source region 253c. A region of the semiconductor layer 253 that overlaps with the conductive layer 255 functions as the channel formation region 253b. The drain region 253a is electrically connected to the conductive layer 258a, and the source region 253c is electrically connected to the conductive layer 258b.

The insulating layer 110 (the insulating layers 110a, 110b, 110c, 110d, and 110e) is provided over the insulating layer 256, the conductive layer 258a, and the conductive layer 258b, and the conductive layer 112b is provided over the insulating layer 110.

In a region overlapping with part of the conductive layer 258a, the conductive layer 112b and the insulating layer 110 are provided with an opening 146 (FIG. 17A). The semiconductor layer 108 is provided inside the opening 146.

The insulating layer 106 is provided over the insulating layer 110, the conductive layer 112b, and the semiconductor layer 108, and the conductive layer 104 is provided over the insulating layer 106. The insulating layer 195 is provided over the insulating layer 106 and the conductive layer 104.

The conductive layer 259 functions as a back gate electrode of the transistor 250. It is thus preferable that the conductive layer 259 overlap with the channel formation region 253b and extend beyond an end portion of the channel formation region 253b. That is, the conductive layer 259 is preferably larger than the channel formation region 253b. The conductive layer 259 preferably extends beyond an end portion of the semiconductor layer 253. That is, the conductive layer 259 is preferably larger than the semiconductor layer 253.

A back gate electrode is positioned such that a channel formation region of a semiconductor layer is sandwiched between a gate electrode and the back gate electrode. By changing the potential of the back gate electrode, the threshold voltage of a transistor can be changed. The potential of the back gate electrode may be a ground potential or a given potential.

The back gate electrode is formed using a conductive layer and can function in a manner similar to that of the gate electrode. For example, the potential of the back gate electrode may be the same as the potential of the gate electrode.

The back gate electrode can be formed using a material and a method similar to those used for the gate electrode, a source electrode, a drain electrode, or the like. The gate electrode and the back gate electrode are conductive layers and thus each have a function of preventing an electric field generated outside the transistor from affecting the semiconductor layer in which the channel is formed (in particular, an electric field blocking function against static electricity). That is, the variation in the electrical characteristics of the transistor due to the influence of an external electric field such as static electricity can be prevented. By providing the back gate electrode, the amount of change in threshold voltage of the transistor in a BT (Bias Temperature) stress test can be reduced. By providing the back gate electrode, the variation in the characteristics of the transistor can be reduced and the reliability of a semiconductor device including the transistor can be increased.

The semiconductor layer 253 functions as a semiconductor layer where the channel of the transistor 250 is formed, the insulating layer 254 functions as a gate insulating layer, and the conductive layer 255 functions as a gate electrode. The conductive layer 258a and the conductive layer 258b respectively function as the drain electrode and the source electrode of the transistor 250

Like the transistor 100B, the transistor 250 may be an OS transistor.

Here, for the semiconductor layer 108 and the semiconductor layer 253, the same material or different materials may be used. For the structures of the semiconductor layer 108 and the semiconductor layer 253, the description of the semiconductor layer 108 and the semiconductor layer 108a of the semiconductor device 10 can also be referred to.

A transistor including silicon in its channel formation region (a Si transistor) may be used as the transistor 250.

Examples of silicon include single crystal silicon, polycrystalline silicon, and amorphous silicon. In particular, a transistor including LTPS in its semiconductor layer (hereinafter also referred to as an LTPS transistor) can be used. The LTPS transistor has high field-effect mobility and excellent frequency characteristics.

The structure of the transistor 100B is the same as the above-described structure except that the conductive layer 258a is provided instead of the conductive layer 112a.

The conductive layer 258a functions as one of the source electrode and the drain electrode of the transistor 100B and one of a source electrode and a drain electrode of the transistor 250. Since the transistor 100B and the transistor 250 share the conductive layer 258a, the semiconductor device occupies a smaller area.

Because the conductive layer 258a corresponds to the conductive layer 112a in the above-described transistor 100B, the above description can be referred to.

The conductive layer 258a is a conductive layer in contact with both the semiconductor layer 253 and the semiconductor layer 108. The conductive layer 258a preferably has a stacked-layer structure of at least two layers, i.e., a conductive layer in contact with the semiconductor layer 253 and a conductive layer in contact with the semiconductor layer 108, in which case a material suitable for the layer connected to the semiconductor layer 253 and a material suitable for the layer connected to the semiconductor layer 108 can be used. Thus, reduced contact resistance and favorable adhesion between the conductive layer 258a and the semiconductor layer 253 and between the conductive layer 258a and the semiconductor layer 108 can be achieved. For example, it is preferable that a metal layer or an alloy layer be used as the lowermost layer of the conductive layer 258a (the layer in contact with the semiconductor layer 253) and an oxide conductor layer be used as the uppermost layer of the conductive layer 258a (the layer in contact with the semiconductor layer 108).

As described above, the transistor 100B is a vertical-channel-type transistor. Meanwhile, in the semiconductor layer of the transistor 250, a current flows in the lateral direction, i.e., the direction parallel or substantially parallel to a surface of the substrate 102. Such a transistor can be referred to as a lateral-channel-type transistor or a lateral-channel transistor.

As described above, the semiconductor device of one embodiment of the present invention may include not only a vertical-channel-type transistor but also a lateral-channel-type transistor.

As illustrated in FIG. 13E, the back gate and the gate of the transistor 250 may be electrically connected to each other. As illustrated in FIG. 13F, the back gate of the transistor 250 and the source or drain thereof may be electrically connected to each other. As illustrated in FIG. 13G, the transistor 250 does not necessarily include a back gate.

### Semiconductor Device 10d

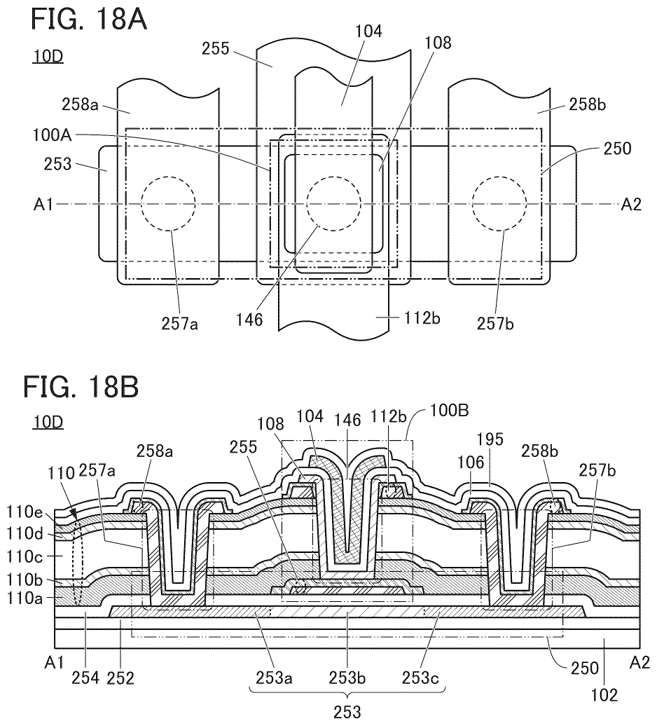

FIG. 13H illustrates a circuit diagram of a semiconductor device 10D. FIG. 18A illustrates a top view of the semiconductor device 10D. FIG. 18B is a cross-sectional view taken along dashed-dotted line A1-A2 in FIG. 18A.

The semiconductor device 10D includes the transistor 100B and the transistor 250. The gate of the transistor 250 is electrically connected to one of the source and the drain of the transistor 100B.

The semiconductor device 10D is different from the semiconductor device 10C in that the opening 146 is provided to overlap with the conductive layer 255 functioning as the gate electrode of the transistor 250. Accordingly, in the semiconductor device 10C, the transistor 100B is provided to be over and overlap with the gate electrode of the transistor 250. In the semiconductor device 10D, the opening 146 is formed by selectively removing part of the conductive layer 112b and part of the insulating layer 110 in a region overlapping with the conductive layer 255.

Although the opening 146 is provided to overlap with the channel formation region 253b in FIG. 18A and FIG. 18B, one embodiment of the present invention is not limited to this example. The opening 146 may be provided so as not to overlap with the channel formation region 253b but to overlap with the conductive layer 255. In the semiconductor device 10D, the conductive layer 255 functions as the gate electrode of the transistor 250 and one of the source electrode and the drain electrode of the transistor 100B.

When the transistor 100B and the transistor 250 are provided to overlap with each other, the semiconductor device occupies a smaller area.

Because the conductive layer 255 corresponds to the conductive layer 112a in the above-described transistor 100B, the above description can be referred to.

The semiconductor device 10D is different from the semiconductor device 10C in the structures of the opening 257a, the opening 257b, the conductive layer 258a, and the conductive layer 258b.

In the semiconductor device 10D, the opening 257a is formed by selectively removing part of the insulating layer 254 and part of the insulating layer 110 in a region overlapping with the drain region 253a of the semiconductor layer 253. In the semiconductor device 10D, the opening 257b is formed by selectively removing part of the insulating layer 254 and part of the insulating layer 110 in a region overlapping with the source region 253c of the semiconductor layer 253.

In the semiconductor device 10D, the conductive layer 258a and the conductive layer 258b are provided over the insulating layer 110.

In the semiconductor device 10D, the conductive layers 258a and 258b and the conductive layer 112b can be concurrently formed using the same material in the same step. The conductive layers 258a and 258b do not need to be formed separately from the conductive layer 112b; thus, the manufacturing process of the semiconductor device can be shortened and the productivity of the semiconductor device can be increased.

The semiconductor device of one embodiment of the present invention includes at least one transistor and at least one capacitor, and a source or a drain of the transistor is electrically connected to one of a pair of electrodes of the capacitor. In FIG. 13I, the source or the drain of the transistor 100 is electrically connected to one electrode of a capacitor 190.

In the transistor of one embodiment of the present invention, which is a kind of vertical transistor, a source electrode, a semiconductor layer, and a drain electrode can be provided to overlap with each other; thus, the area occupied by the transistor can be significantly smaller than the area occupied by a planar transistor. When a planar transistor is used as a p-channel Si transistor and a vertical transistor is used as an n-channel OS transistor, a CMOS (Complementary Metal Oxide Semiconductor) circuit can be formed. When the planar transistor and the vertical transistor are provided to overlap with each other in this structure, the area occupied by the CMOS circuit can be reduced.

A vertical transistor can have improved on-state current and can offer an improved degree of integration as compared with a planar transistor; thus, a problem of an OS transistor having a lower on-state current than LTPS can be solved and the bezel of a display device can be narrowed. Consequently, without using a structure in which an LTPS transistor and an OS transistor are used in combination (also referred to as LTPO), the backplane of a display device in any size, including large and small to medium sizes, can be obtained only with OS transistors. When a display device is manufactured using only OS transistors, the number of necessary photomasks can be small and the number of manufacturing steps can be reduced as compared with the case of using LTPO; thus, costs can be reduced.

As described above, when the transistor of one embodiment of the present invention includes two or more conductive layers containing different metals in at least one of its source electrode and drain electrode, the contact resistance with the semiconductor layer can be reduced and the wiring resistance can be reduced. Thus, the transistor can have high reliability and a high on-state current.

This embodiment can be combined with the other embodiments as appropriate. In this specification, in the case where a plurality of structure examples are shown in one embodiment, the structure examples can be combined as appropriate.

### Embodiment 2

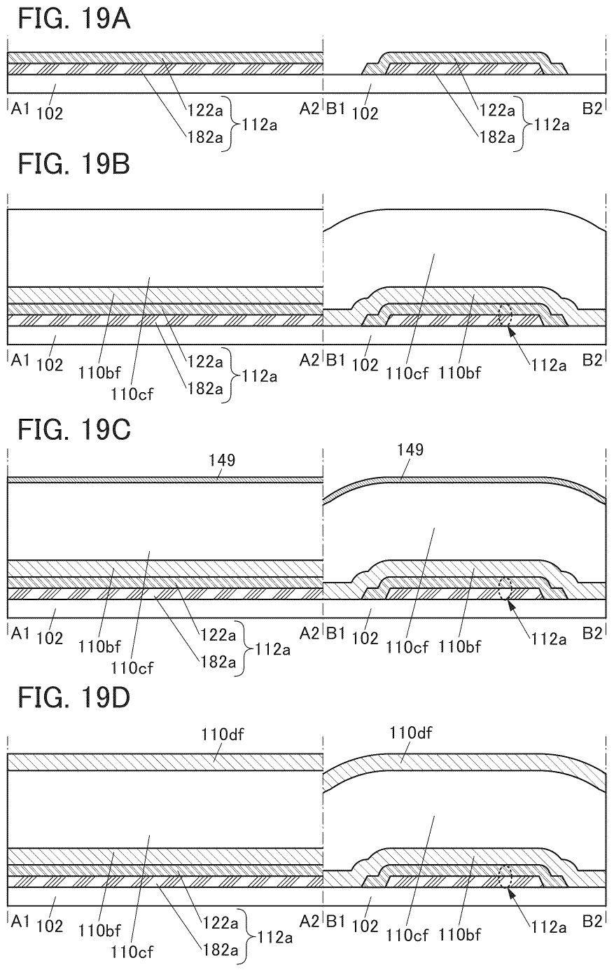

In this embodiment, a method for manufacturing the semiconductor device of one embodiment of the present invention will be described with reference to FIG. 19 to FIG. 21. In this embodiment, a method for manufacturing the transistor 100 described as an example in Embodiment 1 will be described. Note that as for materials and formation methods of components, portions similar to the portions described above in Embodiment 1 are not described in some cases.

FIG. 19 to FIG. 21 each illustrate a cross-sectional view along dashed-dotted line A1-A2 and a cross-sectional view along dashed-dotted line B1-B2 in FIG. 1A side by side.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. An example of a thermal CVD method is a metal organic CVD (MOCVD) method.

Thin films included in the semiconductor device (e.g., insulating films, semiconductor films, and conductive films) can be formed by a wet film-formation method such as a spin coating method, a dip coating method, a spray coating method, an inkjet method, dispensing, screen printing, offset printing, a doctor knife method, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet rays, KrF laser light, ArF laser light, or the like can be used. The light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely fine processing can be performed. Note that a photomask is not needed when the light exposure is performed by scanning with a beam such as an electron beam.

For etching of thin films, a dry etching method, a wet etching method, a sandblasting method, or the like can be used.

### Manufacturing Method Example

First, the conductive layer 112a is formed over the substrate 102. FIG. 19A illustrates a case where the conductive layer 112a has a two-layer structure of the conductive layer 182a and the conductive layer 122a covering the top surface and the side surface of the conductive layer 182a.

First, a conductive film to be the conductive layer 182a is formed over the substrate 102, and the conductive film is processed to form the conductive layer 182a. Next, a conductive film to be the conductive layer 122a is formed over the substrate 102 and the conductive layer 182a, and the conductive film is processed, so that the conductive layer 122a covering the top surface and the side surface of the conductive layer 182a is formed (FIG. 19A).

For the formation of the conductive film, for example, a sputtering method is suitable. A conductive layer can be formed in the following manner: a resist mask is formed over a conductive film by a photolithography process and then, the conductive film is processed. The conductive film can be processed by a wet etching method and/or a dry etching method.

In the case where the conductive layer 112a has a stacked-layer structure of three or more layers, a plurality of layers formed to have the same or substantially the same top-view shapes can be formed by processing with the use of the same mask pattern. For example, the conductive layer 184a and the conductive layer 122a included in the transistor 100A (see FIG. 4A and FIG. 4B) can be formed by processing conductive films in the same step. The conductive layer 184a and the conductive layer 182a illustrated in FIG. 7C can be formed by processing conductive films in the same step.

Next, an insulating film 110bf to be the insulating layer 110b and an insulating film 110cf to be the insulating layer 110c are formed over the conductive layer 112a (FIG. 19B).

For example, a silicon nitride film or an aluminum oxide film is preferably formed as the insulating film 110bf. Furthermore, it is preferable that a silicon oxide film or a silicon oxynitride film be formed as the insulating film 110cf, for example.

For the formation of the insulating film 110bf and the insulating film 110cf, a sputtering method or a PECVD method is suitable, for example. It is preferable that the insulating film 110cf be formed in a vacuum successively after the formation of the insulating film 110bf, without exposure of a surface of the insulating film 110cf to the air. By forming the insulating film 110bf and the insulating film 110cf successively, attachment of impurities derived from the air to a surface of the insulating layer 110bf can be inhibited. Examples of the impurities include water and organic substances.

Note that in the case where the insulating layer 110 has a five-layer structure as illustrated in the transistor 100B (see FIG. 8A and FIG. 8B), at least one of the layers constituting the insulating layer 110 is preferably formed by a PECVD method, in which case both a film having a low hydrogen content and a film having a high hydrogen content can be easily formed. Furthermore, it is preferable that the insulating film 110bf be formed in a vacuum successively after the formation of an insulating film to be the insulating layer 110a, without exposure of a surface of the insulating film to the air.

The substrate temperature at the time of forming the insulating film 110bf and the insulating film 110cf is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperature at the time of forming the insulating film 110bf and the insulating film 110cf is in the above range, impurities (e.g., water and hydrogen) released from the insulating films 110bf and 110cf themselves can be reduced, which can inhibit the diffusion of the impurities to the semiconductor layer 108. Consequently, a transistor with favorable electrical characteristics and high reliability can be provided.

Note that since the insulating film 110bf and the insulating film 110cf are formed earlier than the semiconductor layer 108, there is no need to consider the probability of oxygen release from the semiconductor layer 108 due to heat applied thereto at the time of forming the insulating film 110bf and the insulating film 110cf.

It is preferable that plasma treatment be performed in an oxygen-containing atmosphere after the formation of the insulating film 110cf, without exposure to the air (in-situ). For example, N₂O plasma treatment is preferably performed. Such plasma treatment enables oxygen supply to the insulating film 110cf.

Next, the metal oxide layer 149 is preferably formed over the insulating film 110cf (FIG. 19C). The formation of the metal oxide layer 149 enables oxygen supply to the insulating film 110cf.

There is no limitation on the conductivity of the metal oxide layer 149. For the metal oxide layer 149, at least one type of an insulating film, a semiconductor film, or a conductive film can be used. For the metal oxide layer 149, aluminum oxide, hafnium oxide, hafnium aluminate, an indium oxide, an indium tin oxide (ITO), or an indium tin oxide containing silicon (ITSO) can be used, for example.

An oxide material containing one or more elements contained in the semiconductor layer 108 is preferably used for the metal oxide layer 149. It is particularly preferable to use an oxide semiconductor material that can be used for the semiconductor layer 108.

At the time of forming the metal oxide layer 149, a larger amount of oxygen can be supplied to the insulating film 110cf with a higher proportion of the oxygen flow rate to the total flow rate of a film formation gas introduced into a treatment chamber of a film formation apparatus (an oxygen flow rate ratio), or with a higher oxygen partial pressure in the treatment chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferred that the oxygen flow rate ratio be 100% and the oxygen partial pressure be as close to 100% as possible.

When the metal oxide layer 149 is formed by a sputtering method in an oxygen-containing atmosphere in the above-described manner, oxygen can be supplied to the insulating film 110cf and release of oxygen from the insulating film 110cf can be prevented during the formation of the metal oxide layer 149. As a result, a large amount of oxygen can be enclosed in the insulating film 110cf. Moreover, a large amount of oxygen can be supplied to the semiconductor layer 108 by heat treatment performed later. Consequently, the amount of oxygen vacancies and VoH in the semiconductor layer 108 can be reduced, whereby a transistor with favorable electrical characteristics and high reliability can be provided.

Heat treatment is preferably performed after the metal oxide layer 149 is formed. By performing heat treatment after the formation of the metal oxide layer 149, oxygen can be effectively supplied from the metal oxide layer 149 to the insulating film 110cf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating film 110cf or the like can be prevented as much as possible. An oven, a rapid thermal annealing (RTA) apparatus, or the like can be used for the heat treatment. With the RTA apparatus, the heat treatment time can be shortened.

After the formation of the metal oxide layer 149 or the above-described heat treatment, oxygen may be further supplied to the insulating film 110cf through the metal oxide layer 149. As a method for supplying oxygen, an ion implantation method, an ion doping method, a plasma immersion ion implantation method, or plasma treatment can be used, for example. For the plasma treatment in the method for manufacturing a semiconductor device of one embodiment of the present invention, an apparatus in which an oxygen gas is made to be plasma by high-frequency power can be suitably used. Examples of an apparatus in which a gas is made to be plasma by high-frequency power include a plasma etching apparatus and a plasma ashing apparatus.

Heat treatment may be performed after the formation of the insulating film 110bf and the insulating film 110cf before the formation of the metal oxide layer 149. By the heat treatment, water and hydrogen can be released from the surface and inside of the insulating film 110cf.

Then, the metal oxide layer 149 is removed (FIG. 19D).

There is no particular limitation on a method for removing the metal oxide layer 149, and a wet etching method can be suitably used. When a wet etching method is used, the insulating film 110cf can be inhibited from being etched at the time of the removal of the metal oxide layer 149. In that case, a reduction in the thickness of the insulating film 110cf can be inhibited and the thickness of the insulating layer 110c can be uniform.

The treatment for supplying oxygen to the insulating film 110cf is not necessarily performed in the above-described manner. For example, an ion doping method, an ion implantation method, or plasma treatment can be employed to supply an oxygen radical, an oxygen atom, an oxygen atomic ion, an oxygen molecular ion, or the like to the insulating film 110cf. A film that inhibits oxygen release may be formed over the insulating film 110cf and then, oxygen may be supplied to the insulating film 110cf through the film. It is preferable to remove the film after supply of oxygen. As the film that inhibits oxygen release, a conductive film or a semiconductor film including one or more of indium, zinc, gallium, tin, aluminum, chromium, tantalum, titanium, molybdenum, nickel, iron, cobalt, and tungsten can be used.

Next, an insulating film 110df to be the insulating layer 110d is formed over the insulating film 110cf (FIG. 19D).

For the formation of the insulating film 110df, the description of the formation of the insulating film 110bf can be referred to. The film formation conditions for the insulating film 110bf may be the same as or different from those for the insulating film 110df.

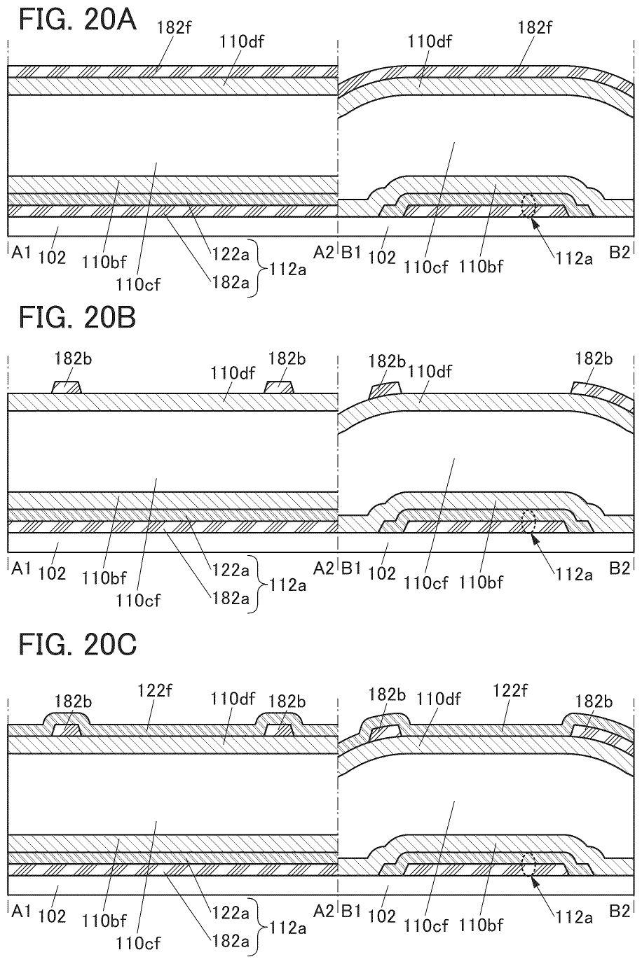

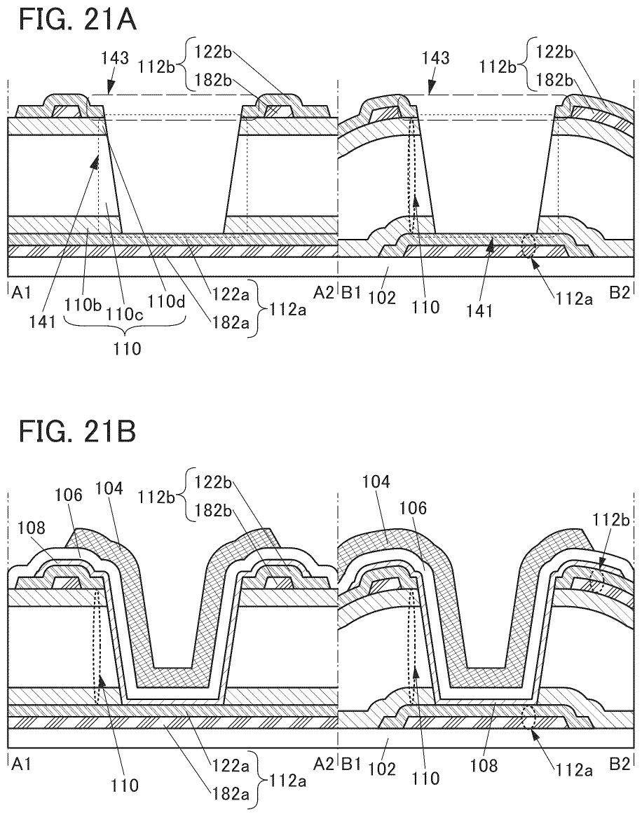

Next, the conductive layer 112b is formed over the insulating film 110df (FIG. 20A to FIG. 20C and FIG. 21A). FIG. 21A illustrates a case where the conductive layer 112b has a two-layer structure of the conductive layer 182b and the conductive layer 122a covering the top surface and the side surface of the conductive layer 182b.

First, a conductive film 182f to be the conductive layer 182b is formed over the insulating film 110df (FIG. 20A), and the conductive film 182f is processed to form the conductive layer 182b (FIG. 20B).

The conductive layer 182b is formed in an island shape so as not to overlap with an opening portion to be formed later in the insulating films 110bf, 110cf, and 110df. The conductive layer 182b may have an opening overlapping with the whole opening portion to be formed later (see the opening 145 illustrated in FIG. 1A and the like).

Next, a conductive film 122f to be the conductive layer 122b is formed over the insulating film 110df and the conductive layer 182b (FIG. 20C), and the conductive film 122f is processed, so that the conductive layer 122b covering the top surface and the side surface of the conductive layer 182b is formed (FIG. 21A). The conductive layer 122b is formed to have the opening 143 at a position overlapping with the opening portion to be formed later in the insulating films 110bf, 110cf, and 110df.

For the formation of the conductive films (the conductive film 182f and the conductive film 122f), for example, a sputtering method is suitable. A conductive layer can be formed in the following manner: a resist mask is formed over a conductive film by a photolithography process and then, the conductive film is processed. The conductive films (the conductive film 182f and the conductive film 122f) can be processed by one or both of a wet etching method and a dry etching method. A wet etching method is particularly suitable for the formation of the opening 143

The step of processing the conductive film 122f into an island shape and the step of providing the opening 143 in the conductive film 122f can be performed independently, and in that case, there is no limitation on the order of the steps. Alternatively, after light exposure using a mask for processing into a quadrangular island shape and light exposure using a mask for providing a circular opening are performed, etching may be performed, in which case the processing into island shapes and the formation of the opening are performed at a time. Light exposure using a multi-tone mask (typically a half-tone mask or a gray-tone mask) may be used.

An opening is formed in the insulating film 110bf to the insulating film 110df, so that the insulating layer 110 (the insulating layers 110b, 110c, and 110d) having the opening 141 is formed (FIG. 21A).

The opening 141 is provided at a position overlapping with the opening 143 of the conductive layer 112b. By providing the opening 141, a region of the conductive layer 182a (to be the conductive layer 112a later) that overlaps with the openings 141 and 143 is exposed.

Here, at the time of forming the opening 141, the surfaces of the conductive layer 122a and the conductive layer 122b are oxidized in some cases. For example, by ashing, metal oxide films are formed on the top surface of the conductive layer 122a and the top surface and the side surface of the conductive layer 122b, in some cases. That is, in some cases, a metal oxide layer is formed on the surfaces of the conductive layer 112a and the conductive layer 112b in and after the step of FIG. 21A (see the conductive layer 186a and the conductive layer 186b in FIG. 7B).

For the formation of the opening 141, one or both of a wet etching method and a dry etching method can be used, and for example, a dry etching method is suitable.

The opening 141 can be formed using the resist mask used for the formation of the opening 143, for example. Specifically, a resist mask is formed over the conductive film 122f, part of the conductive film 122f is removed with the use of the resist mask to form the opening 143, and part of each of the insulating films 110bf, 110cf, and 110df is removed with the use of the resist mask, whereby the opening 141 can be formed. The opening 141 and the opening 143 may be formed using different resist masks.

Here, an impurity containing a metal derived from the conductive layer 112b, an impurity generated by the etching step (e.g., an impurity derived from an etching gas), and the like may remain on the surface of the layer exposed inside the opening 141. Therefore, the impurity attached to the surface of the layer exposed inside the opening 141 is preferably removed before the semiconductor layer 108 is formed. This can improve the coverage with the semiconductor layer 108. In addition, the transistor can have favorable electrical characteristics or a reduced variation in electrical characteristics.

For example, the inside of the opening 141 is preferably cleaned using an acid-based solution. Specifically, it is preferable to use dilute hydrofluoric acid, oxalic acid, phosphoric acid, acetic acid, nitric acid, a mixed solution containing two or more of these acids, or the like. Note that a plurality of layers such as the conductive layer 112a, the conductive layer 112b, and the insulating layer 110 are exposed inside the opening 141. Therefore, it is preferable to perform the treatment with a solution that is sufficiently diluted so that these exposed layers are not excessively etched.

Next, a metal oxide film is formed to cover the opening 141 and the opening 143, and the metal oxide film is processed to form the semiconductor layer 108 (FIG. 21B). The semiconductor layer 108 is provided to be in contact with the top surface and the side surface of the conductive layer 112b, the top surface and the side surface of the insulating layer 110, and the top surface of the conductive layer 112a.

The metal oxide film to be the semiconductor layer 108 is preferably formed to have as uniform a thickness as possible, on the side surface of the insulating layer 110 in the opening 141 and the side surface of the conductive layer 112b in the opening 143. The metal oxide film can be formed by, for example, a sputtering method or an ALD method.

The metal oxide film to be the semiconductor layer 108 is preferably formed by a sputtering method using a metal oxide target.

The semiconductor layer 108 is preferably a dense film with as few defects as possible. The semiconductor layer 108 is preferably a highly purified film in which impurities containing hydrogen elements are reduced as much as possible. It is particularly preferable to use a metal oxide layer having crystallinity as the semiconductor layer 108.

In forming the metal oxide film to be the semiconductor layer 108, an oxygen gas is preferably used. When an oxygen gas is used at the time of forming the metal oxide film, oxygen can be suitably supplied to the insulating layer 110. In the case where an oxide is used for the insulating layer 110c, for example, oxygen can be suitably supplied to the insulating layer 110c.

The oxygen supply to the insulating layer 110c enables the semiconductor layer 108 to be supplied with oxygen in a later step, so that the amounts of oxygen vacancies and VoH in the semiconductor layer 108 can be reduced.

In forming the metal oxide film to be the semiconductor layer 108, the oxygen gas and an inert gas (e.g., a helium gas, an argon gas, or a xenon gas) may be mixed. Note that when the oxygen flow rate ratio at the time of forming the metal oxide film is higher, the crystallinity of the semiconductor layer 108 can be higher and a transistor with higher reliability can be obtained. By contrast, when the oxygen flow rate ratio is lower, the crystallinity of the semiconductor layer 108 is lower and a transistor with a high on-state current can be obtained.

In forming the metal oxide film to be the semiconductor layer 108, as the substrate temperature is higher, a denser metal oxide film having higher crystallinity can be formed. In contrast, as the substrate temperature is lower, a metal oxide film having lower crystallinity and higher electric conductivity can be formed.

The substrate temperature during the formation of the metal oxide film to be the semiconductor layer 108 is preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably higher than or equal to room temperature and lower than or equal to 140° C., in which case productivity is increased. Furthermore, when the metal oxide film is formed with the substrate temperature set at room temperature or without heating the substrate, the crystallinity can be made low.

In the case of using an ALD method, a film formation method such as a thermal ALD method or PEALD (Plasma Enhanced ALD) is preferably used. The film formation by a thermal ALD method is preferable because of its capability of forming a film with extremely high step coverage. The film formation by a PEALD method is preferable because of its capability of forming a film at low temperatures, in addition to its capability of offering extremely high coverage.

For example, the metal oxide film to be the semiconductor layer 108 can be formed by an ALD method using a precursor containing a constituent metal element and an oxidizer.

Examples of a precursor containing indium include trimethylindium, triethylindium, tris(2,2,6,6-tetramethyl-3,5-heptanedionato)indium, cyclopentadienylindium, indium(III) chloride, and (3-(dimethylamino)propyl)dimethylindium.

Examples of a precursor containing gallium include trimethylgallium, triethylgallium, tris(dimethylamido)gallium(III), gallium(III) acetylacetonate, tris(2,2,6,6-tetramethyl-3,5-heptanedionato)gallium, dimethylchlorogallium, diethylchlorogallium, and gallium(III) chloride.

Examples of a precursor containing tin include tetramethyltin, tetraethyltin, tetraethenyltin, tetraallyltin, tributylvinyltin, allyltributyltin, tributylstannylacetylene, tributylphenyltin, chlorotrimethyltin, chlorotriethyltin, and tin(IV) chloride.

Examples of a precursor containing zinc include dimethylzinc, diethylzinc, bis(2,2,6,6-tetramethyl-3,5-heptanedionato)zinc, and zinc chloride.

In the case of forming a film of an In—Ga—Zn oxide, for example, three precursors of a precursor containing indium, a precursor containing gallium, and a precursor containing zinc can be used. Alternatively, two precursors, which are a precursor containing indium and a precursor containing gallium and zinc, may be used.

Examples of the oxidizer include ozone, oxygen, and water.

As an example of a method for controlling the composition of a film to be formed, adjusting the flow rate ratio of the source gases, the flowing time of the source gases, the flowing order of the source gases, or the like is given. By adjusting such conditions, a film whose composition is continuously changed can be formed. Furthermore, films having different compositions can be formed successively.

Before the formation of the metal oxide film to be the semiconductor layer 108, at least one of treatment for desorbing water, hydrogen, an organic substance, and the like adsorbed on the surface of the insulating layer 110, and treatment for supplying oxygen to the insulating layer 110 is preferably performed. For example, heat treatment can be performed at a temperature higher than or equal to 70° C. and lower than or equal to 200° C. in a reduced-pressure atmosphere. Alternatively, plasma treatment in an oxygen-containing atmosphere may be performed. Alternatively, oxygen may be supplied to the insulating layer 110 by performing plasma treatment in an atmosphere containing an oxidizing gas such as dinitrogen monoxide (N₂O). When plasma treatment is performed using a dinitrogen monoxide gas, an organic substance on the surface of the insulating layer 110 can be favorably removed and oxygen can be supplied. After such treatment, the metal oxide film is preferably formed successively without exposure of the surface of the insulating layer 110 to the air.

In the case where the semiconductor layer 108 has a stacked-layer structure, an upper metal oxide film is preferably formed successively after the formation of a lower metal oxide film without exposure of a surface of the lower metal oxide film to the air.

In the case where the semiconductor layer 108 has a stacked-layer structure, all the layers constituting the semiconductor layer 108 may be formed by the same film formation method (e.g., a sputtering method or an ALD method) or the layers may be formed by different film formation methods. For example, the first metal oxide film may be formed by a sputtering method and the second metal oxide film may be formed by an ALD method.

For the formation of the semiconductor layer 108, one or both of a wet etching method and a dry etching method can be used, and for example, a wet etching method is suitable. At this time, part of the conductive layer 112b in the region that does not overlap with the semiconductor layer 108 is etched and thinned in some cases. In a similar manner, part of the insulating layer 110 in the region that does not overlap with the semiconductor layer 108 or the conductive layer 112b is etched and thinned in some cases.

Here, it is preferable that heat treatment be performed after the metal oxide film is formed or after the metal oxide film is processed into the semiconductor layer 108. By the heat treatment, hydrogen or water contained in the semiconductor layer 108 or adsorbed on its surface can be removed. Furthermore, the film quality of the semiconductor layer 108 is improved (e.g., the number of defects is reduced or the crystallinity is increased) by the heat treatment in some cases. It is preferable that the heat treatment be performed before processing into the semiconductor layer 108.

It is preferable that the heat treatment cause oxygen supply from the insulating layer 110c to at least part of the metal oxide film or at least part of the semiconductor layer 108. The region of the semiconductor layer 108 that is in contact with the insulating layer 110c and the vicinity thereof function as a channel formation region. Oxygen supply to the region can reduce the amount of oxygen vacancies in the channel formation region and lower the carrier concentration therein. In other words, the channel formation region can be an i-type (intrinsic) or substantially i-type region. Accordingly, the transistor can have stable electrical characteristics.

The above description can be referred to for the heat treatment; thus, the detailed description thereof is omitted.

Note that the heat treatment may be omitted if unnecessary. Alternatively, the heat treatment is not performed, and heat treatment performed in a later step may also serve as the heat treatment. Alternatively, treatment at a high temperature (e.g., film formation step) in a later step can also serve as the heat treatment in some cases.

Portions of the conductive layer 112a and the conductive layer 112b that are in contact with the metal oxide film (or the semiconductor layer 108) are oxidized by the film formation step of the metal oxide film to be the semiconductor layer 108 or by the subsequent heat treatment or the like, in some cases (see the conductive layer 186a and the conductive layer 186b in FIG. 7B).

Then, the insulating layer 106 is formed to cover the semiconductor layer 108, the conductive layer 112b, and the insulating layer 110 (FIG. 21B). For the formation of the insulating layer 106, for example, a PECVD method or an ALD method is suitable.

In the case where the semiconductor layer 108 is formed using an oxide semiconductor, the insulating layer 106 preferably functions as a barrier film that inhibits diffusion of oxygen. The insulating layer 106 having a function of inhibiting diffusion of oxygen inhibits diffusion of oxygen into the conductive layer 104 from above the insulating layer 106 and thus can inhibit oxidation of the conductive layer 104. Consequently, a transistor with favorable electrical characteristics and high reliability can be provided.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

By increasing the temperature at the time of forming the insulating layer 106 functioning as the gate insulating layer, the insulating layer including few defects can be obtained. However, the high temperature at the time of forming the insulating layer 106 sometimes allows release of oxygen from the semiconductor layer 108, which increases the amounts of oxygen vacancies and VoH in the semiconductor layer 108. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above-described range, release of oxygen from the semiconductor layer 108 can be inhibited while the defects in the insulating layer 106 can be reduced. Consequently, a transistor with favorable electrical characteristics and high reliability can be provided.

Before the formation of the insulating layer 106, a surface of the semiconductor layer 108 may be subjected to plasma treatment. By the plasma treatment, impurities such as water adsorbed on the surface of the semiconductor layer 108 can be reduced. Accordingly, impurities at the interface between the semiconductor layer 108 and the insulating layer 106 can be reduced, achieving a highly reliable transistor. Performing the plasma treatment in this manner is particularly suitable in the case where the surface of the semiconductor layer 108 is exposed to the air after the formation of the semiconductor layer 108 before the formation of the insulating layer 106. The plasma treatment can be performed in an atmosphere of oxygen, ozone, nitrogen, dinitrogen monoxide, argon, or the like, for example. The plasma treatment and the formation of the insulating layer 106 are preferably performed successively without exposure to the air.

A film including a large amount of oxygen is preferably used for the insulating layer 106, in which case oxygen can be supplied from the insulating layer 106 to the semiconductor layer 108. A film which releases oxygen by heating is further preferably used as the insulating layer 106. When the insulating layer 106 releases oxygen by being heated during the manufacturing process of the transistor, the oxygen can be supplied to the semiconductor layer 108. The oxygen supply from the insulating layer 106 to the semiconductor layer 108, particularly to the channel formation region of the semiconductor layer 108, can reduce the amount of oxygen vacancies in the semiconductor layer 108, so that a transistor with favorable electrical characteristics and high reliability can be obtained.

Then, the conductive layer 104 is formed over the insulating layer 106 (FIG. 21B). For the formation of a conductive film to be the conductive layer 104, a sputtering method, a thermal CVD method (including an MOCVD method), or an ALD method is suitably used, for example. A resist mask is formed over the conductive film by a photolithography process and then, the conductive film is processed, so that the conductive layer 104 having an island shape, which functions as the gate electrode, can be formed.

Through the above steps, the semiconductor device of one embodiment of the present invention can be manufactured.

### Formation Method of Insulating Layer 110c

An example of a method for forming the insulating layer 110c will be described below. As described above, as the insulating layer 110c, which is in contact with the channel formation region of the semiconductor layer 108, a layer including oxygen is preferably used. Here, the insulating layer 110c preferably has a structure which allows easy supply of oxygen especially to a center portion of the channel formation region of the semiconductor layer 108. Thus, for example, the insulating layer 110c may have a structure in which the diffusion coefficient of oxygen differs (the ease of diffusion of oxygen differs) depending on the region. Alternatively, a region including more oxygen than the other portion may be included in a center portion in the thickness direction of the insulating layer 110c.

Specifically, the insulating layer 110c may be formed by performing a film formation step of an oxide insulating film or an oxynitride insulating film two or more times under different conditions.

Here, an example where silicon oxynitride is formed by a PECVD method is described.

A mixed gas including a deposition gas containing silicon and an oxidizing gas can be used as the source gas of the insulating layer 110c. As the deposition gas containing silicon, one or more of silane (SiH₄), disilane (Si₂H₆), trisilane (Si₃H₈), silane fluoride (SiF₄), and TEOS (Tetraethoxysilane, Si(OC₂H₅)₄) can be used, for example. As the oxidizing gas, a gas containing oxygen can be suitably used. As the oxidizing gas, for example, one or more of oxygen (O₂), ozone (O₃), dinitrogen monoxide (N₂O), nitrogen monoxide (NO), and nitrogen dioxide (NO₂) can be used. In the case where silane (SiH₄) is used as the deposition gas containing silicon, dinitrogen monoxide (N₂O) is preferably used as the oxidizing gas, in which case the number of particles can be smaller than that of the case where oxygen (O₂) is used. Alternatively, in the case where silicon oxide is formed as the insulating layer 110b and TEOS is used as the deposition gas containing silicon, oxygen (O₂) can be suitably used as the oxidizing gas.

When the plasma density with respect to the flow rate of the deposition gas is reduced, that is, when the ratio (value of the ratio) of the plasma density to the flow rate of the deposition gas is reduced, in the formation of the insulating layer 110c by a PECVD method, the insulating layer can have a high oxygen diffusion coefficient. Here, in the case where an RF power source is used to bring the source gas into a plasma state, the plasma density can be reduced by reducing the power of the RF power source (hereinafter also referred to as RF power). By reducing the RF power with respect to the flow rate of the deposition gas (reducing the ratio of the RF power to the flow rate of the deposition gas), the insulating layer can have a high oxygen diffusion coefficient. By reducing the ratio of the RF power to the flow rate of the deposition gas (hereinafter also referred to as an F ratio), the diffusion coefficient of oxygen in the insulating layer 110c is increased, so that oxygen contained in the insulating layer 110c can be efficiently supplied to the semiconductor layer 108 (in particular, the channel formation region). Thus, the transistor can be inhibited from being normally on and the threshold voltage of the transistor can be inhibited from being shifted in the negative direction.

However, in the case where a gas containing hydrogen (e.g., SiH₄) is used as the source gas, too low an F ratio might increase the amount of hydrogen contained in the insulating layer 110c. A large amount of hydrogen contained in the insulating layer 110c might cause the insulating layer 110c to release a large amount of impurities containing hydrogen (e.g., water, hydrogen, and ammonia).

Furthermore, in the case where a gas containing nitrogen (e.g., N₂O) is used as the source gas, too low an F ratio might increase the amount of nitrogen contained in the insulating layer 110c. A large amount of nitrogen contained in the insulating layer 110c might cause the insulating layer 110c to release a large amount of impurities containing nitrogen (e.g., nitrogen oxide (NOₓ)).

Note that nitrogen oxide (NOₓ) including nitrogen dioxide (NO₂) forms a state in the insulating layer. The state is positioned in the energy gap of the oxide semiconductor. Thus, when nitrogen oxide (NOₓ) is diffused to the interface between the insulating layer 110c and the semiconductor layer 108, an electron may be trapped by the state on the insulating layer 110c side. As a result, the trapped electron remains in the vicinity of the interface between the insulating layer 110c and the semiconductor layer 108; hence, the threshold voltage of the transistor is shifted in the positive direction.

Thus, in one embodiment of the present invention, an oxide insulating film or an oxynitride insulating film provided in the center portion in the thickness direction of the insulating layer 110c is formed under a condition with a low F ratio, and an insulating film positioned away from the center portion in the thickness direction of the insulating layer 110c is formed under a condition with a higher F ratio. Accordingly, the center portion of the channel formation region of the semiconductor layer 108 is in contact with the insulating film having a high oxygen diffusion coefficient. Thus, oxygen is easily supplied to the channel formation region, so that oxygen vacancies in the channel formation region can be reduced, and the transistor can have a positive threshold voltage (normally off). Moreover, a shift of the threshold voltage of the transistor in the negative direction can be suppressed. In contrast, a region of the semiconductor layer 108 that is away from the center portion of the channel formation region is in contact with the insulating film having a lower oxygen diffusion coefficient than the insulating film that the center portion is in contact with. As compared with the case where the whole insulating layer 110c is formed under a condition with a low F ratio, diffusion of impurities including hydrogen and impurities including nitrogen from the insulating layer 110c into the semiconductor layer 108 can be inhibited, so that a shift of the threshold voltage of the transistor in the positive direction can be inhibited. Accordingly, when the insulating layer 110c is formed of a plurality of layers formed under conditions with different F ratios, the transistor can have high reliability.

Depending on the F ratio condition or the like, part of a region of the semiconductor layer 108 that is in contact with the insulating layer 110c may become a low-resistance region. In particular, a low-resistance region may be formed in the region of the semiconductor layer 108 that is in contact with the insulating layer 110c and that is in the vicinity of the insulating layer 110b or in the vicinity of the insulating layer 110d. Thus, a high electric field is not easily generated in the vicinity of the drain region, and generation of hot carriers and degradation of the transistor can be inhibited.

When the unit of the deposition gas flow rate is represented by sccm (Standard Cubic Centimeters Per Minute) and the unit of the RF power is represented by W (Watt), the F ratio in the film formation of the layers included in the insulating layer 110c is preferably less than or equal to 12, less than or equal to 10, less than or equal to 9, less than or equal to 8, less than or equal to 7, less than or equal to 6, or less than or equal to 5 and greater than or equal to 2 or greater than or equal to 3. For example, in the case where the flow rate of silane (SiH₄) is 290 sccm and the RF power is 1160 W, the F ratio is 4. For example, in the case where the flow rate of silane (SiH₄) is 290 sccm and the RF power is 1740 W, the F ratio is 6. When the F ratio is within the above-described range, oxygen contained in the insulating layer 110c can be efficiently supplied to the semiconductor layer 108 (in particular, the channel formation region) and the amount of impurities released from the insulating layer 110c can be reduced. Note that the F ratio for the insulating film positioned away from the center portion in the thickness direction of the insulating layer 110c (the film in contact with the insulating layer 110b or the insulating layer 110d and the film in the vicinity thereof) may be lower than 2 or higher than 12 in some cases.

In this specification and the like, sccm represents a flow rate at 1 atmospheric pressure and 0° C. (273.15 K). Although the F ratio of the case where the unit of a deposition gas flow rate is represented by sccm and the unit of the RF power is represented by W is shown, when a different unit is used, the unit can be converted into the above unit to calculate the F ratio. For example, in the case where the flow rate is 0.3 SLM (Standard Liter Per Minute), the F ratio can be calculated by converting 0.3 SLM into 300 sccm.

Electrical characteristics of a transistor with a shorter channel length are more affected by oxygen vacancies (V_{O}) and V_{O}H in the channel formation region than those of a transistor with a longer channel length. Therefore, it is extremely important to efficiently supply oxygen from the insulating layer 110c to the semiconductor layer 108 (in particular, the channel formation region) and to reduce the amount of impurities released from the insulating layer 110c. When the F ratio in the formation of the insulating layer 110c is within the above-described range, the transistor can have favorable electrical characteristics and high reliability.

Specifically, the insulating layer 110c is preferably formed in the following manner: a first silicon oxynitride film is formed, a second silicon oxynitride film is formed under a condition with a lower F ratio than the condition for the first silicon oxynitride film, and a third silicon oxynitride film is formed under a condition with a higher F ratio than the condition for the second silicon oxynitride film. In that case, the first silicon oxynitride film and the third silicon oxynitride film are preferably formed under the conditions with the same F ratio. In the insulating layer 110c, the second silicon oxynitride film corresponds to the layer in contact with the center portion of the channel formation region of the semiconductor layer 108. Accordingly, oxygen is easily supplied especially to the center portion of the channel formation region of the semiconductor layer 108, and a reduction in reliability of the transistor can be inhibited.

For example, the insulating layer 110c preferably has a structure in which three silicon oxynitride films formed under conditions with the respective F ratios of 10, 4, and 10 are stacked in this order.

Alternatively, the insulating layer 110c is preferably formed in the following manner: a first silicon oxynitride film is formed, a second silicon oxynitride film is formed under a condition with a lower F ratio than the condition for the first silicon oxynitride film, a third silicon oxynitride film is formed under a condition with a lower F ratio than the condition for the second silicon oxynitride film, a fourth silicon oxynitride film is formed under a condition with a higher F ratio than the condition for the third silicon oxynitride film, and a fifth silicon oxynitride film is formed under a condition with a higher F ratio than the condition for the fourth silicon oxynitride film. In that case, the first silicon oxynitride film and the fifth silicon oxynitride film are preferably formed under the conditions with the same F ratio, and the second silicon oxynitride film and the fourth silicon oxynitride film are preferably formed under the conditions with the same F ratio. In the insulating layer 110c, the third silicon oxynitride film corresponds to the layer in contact with the center portion of the channel formation region of the semiconductor layer 108. Accordingly, oxygen is easily supplied especially to the center portion of the channel formation region of the semiconductor layer 108, and a reduction in reliability of the transistor can be inhibited.

For example, the insulating layer 110c preferably has a structure in which five silicon oxynitride films formed under conditions with the respective F ratios of 10, 6, 4, 6, and 10 are stacked in this order.

Note that there is no particular limitation on the thicknesses of the layers and the relationship between thickness magnitudes of the layers. For example, the layer formed under a condition with a lower F ratio may have a smaller thickness. Alternatively, the layer formed under a condition with a lower F ratio may have a larger thickness. Alternatively, the layers may be formed to have the same thickness.

By measuring the nitrogen concentration (N concentration) profile or the hydrogen concentration (H concentration) profile of the insulating layer 110c in the depth direction using secondary ion mass spectrometry (SIMS), it can be confirmed that the insulating layer 110c consist of a plurality of layers formed under different film formation conditions. Specifically, the layer formed under a condition with a lower F ratio has a higher hydrogen concentration. The layer formed under a condition with a lower F ratio has a lower nitrogen concentration. Such analysis can estimate the number of layers constituting the insulating layer 110c and the relationship between F ratio condition magnitudes of the layers.

Note that in film formation, the etching rate with respect to an etchant is low when the F ratio is high, whereas the etching rate with respect to an etchant is high when the F ratio is low; thus, the etching rate can be used as an indicator of ease of diffusion. As the etchant, an etchant containing hydrofluoric acid can be used, for example. Specific examples include hydrofluoric acid and BHF (Buffered Hydrofluoric acid). Note that BHF is an etchant containing hydrofluoric acid and a buffer agent (e.g., ammonium fluoride (NH₄F)). Alternatively, any of these etchants to which a surface-active agent is added may be used. For example, the etching rate of each of the layers constituting the insulating layer 110c with respect to 0.5 wt % hydrofluoric acid at 25° C. is preferably higher than or equal to 8 nm/min, higher than or equal to 9 nm/min, higher than or equal to 10 nm/min, higher than or equal to 11 nm/min, or higher than or equal to 12 nm/min and lower than or equal to 15 nm/min. Note that the etching rate can be calculated by dividing a difference between the thickness of a target film before the etching and the thickness of the target film after the etching by the etching time.

Alternatively, the insulating layer 110c may be formed in the following manner: a film formation step of an oxide insulating film or an oxynitride insulating film is performed two or more times, and plasma treatment is performed in an oxygen-containing atmosphere after at least one of the film formation steps. For example, the insulating layer 110c may be formed in the following manner: a first silicon oxynitride film is formed, first N₂O plasma treatment is performed, a second silicon oxynitride film is formed, and second N₂O plasma treatment is performed. Alternatively, for example, the insulating layer 110c may be formed in the following manner: a first silicon oxynitride film is formed, first N₂O plasma treatment is performed, a second silicon oxynitride film is formed, second N₂O plasma treatment is performed, a third silicon oxynitride film is formed, and third N₂O plasma treatment is performed. Note that the number of film formation steps and the number of plasma treatment steps are each not limited to two or three and may each be four or more.

The silicon oxynitride films may be formed under the same film formation conditions, or at least one of the films may be formed under different conditions. The plasma treatments may be performed under the same conditions, or at least one plasma treatment may be performed under different conditions.

Performing the plasma treatment in an oxygen-containing atmosphere a plurality of times is preferable in order to increase the amount of oxygen contained in the insulating layer 110c. By changing whether the plasma treatment is performed or the plasma treatment conditions (treatment time or the like) in each time, a region containing more oxygen than the other portions can be easily formed in the center portion in the thickness direction of the insulating layer 110c. For example, in the case where three times of plasma treatments are performed, the same conditions are preferably used for the first and third plasma treatments and the treatment time of the second plasma treatment is preferably longer than those of the first and third plasma treatments. Alternatively, the plasma treatment may be performed only after the second film formation, without performing the plasma treatment after the first film formation and the third film formation. Alternatively, the plasma treatment may be performed after the first film formation and the third film formation, and the plasma treatment may be omitted after the second film formation.

For example, the insulating layer 110c may be formed in the following manner: a silicon oxynitride film formed under a condition with an F ratio of 10 is formed, N₂O plasma treatment is performed, a silicon oxynitride film formed under a condition with an F ratio of 4 is formed, a silicon oxynitride film formed under a condition with an F ratio of 10 is formed, and N₂O plasma treatment is performed.

This embodiment can be combined with the other embodiments as appropriate.

### Embodiment 3

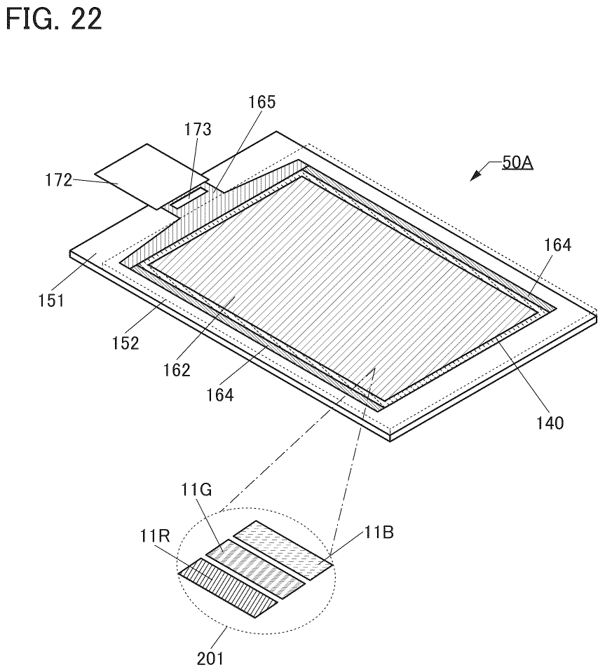

In this embodiment, display devices of embodiments of the present invention will be described with reference to FIG. 22 to FIG. 27.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a tape carrier package (TCP) is attached to the display device and a module in which the display device is mounted with an integrated circuit (IC) by a chip on glass (COG) method, a chip on film (COF) method, or the like.

The display device in this embodiment may have a function of a touch panel. For example, the display device can employ any of a variety of sensing elements (also referred to as sensor elements) that can sense proximity or touch of a sensing target such as a finger.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be sensed simultaneously.

Examples of a touch panel include an out-cell type, an on-cell type, and an in-cell type. Note that an in-cell touch panel has a structure in which an electrode included in a sensing element is provided on one or both of a substrate supporting a display element and a counter substrate.

### Display Device 50A

FIG. 22 is a perspective view of a display device 50A.

In the display device 50A, a substrate 152 and a substrate 151 are bonded to each other. In FIG. 22, the substrate 152 is indicated by a dashed line.

The display device 50A includes a display portion 162, a connection portion 140, a circuit portion 164, a conductive layer 165, and the like. FIG. 22 illustrates an example where an IC 173 and an FPC 172 are implemented onto the display device 50A. Thus, the structure illustrated in FIG. 22 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 22 illustrates an example where the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or input to the conductive layer 165 from the IC 173.

FIG. 22 illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The semiconductor device of one embodiment of the present invention can be used for one or both of the display portion 162 and the circuit portion 164 of the display device 50A, for example.

In the case where the semiconductor device of one embodiment of the present invention is used for a pixel circuit of the display device, for example, the area occupied by the pixel circuit can be reduced and the display device can have high resolution. In the case where the semiconductor device of one embodiment of the present invention is used for a driver circuit (e.g., one or both of a gate line driver circuit and a source line driver circuit) of the display device, for example, the area occupied by the driver circuit can be reduced and the display device can have a narrow bezel. Since the semiconductor device of one embodiment of the present invention has favorable electrical characteristics, a display device can have increased reliability by using the semiconductor device.

The display portion 162 of the display device 50A is a region where an image is to be displayed, and includes a plurality of pixels 201 that are periodically arranged. FIG. 22 illustrates an enlarged view of one of the pixels 201.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 201 illustrated in FIG. 22 includes a subpixel 11R that emits red light, a subpixel 11G that emits green light, and a subpixel 11B that emits blue light. There is no particular limitation on the number of subpixels included in one pixel.

The subpixels 11R, 11G, and 11B each include a display element and a circuit for controlling the driving of the display element.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

Examples of a display device that includes a liquid crystal element include a transmissive liquid crystal display device, a reflective liquid crystal display device, and a transflective liquid crystal display device.

Examples of the mode that can be applied to the display device using a liquid crystal element include a vertical alignment (VA) mode, an FFS (Fringe Field Switching) mode, an IPS (In-Plane-Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

Examples of a light-emitting substance included in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of the pair of electrodes of the light-emitting element functions as an anode, and the other electrode functions as a cathode.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

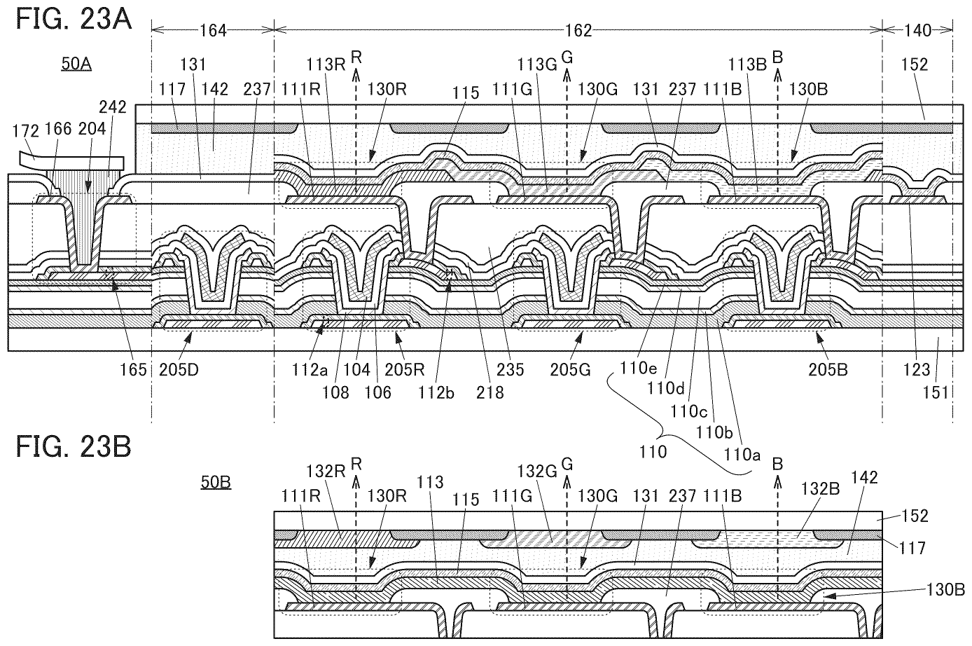

FIG. 23A illustrates an example of cross sections of part of a region including the FPC 172, part of the circuit portion 164, part of the display portion 162, part of the connection portion 140, and part of a region including the end portion of the display device 50A.

The display device 50A illustrated in FIG. 23A includes transistors 205D, 205R, 205G, and 205B, a light-emitting element 130R, a light-emitting element 130G, a light-emitting element 130B, and the like between the substrate 151 and the substrate 152. The light-emitting element 130R is a display element included in the subpixel 11R that emits red light, the light-emitting element 130G is a display element included in the subpixel 11G that emits green light, and the light-emitting element 130B is a display element included in the subpixel 11B that emits blue light.

The display device 50A employs an SBS structure. The SBS structure can optimize materials and structures of light-emitting elements and thus can increase the degree of freedom in selecting materials and structures, so that the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

All of the transistors 205D, 205R, 205G, and 205B are formed over the substrate 151. These transistors can be manufactured using the same material through the same process.

This embodiment describes an example where OS transistors are used as the transistors 205D, 205R, 205G, and 205B. The transistor of one embodiment of the present invention can be used as each of the transistors 205D, 205R, 205G, and 205B. In other words, the display device 50A includes the transistor of one embodiment of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

Specifically, the transistors 205D, 205R, 205G, and 205B each include the conductive layer 104 functioning as a gate, the insulating layer 106 functioning as a gate insulating layer, the conductive layer 112a and the conductive layer 112b functioning as a source and a drain, the semiconductor layer 108 including a metal oxide, and the insulating layer 110. Here, a plurality of layers obtained by processing the same conductive film are illustrated with the same hatching pattern. The insulating layer 110 is positioned between the conductive layer 112a and the semiconductor layer 108. The insulating layer 106 is positioned between the conductive layer 104 and the semiconductor layer 108.

In this embodiment, an example in which the transistor 100B described in Embodiment 1 is used as each of the transistors 205D, 205R, 205G, and 205B is described. Specifically, an example in which the insulating layer 110 has a five-layer structure of the insulating layers 110a, 110b, 110c, 110d, and 110e is described. In the example, the conductive layer 112a and the conductive layer 112b each have a two-layer structure in which the top surface and the side surface of the lower layer are covered with the upper layer.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Gates may be provided above and below a semiconductor layer where a channel is formed.

A Si transistor may be included in the display device of this embodiment.

To increase the emission luminance of the light-emitting element included in the pixel circuit, it is necessary to increase the amount of current flowing through the light-emitting element. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Thus, with the use of an OS transistor as a driving transistor included in the pixel circuit, the amount of current flowing through the light-emitting element can be increased, resulting in an increase in emission luminance of the light-emitting element.

When transistors operate in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be set minutely by a change in gate-source voltage; hence, the amount of current flowing through the light-emitting element can be controlled. Therefore, the number of gray levels in the pixel circuit can be increased.

In addition, regarding saturation characteristics of current flowing when a transistor operates in a saturation region, even in the case where the source-drain voltage of an OS transistor gradually increases, more stable current (saturation current) can be fed through the OS transistor than through a Si transistor. Thus, by using an OS transistor as the driving transistor, a stable current can be fed through light-emitting elements even when the current-voltage characteristics of the light-emitting elements vary, for example. In other words, when the OS transistor operates in the saturation region, the source-drain current hardly changes with a change in the source-drain voltage; hence, the emission luminance of the light-emitting element can be stable.

The transistor included in the circuit portion 164 and the transistor included in the display portion 162 may have the same structure or different structures. One kind of structure or two or more kinds of structures may be employed for a plurality of transistors included in the circuit portion 164. Similarly, one kind of structure or two or more kinds of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a favorable example, a structure is given in which an OS transistor is used as a transistor functioning as a switch for controlling electrical continuity and discontinuity between wirings and an LTPS transistor is used as a transistor for controlling a current.

For example, one transistor included in the display portion 162 functions as a transistor for controlling current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. This is because the insulating layer 218 can function as a barrier layer. Such a structure can effectively inhibit diffusion of impurities into the transistors from the outside and increase the reliability of the display device.

The insulating layer 218 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, the formation of a depression in the insulating layer 235 can be inhibited in processing pixel electrodes 111R, 111G, and 111B, for example. Alternatively, a depression may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 23A emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 23A emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 23A emits blue light (B). The EL layer 113B includes a light-emitting layer that emits blue light.

Although the EL layers 113R, 113G, and 113B have the same thickness in FIG. 23A, the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. In that case, a microcavity structure is obtained, and the color purity of light emitted from each light-emitting element can be improved.

The pixel electrode 111R is electrically connected to the conductive layer 112b included in the transistor 205R through an opening provided in the insulating layer 106, the insulating layer 218, and the insulating layer 235. In a similar manner, the pixel electrode 111G is electrically connected to the conductive layer 112b included in the transistor 205G, and the pixel electrode 111B is electrically connected to the conductive layer 112b included in the transistor 205B.

As described above, an example in which the conductive layer 112b has a two-layer structure in which the top surface and the side surface of the lower layer are covered with the upper layer is described in this embodiment. FIG. 23A illustrates an example in which an opening is provided in the upper layer of the conductive layer 112b and the pixel electrode is in contact with the top surface of the lower layer of the conductive layer 112b through the opening. In the transistor of one embodiment of the present invention, the conductive layer 112b has a stacked-layer structure. The layer in contact with the pixel electrode is preferably selected from the layers constituting the conductive layer 112b so that the contact resistance between the pixel electrode and the conductive layer 112b can be low. The layer in contact with the pixel electrode may be selected from the adhesion perspective.

For example, in the case where a metal layer or an alloy layer is used as the pixel electrode (or the lowermost layer of the pixel electrode), the top surface of a metal layer or an alloy layer among the layers constituting the conductive layer 112b is preferably in contact with the pixel electrode. In the case where an oxide conductive layer is used as the pixel electrode (or the lowermost layer of the pixel electrode), the top surface of an oxide conductive layer among the layers constituting the conductive layer 112b is preferably in contact with the pixel electrode.

End portions of the pixel electrodes 111R, 111G, and 111B are covered with an insulating layer 237. The insulating layer 237 functions as a partition. The insulating layer 237 can have a single-layer structure or a stacked-layer structure including one or both of an inorganic insulating material and an organic insulating material. A material that can be used for the insulating layer 218 and a material that can be used for the insulating layer 235 can be used for the insulating layer 237, for example. The insulating layer 237 can electrically isolate the pixel electrode and the common electrode. Furthermore, the insulating layer 237 can electrically isolate light-emitting elements adjacent to each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display device 50A.

The common electrode 115 is one continuous film shared by the light-emitting elements 130R, 130G, and 130B. The common electrode 115 shared by the light-emitting elements is electrically connected to a conductive layer 123 provided in the connection portion 140. The conductive layer 123 is preferably formed using a conductive layer formed using the same material through the same process as the pixel electrodes 111R, 111G, and 111B.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (also referred to as an In—Sn oxide or an ITO), an In—Si—Sn oxide (also referred to as an ITSO), an indium zinc oxide (an In—Zn oxide), and an In—W—Zn oxide. Other examples of the material include an alloy containing aluminum (an aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element preferably includes an electrode having properties of transmitting and reflecting visible light (a transflective electrode), and the other preferably includes an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 23A, an end portion of the EL layer 113R and an end portion of the EL layer 113G adjacent to each other overlap with each other, an end portion of the EL layer 113G and an end portion of the EL layer 113B adjacent to each other overlap with each other, and an end portion of the EL layer 113R and an end portion of the EL layer 113B adjacent to each other overlap with each other. When island-shaped EL layers are formed using a fine metal mask, end portions of the EL layers adjacent to each other may overlap with each other as illustrated in FIG. 23A; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layers 113R, 113G, and 113B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex—Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a substance with a bipolar property and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure can also be referred to as a stack structure.

In the case of using a tandem light-emitting element in FIG. 23A, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements. In FIG. 23A, a solid sealing structure is employed in which a space between the substrate 152 and the substrate 151 is filled with the adhesive layer 142. Alternatively, a hollow sealing structure may be employed in which the space is filled with an inert gas (e.g., nitrogen or argon). In that case, the adhesive layer 142 may be provided not to overlap with the light-emitting elements. Furthermore, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is preferable that the protective layer 131 be provided to extend to the end portion of the display device 50A. Meanwhile, a connection portion 204 has a portion not provided with the protective layer 131 so that the FPC 172 and a conductive layer 166 are electrically connected to each other.

By providing the protective layer 131 over the light-emitting elements 130R, 130G, and 130B, the reliability of the light-emitting elements can be increased.

The protective layer 131 can have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film including an ITO, an In—Zn oxide, a Ga—Zn oxide, an Al—Zn oxide, an IGZO, or the like can be used for the protective layer 131. The inorganic film preferably has high resistance, specifically, higher resistance than the common electrode 115. The inorganic film may further include nitrogen.

When light emitted from the light-emitting element is extracted through the protective layer 131, the protective layer 131 preferably has a high visible-light-transmitting property. For example, an ITO, an IGZO, and aluminum oxide are preferable because they are inorganic materials having a high visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 151 not overlapping with the substrate 152. In the connection portion 204, the conductive layer 165 is electrically connected to the FPC 172 through the conductive layer 166 and a connection layer 242. In this example, the conductive layer 165 is a conductive layer having a stacked-layer structure obtained by processing the same conductive films as the conductive layer 112b. In this example, the conductive layer 166 is a conductive layer obtained by processing the same conductive film as the pixel electrodes 111R, 111G, and 111B. A structure similar to that of the connection portion between the pixel electrode and the conductive layer 112b can be applied to the connection portion between the conductive layer 165 and the conductive layer 166. Specifically, FIG. 23A illustrates an example in which an opening is provided in the upper layer of the conductive layer 165 and the conductive layer 166 is in contact with the top surface of the lower layer of the conductive layer 165 through the opening. On the top surface of the connection portion 204, the conductive layer 166 is exposed. Thus, the connection portion 204 and the FPC 172 can be electrically connected to each other through the connection layer 242.

The display device 50A has a top-emission structure. Light from the light-emitting element is emitted toward the substrate 152. For the substrate 152, a material having a high visible-light-transmitting property is preferably used. The pixel electrodes 111R, 111G, and 111B include a material that reflects visible light, and the counter electrode (the common electrode 115) includes a material that transmits visible light.

The light-blocking layer 117 is preferably provided on the surface of the substrate 152 on the substrate 151 side. The light-blocking layer 117 can be provided over a region between adjacent light-emitting elements, in the connection portion 140, and in the circuit portion 164, for example.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an inkjet method, an etching method using a photolithography method, or the like.

Moreover, a variety of optical members can be provided on the outer surface of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer to inhibit the surface contamination and damage. For the surface protective layer, DLC (diamond-like carbon), aluminum oxide (AlOₓ), a polyester-based material, a polycarbonate-based material, or the like may be used. The surface protective layer is preferably formed using a material having high visible light transmittance. The surface protective layer is preferably formed using a material with high hardness.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As the connection layer 242, an anisotropic conductive film (ACF), an anisotropic conductive paste (ACP), or the like can be used.

### Display Device 50b

FIG. 23B illustrates an example of a cross section of the display portion 162 of a display device 50B. The display device 50B is different from the display device 50A mainly in that the subpixels of different colors include respective coloring layers (color filters or the like) and the light-emitting elements that share an EL layer 113. The structure illustrated in FIG. 23B can be combined with the structure of the region including the FPC 172, the circuit portion 164, the stacked-layer structure from the substrate 151 to the insulating layer 235 in the display portion 162, the connection portion 140, and the end portion, which is illustrated in FIG. 23A. In the following description of display devices, the description of portions similar to those of the above-described display device may be omitted.

The display device 50B illustrated in FIG. 23B includes the light-emitting elements 130R, 130G, and 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing steps can be smaller in the case where the EL layer 113 is shared between the subpixels of different colors than the case where the subpixels of different colors include different EL layers.

The light-emitting elements 130R, 130G, and 130B illustrated in FIG. 23B emit white light, for example. When white light emitted from the light-emitting elements 130R, 130G, and 130B passes through the coloring layers 132R, 132G, and 132B, light of desired colors can be obtained.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are stacked in this order; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element emitting white light has a microcavity structure, light with a specific wavelength such as red, green, or blue is sometimes intensified to be emitted.

Alternatively, the light-emitting elements 130R, 130G, and 130B illustrated in FIG. 23B emit blue light, for example. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### Display Device 50C

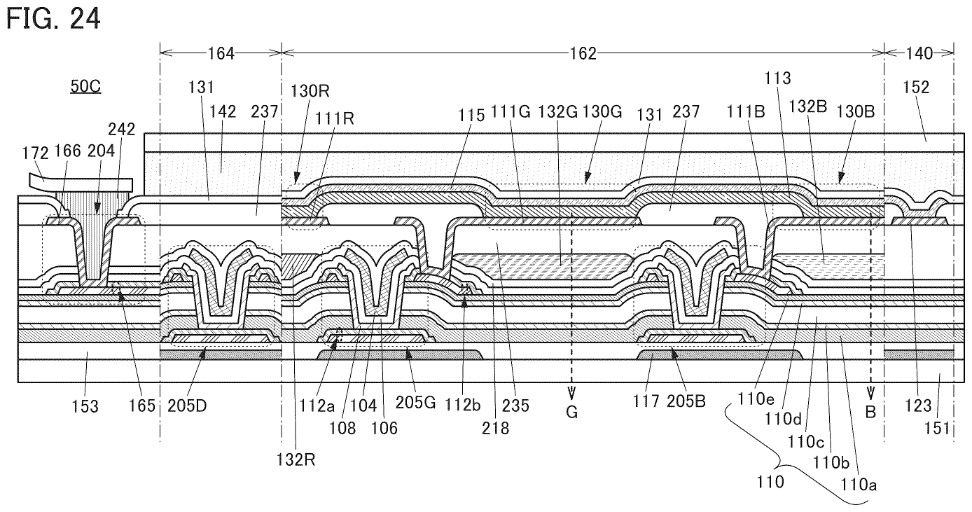

A display device 50C illustrated in FIG. 24 is different from the display device 50B mainly in having a bottom-emission structure.

Light from the light-emitting element is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 24 illustrates an example where the light-blocking layers 117 are provided over the substrate 151, an insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111R, 111G, and 111B. A material that reflects visible light is preferably used for the common electrode 115. In the display device having a bottom-emission structure, a metal or the like having low resistance can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

### Display Device 50D

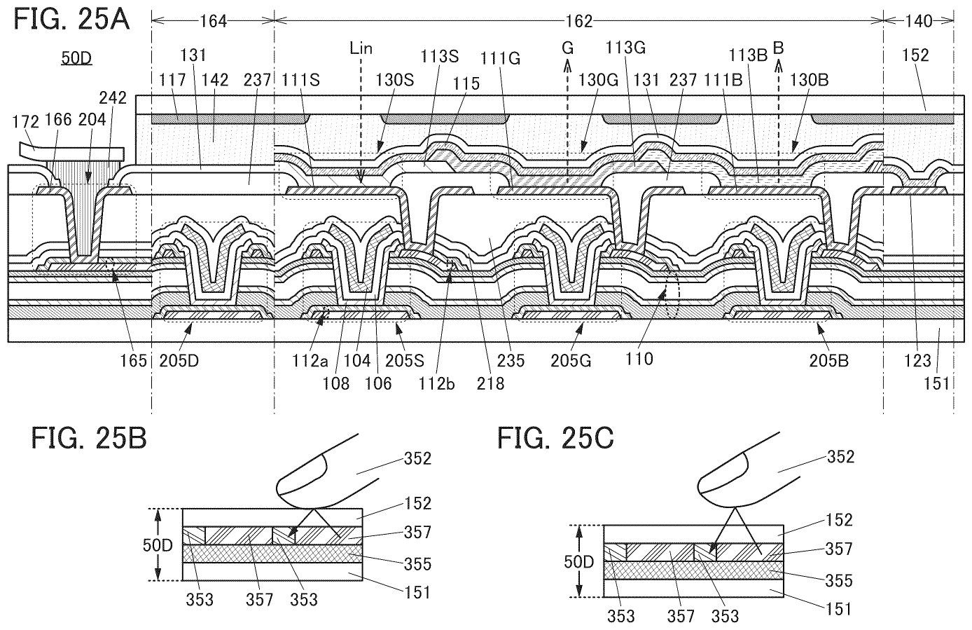

A display device 50D illustrated in FIG. 25A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiodes can be formed over the same substrate. Thus, the organic photodiodes can be incorporated in a display device including the organic EL elements.

The display device 50D can detect the touch or approach of an object while displaying an image because the pixel includes the light-emitting element and the light-receiving element and thus has a light-receiving function. Accordingly, the display portion 162 has one or both of an image capturing function and a sensing function in addition to a function of displaying an image. For example, an image can be displayed by using all the subpixels included in the display device 50D; or light can be emitted by some of the subpixels as a light source, light can be detected by some other subpixels, and an image can be displayed by using the remaining subpixels.

Accordingly, a light-receiving portion and a light source do not need to be provided separately from the display device 50D; hence, the number of components of an electronic device can be reduced. For example, a biometric authentication device provided in the electronic device, a capacitive touch panel for scroll operation, or the like is not necessarily provided separately. Thus, with the use of the display device 50D, an electronic device can be provided at lower manufacturing costs.

When the light-receiving elements are used for an image sensor, the display device 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

Moreover, the light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect the object even when the object is not in contact with the display device.

The light-receiving element 130S includes a pixel electrode 111S over the insulating layer 235, a functional layer 113S over the pixel electrode 111S, and the common electrode 115 over the functional layer 113S. The functional layer 113S is irradiated with light Lin coming from the outside of the display device 50D.

The pixel electrode 111S is electrically connected to the conductive layer 112b included in a transistor 205S through an opening provided in the insulating layer 106, the insulating layer 218, and the insulating layer 235.

An end portion of the pixel electrode 111S is covered with the insulating layer 237.

The common electrode 115 is one continuous film shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment illustrates an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer including a substance having a high hole-transport property, a substance having a high electron-transport property, a substance having a bipolar property, or the like. Without limitation to the above, the functional layer 113S may further include a layer including a substance having a high hole-injection property, a hole-blocking material, a substance having a high electron-injection property, an electron-blocking material, or the like. The functional layer 113S can be formed using a material that can be used for the light-emitting element, for example.

Either a low molecular compound or a high molecular compound can be used in the light-receiving element, and an inorganic compound may also be included. Each layer included in the light-receiving element can be formed by an evaporation method (including a vacuum evaporation method), a transfer method, a printing method, an inkjet method, a coating method, or the like.

In the display device 50D illustrated in FIG. 25B and FIG. 25C, a layer 353 including a light-receiving element, a circuit layer 355, and a layer 357 including a light-emitting element are provided between the substrate 151 and the substrate 152.

The layer 353 includes the light-receiving element 130S, for example. The layer 357 includes the light-emitting elements 130R, 130G, and 130B, for example.

The circuit layer 355 includes a circuit for driving a light-receiving element and a circuit for driving a light-emitting element. The circuit layer 355 includes the transistors 205R, 205G, and 205B, for example. The circuit layer 355 can further include one or more of a switch, a capacitor, a resistor, a wiring, a terminal, and the like.

FIG. 25B illustrates an example where the light-receiving element 130S is used as a touch sensor. Light emitted from the light-emitting element in the layer 357 is reflected by a finger 352 that touches the display device 50D as illustrated in FIG. 25B; then, the light-receiving element in the layer 353 senses the reflected light. Thus, the touch of the finger 352 on the display device 50D can be detected.

FIG. 25C illustrates an example where the light-receiving element 130S is used as a contactless sensor. Light emitted from the light-emitting element in the layer 357 is reflected by the finger 352 that is close to (i.e., that does not touch) the display device 50D as illustrated in FIG. 25C; then, the light-receiving element in the layer 353 senses the reflected light.

### Display Device 50e

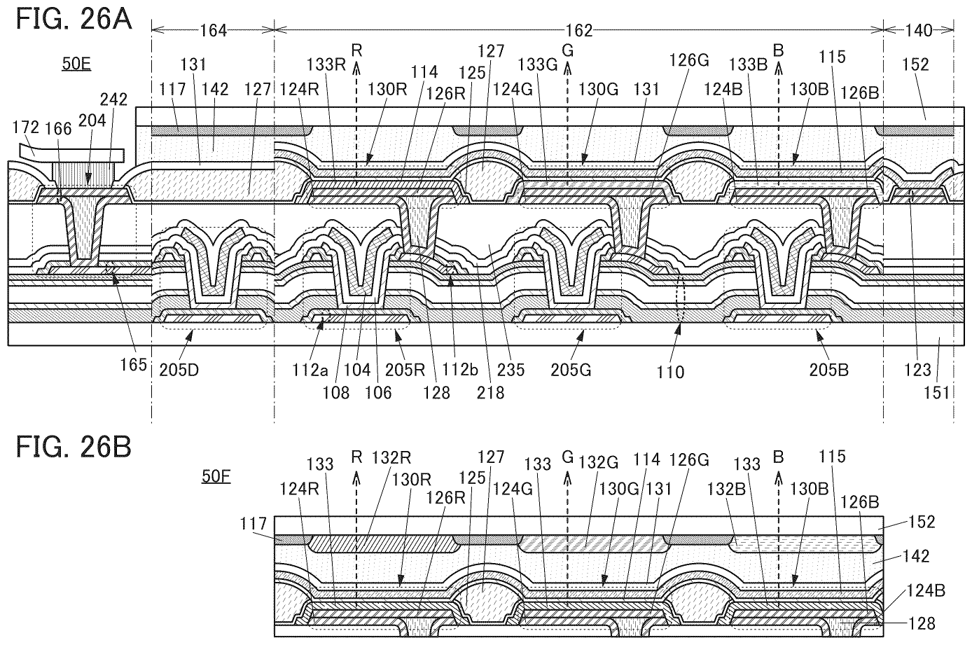

A display device 50E illustrated in FIG. 26A is an example of a display device having an MML (metal maskless) structure. In other words, the display device 50E includes a light-emitting element that is formed without using a fine metal mask.

An island-shaped light-emitting layer of the light-emitting element included in the display device having an MML structure is formed by forming a light-emitting layer on the entire surface and then processing the light-emitting layer by a photolithography method. Accordingly, a high-resolution display device or a display device with a high aperture ratio, which has been difficult to achieve so far, can be achieved. Moreover, light-emitting layers can be formed separately for the respective colors, enabling the display device to perform extremely clear display with high contrast and high display quality. In the case where the display device includes three kinds of light-emitting elements, which are a light-emitting element emitting blue light, a light-emitting element emitting green light, and a light-emitting element emitting red light, for example, three kinds of island-shaped light-emitting layers can be formed by repeating formation of a light-emitting layer and processing by photolithography three times.

A device having an MML structure can be manufactured without using a metal mask, and thus can break through the resolution limit due to alignment accuracy of the metal mask. Furthermore, manufacturing a device without using a metal mask can eliminate the need for the manufacturing facilities of a metal mask and the cleaning step of the metal mask. For the processing by photolithography, an apparatus that is the same as or similar to an apparatus used for manufacturing a transistor can be used; thus, there is no need to introduce a special apparatus to manufacture the device having an MML structure. The MML structure can reduce the manufacturing cost as described above, and thus is suitable for mass production of the device.

A display device having an MML structure does not require a pseudo improvement in resolution by employing unique pixel arrangement such as PenTile arrangement, for example; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

Providing a sacrificial layer over a light-emitting layer can reduce damage to the light-emitting layer in the manufacturing process of the display device, resulting in an increase in reliability of the light-emitting element.

Furthermore, employing a film formation step using an area mask and a processing step using a resist mask enables a light-emitting element to be manufactured by a relatively easy process.

The stacked-layer structure from the substrate 151 to the insulating layer 235 and the stacked-layer structure from the protective layer 131 to the substrate 152 are similar to those in the display device 50A; therefore, description thereof is omitted.

In FIG. 26A, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 26A emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 26A emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 26A emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. Note that in this specification and the like, the layer 133R, the layer 133G, and the layer 133B are sometimes referred to as island-shaped EL layers, EL layers formed in island shapes, or the like, in which case the common layer 114 is not included. The light-emitting elements formed without using a metal mask do not necessarily include a common layer, and all the layers included in the EL layer may be formed in island shapes.

The layer 133R, the layer 133G, and the layer 133B are isolated from each other. When the EL layer is provided to have an island shape for each light-emitting element, a leakage current between adjacent light-emitting elements can be inhibited. This can prevent crosstalk-induced unintended light emission, so that a display device with extremely high contrast can be obtained.

Although the layers 133R, 133G, and 133B have the same thickness in FIG. 26A, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 218, and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressions of the conductive layers 124R, 124G, and 124B.

The layer 128 has a function of filling the depressions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 26A illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover a side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0 degrees and less than 90 degrees. In the case where the end portions of the pixel electrodes have a tapered shape, the layer 133R provided along side surfaces of the pixel electrodes has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted. In FIG. 26, the conductive layer 123 and the conductive layer 166 each have a stacked-layer structure of a conductive layer obtained by processing the same conductive film as the conductive layers 124R, 124G, and 124B and a conductive layer obtained by processing the same conductive film as the conductive layers 126R, 126G, and 126B.

The top and side surfaces of the conductive layer 126R are covered with the layer 133R. Similarly, the top and side surfaces of the conductive layers 126G are covered with the layer 133G, and the top and side surfaces of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with insulating layers 125 and 127. The common layer 114 is provided over the layer 133R, the layer 133G, the layer 133B, and the insulating layers 125 and 127, and the common electrode 115 is provided over the common layer 114. The common layer 114 and the common electrode 115 are each a continuous film provided to be shared by a plurality of light-emitting elements.

In FIG. 26A, the insulating layer 237 illustrated in FIG. 23A or the like is not provided between the conductive layer 126R and the layer 133R. That is, an insulating layer (also referred to as a partition wall, a bank, a spacer, or the like) that is in contact with the pixel electrode and covers an upper end portion of the pixel electrode is not provided in the display device 50E. Thus, the interval between adjacent light-emitting elements can be extremely shortened. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surface and part of the top surface of each of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depression of the insulating layer 125. The insulating layer 127 preferably covers at least part of a side surface of the insulating layer 125.

Providing the insulating layer 125 and the insulating layer 127 makes it possible to fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, a step is generated due to a level difference between a region where the pixel electrode and the island-shaped EL layer are provided and a region where neither the pixel electrode nor the island-shaped EL layer is provided (a region between the light-emitting elements). In the display device of one embodiment of the present invention, the step can be eliminated with the insulating layer 125 and the insulating layer 127, and the coverage with the common layer 114 and the common electrode 115 can be improved. Thus, connection defects caused by step disconnection can be inhibited. In addition, an increase in electric resistance, which is caused by local thinning of the common electrode 115 due to the step, can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a convex shape with a large radius of curvature.

The insulating layer 125 can be formed using an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer, entry of impurities (typified by at least one of water and oxygen) that would be diffused into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer including an organic material can be favorably used. As the organic material, a photosensitive resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### Display Device 50f

FIG. 26B illustrates an example of a cross section of the display portion 162 of a display device 50F. The display device 50F is different from the display device 50E mainly in that the subpixels of different colors include respective coloring layers (color filters or the like) and respective layers 133 in the light-emitting elements. The structure illustrated in FIG. 26B can be combined with the structure of the region including the FPC 172, the circuit portion 164, the stacked-layer structure from the substrate 151 to the insulating layer 235 in the display portion 162, the connection portion 140, and the end portion, which is illustrated in FIG. 26A.

The display device 50F illustrated in FIG. 26B includes the light-emitting elements 130R, 130G, and 130B, the coloring layer 132R transmitting red light, the coloring layer 132G transmitting green light, the coloring layer 132B transmitting blue light, and the like.

Light emitted from the light-emitting element 130R is extracted as red light to the outside of the display device 50F through the coloring layer 132R. Similarly, light emitted from the light-emitting element 130G is extracted as green light to the outside of the display device 50F through the coloring layer 132G. Light emitted from the light-emitting element 130B is extracted as blue light to the outside of the display device 50F through the coloring layer 132B.

The light-emitting elements 130R, 130G, and 130B each include the layer 133. The three layers 133 are formed using the same process and the same material. The three layers 133 are isolated from each other. When the EL layer is provided to have an island shape for each light-emitting element, a leakage current between adjacent light-emitting elements can be inhibited. This can prevent crosstalk-induced unintended light emission, so that a display device with extremely high contrast can be obtained.

The light-emitting elements 130R, 130G, and 130B illustrated in FIG. 26B emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 26B emit blue light, for example. In this case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and color purity of light exhibited by a subpixel can be improved.

### Display Device 50g

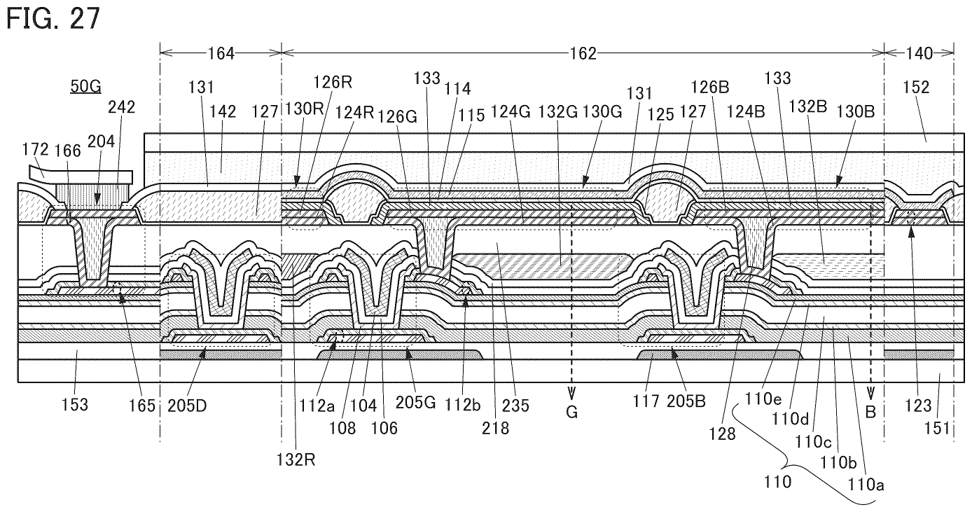

A display device 50G illustrated in FIG. 27 is different from the display device 50F mainly in having a bottom-emission structure.

Light from the light-emitting element is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 27 illustrates an example where the light-blocking layers 117 are provided over the substrate 151, the insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a high visible-light-transmitting property is used for each of the conductive layers 124R, 124G, 124B, 126R, 126G, and 126B. A material that reflects visible light is preferably used for the common electrode 115. In the display device having a bottom-emission structure, a metal or the like having low resistance can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

This embodiment can be combined with the other embodiments as appropriate.

### Embodiment 4

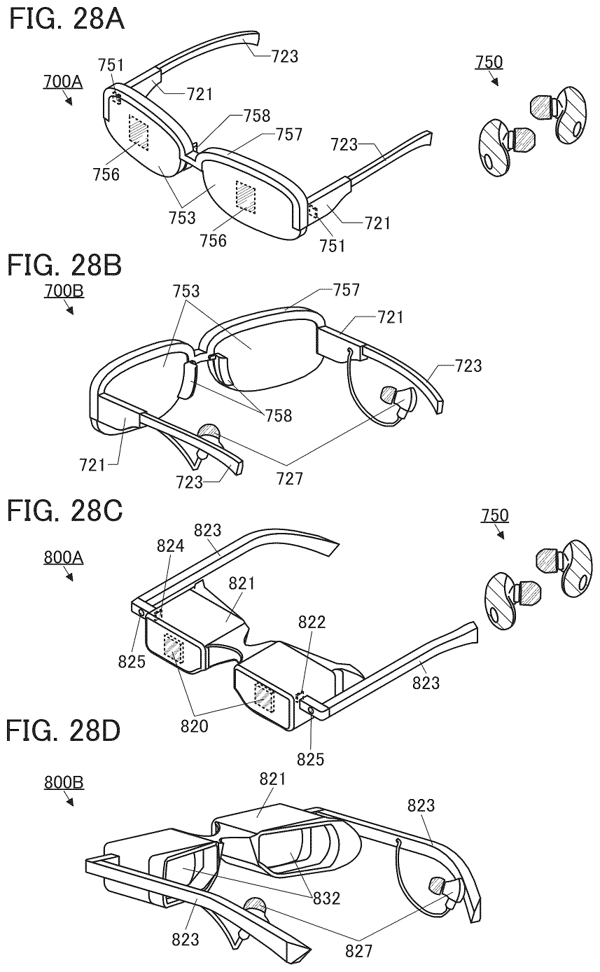

In this embodiment, electronic devices of one embodiment of the present invention will be described with reference to FIG. 28 to FIG. 30.

Electronic devices in this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to a portion other than a display portion in an electronic device. For example, the semiconductor device of one embodiment of the present invention is preferably used for a control portion or the like of an electronic device to enable lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280 x 720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, still further preferably 500 ppi or higher, yet still further preferably 1000 ppi or higher, yet still further preferably 2000 ppi or higher, yet still further preferably 3000 ppi or higher, yet still further preferably 5000 ppi or higher, yet still further preferably 7000 ppi or higher. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIG. 28A to FIG. 28D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 28A and an electronic device 700B illustrated in FIG. 28B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are each provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 28C and an electronic device 800B illustrated in FIG. 28D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

Each of the electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be mounted on the user's head with the wearing portions 823. FIG. 28C and the like illustrate examples where the wearing portion 823 has a shape like a temple of glasses; however, one embodiment of the present invention is not limited thereto. The wearing portion 823 can have a shape with which the user can wear the electronic device and may have a shape of a helmet or a band, for example.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portion 825 is included is illustrated here, without limitation thereto, a range sensor that is capable of measuring the distance to an object (hereinafter such a sensor is also referred to as a sensing portion) can be provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic device 800A may include a vibration mechanism that functions as a bone-conduction earphone. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 28A has a function of transmitting information to the earphones 750 with the wireless communication function. As another example, the electronic device 800A in FIG. 28C has a function of transmitting information to the earphones 750 with the wireless communication function.

The electronic device may include an earphone portion. The electronic device 700B in FIG. 28B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 28D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (the electronic device 700A, the electronic device 700B, or the like) and the goggles-type device (the electronic device 800A, the electronic device 800B, or the like) are suitable as the electronic device of one embodiment of the present invention.

The electronic device of one embodiment of the present invention can transmit information to earphones by wire or wirelessly.

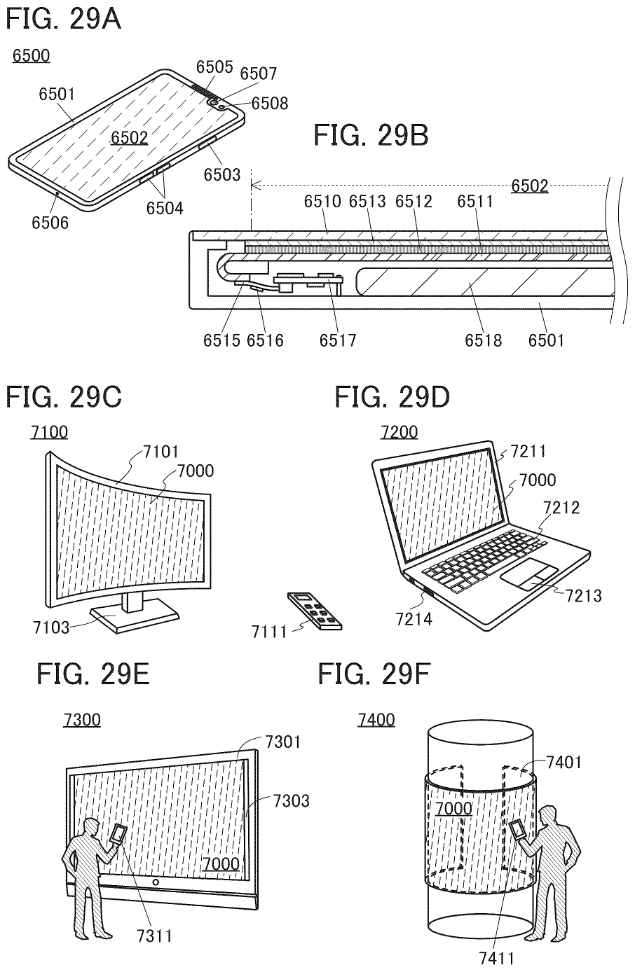

An electronic device 6500 illustrated in FIG. 29A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 29B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 29C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 29C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

The television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 29D illustrates an example of a notebook personal computer. The notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 29E and FIG. 29F illustrate examples of digital signage.

Digital signage 7300 illustrated in FIG. 29E includes a housing 7301, the display portion 7000, a speaker 7303, and the like. Furthermore, an LED lamp, an operation key (including a power switch or an operation switch), a connection terminal, a variety of sensors, a microphone, and the like can be included.

FIG. 29F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIG. 29E and FIG. 29F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 29E and FIG. 29F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

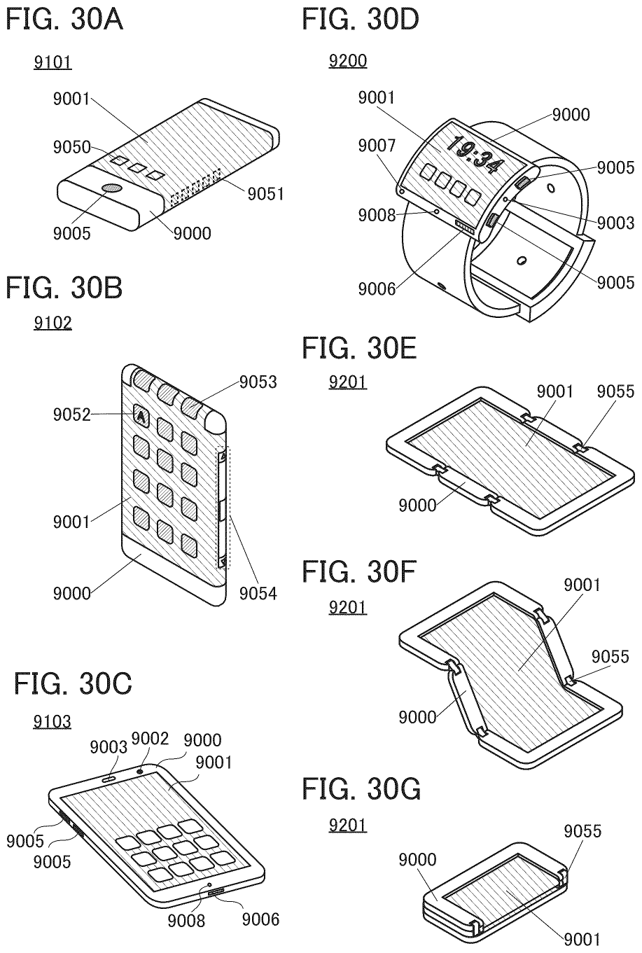

Electronic devices illustrated in FIG. 30A to FIG. 30G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIG. 30A to FIG. 30G, the display device of one embodiment of the present invention can be used in the display portion 9001.

The electronic devices illustrated in FIG. 30A to FIG. 30G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. The functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIG. 30a to FIG. 30g will be described in detail below.

FIG. 30A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 30A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 30B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 30C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 30D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 30E to FIG. 30G are perspective views of a foldable portable information terminal 9201. FIG. 30E is a perspective view illustrating the portable information terminal 9201 that is opened. FIG. 30G is a perspective view illustrating the portable information terminal 9201 that is folded. FIG. 30F is a perspective view illustrating the portable information terminal 9201 that is shifted from one of the states in FIG. 30E and FIG. 30G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example 1

This example shows manufacture and evaluation results of transistors of one embodiment of the present invention.

In this example, three kinds of samples (Sample A, Sample B, and Sample C) were fabricated. Sample A is a transistor corresponding to the structure of the transistor 100B illustrated in FIG. 8A and FIG. 8B. Sample B and Sample C are each different from Sample A in the structure of the conductive layer 112b. Specifically, the conductive layer 112b has a two-layer structure in Sample A, the conductive layer 112b has a three-layer structure (see FIG. 5B) in Sample B, and the conductive layer 112b has a single-layer structure (see FIG. 5A) in Sample C.

Specific methods for manufacturing the transistors will be described below with reference to FIG. 19 to FIG. 21.

First, an approximately 300-nm-thick copper film was formed over a glass substrate (corresponding to the substrate 102) by a sputtering method and processed, so that the conductive layer 182a was formed. Next, an approximately 100-nm-thick ITSO film was formed over the glass substrate and the conductive layer 182a by a sputtering method and processed, so that the conductive layer 122a covering the top surface and the side surface of the conductive layer 182a was formed (FIG. 19A). In the above-described manner, the conductive layer 112a was formed.

Next, an insulating film 110af (not illustrated), the insulating film 110bf, and the insulating film 110cf were formed in this order over the substrate 102 and the conductive layer 112a (FIG. 19B).

As the insulating film 110af, an approximately 70-nm-thick silicon nitride film was formed by a PECVD method. As the insulating film 110 bf, an approximately 100-nm-thick silicon nitride film was formed by a PECVD method. As the insulating film 110cf, an approximately 500-nm-thick silicon oxynitride film was formed by a PECVD method. The insulating film 110af was formed under a condition with a higher proportion of the flow rate of a NH₃ gas with respect to the total flow rate of a film formation gas than that for the insulating film 110bf. The insulating film 110cf was formed under a condition with an F ratio of 6. Each of the insulating films was formed under a condition with a substrate temperature of 350° C.

Next, over the insulating film 110cf, an approximately 20-nm-thick In—Ga—Zn oxide film was formed, so that the metal oxide layer 149 was formed (FIG. 19C). The In—Ga—Zn oxide film was formed by a sputtering method using a metal oxide target whose atomic ratio was In:Ga:Zn=1:1:1 with an oxygen flow rate ratio of 100% at a substrate temperature of room temperature. After the formation of the In—Ga—Zn oxide film, heat treatment was performed at 250° C. for one hour. After that, the metal oxide layer 149 was removed by a wet etching method.

Next, the insulating film 110df and an insulating film 110ef (not illustrated) were formed over the insulating film 110cf (FIG. 19D).

As the insulating film 110df, an approximately 50-nm-thick silicon nitride film was formed by a PECVD method. As the insulating film 110 ef, an approximately 100-nm-thick silicon nitride film was formed by a PECVD method. The insulating film 110ef was formed under a condition with a higher proportion of the flow rate of a NH₃ gas with respect to the total flow rate of a film formation gas than that for the insulating film 110df. For Sample A, an approximately 30-nm-thick silicon nitride film was further formed over the insulating film 110 ef by a PECVD method under a condition with a lower proportion of the flow rate of a NH₃ gas with respect to the total flow rate of a film formation gas than that for the insulating film 110ef. Each of the insulating films was formed under a condition with a substrate temperature of 350° C.

Next, for Sample A, an approximately 50-nm-thick copper film was formed over the silicon nitride film (see the conductive film 182f in (FIG. 20A)) and processed to form the conductive layer 182b (FIG. 20B). Next, an approximately 100-nm-thick ITSO film was formed over the silicon nitride film and the conductive layer 182b by a sputtering method (see the conductive film 122f in FIG. 20C) and processed to form the conductive layer 122b covering the top surface and the side surface of the conductive layer 182b (FIG. 21A). Through the above-described steps, the conductive layer 112b was formed. The opening 143 was provided in the conductive layer 112b by a wet etching method. For Sample A, a silicon nitride film was provided over the insulating film 110ef, and then a copper film was formed as the conductive film 182f. Providing the silicon nitride film can inhibit diffusion of copper into the insulating layer 110.

For Sample B, the conductive layer 112b as illustrated in FIG. 5B was formed. Specifically, an approximately 50-nm-thick ITSO film was used as the conductive layer 184b, an approximately 50-nm-thick copper film was used as the conductive layer 182b, and an approximately 50-nm-thick ITSO film was used as the conductive layer 122b. Since the copper film is formed over the ITSO film in Sample B, diffusion of copper into the insulating layer 110 can be inhibited.

For Sample C, the conductive layer 112b as illustrated in FIG. 5A was formed. Specifically, an approximately 100-nm-thick ITSO film was used as the conductive layer 112b.

Furthermore, the insulating films were processed by a dry etching method to form the insulating layer 110 including the opening 141 (FIG. 21A).

Next, a metal oxide film was formed over the insulating layer 110 and the conductive layer 112b and processed to form the semiconductor layer 108 (FIG. 21B).

As the metal oxide film, an approximately 20-nm-thick In—Ga—Zn oxide film was formed. The In—Ga—Zn oxide film was formed by a sputtering method using a metal oxide target whose atomic ratio was In:Ga:Zn=1:1:1 with an oxygen flow rate ratio of 10% at a substrate temperature of room temperature. After the formation of the In—Ga—Zn oxide film, heat treatment was performed at 350° C. in a CDA atmosphere for one hour.

Next, the insulating layer 106 was formed over the insulating layer 110, the conductive layer 112b, and the semiconductor layer 108 (FIG. 21B).

As the insulating layer 106, an approximately 50-nm-thick silicon oxynitride film was formed by a PECVD method. The insulating layer 106 was formed under a condition with an F ratio of 5.

Next, a film to be the conductive layer 104 were formed over the insulating layer 106 and was processed, so that the conductive layer 104 was formed (FIG. 21B).

As the film to be the conductive layer 104, an approximately 50-nm-thick titanium film, an approximately 200-nm-thick aluminum film, and an approximately 50-nm-thick titanium film were formed in this order by a sputtering method.

After that, as an insulating layer (not illustrated) covering the transistor, an approximately 300-nm-thick silicon nitride oxide film was formed by a PECVD method. After that, heat treatment was performed at 300° C. in a CDA atmosphere for one hour. After that, an approximately 1.5-μm-thick polyimide film was formed as a planarization film (not illustrated) and heat treatment was performed at 250° C. in a nitrogen atmosphere for one hour.

Through the above-described process, transistors of this example were fabricated.

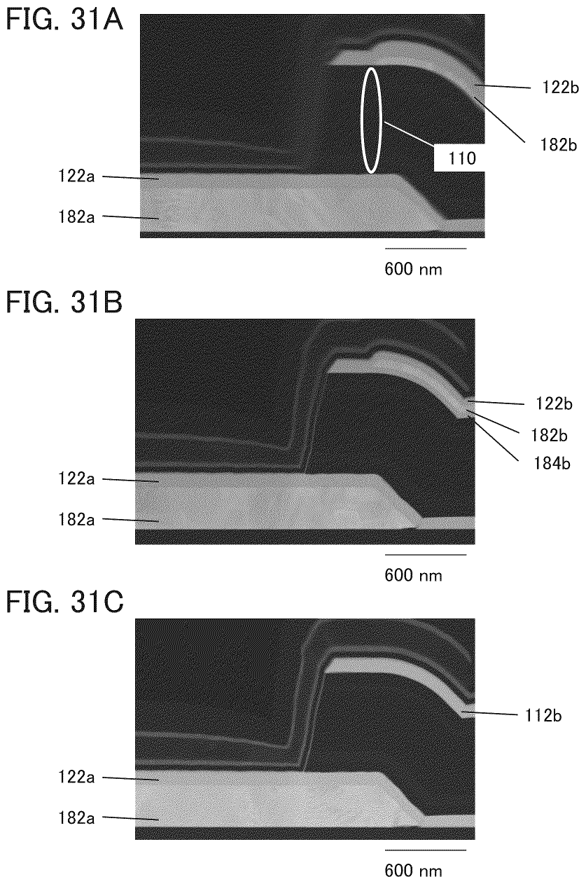

Next, cross-sectional STEM (Scanning Transmission Electron Microscopy) observation of the samples was performed. FIG. 31A shows a cross-sectional STEM image of Sample A, FIG. 31B shows a cross-sectional STEM image of Sample B, and FIG. 31C shows a cross-sectional STEM image of Sample C. FIG. 31A to FIG. 31C show Z contrast (ZC) images. A substance having a larger atomic number is observed brighter in a ZC image.

FIG. 31A to FIG. 31C show that the conductive layer 122a is provided to cover the top surface and the side surface of the conductive layer 182a in each sample. FIG. 31A and FIG. 31B show that the conductive layer 122b is provided to cover the top surface and the side surface of the conductive layer 182b. FIG. 31B shows that an end portion of the conductive layer 182b is positioned over the conductive layer 184b, and the conductive layer 184b and the conductive layer 122b are in contact with each other in a region beyond the end portion. That is, the top surface, the side surface, and the bottom surface of the conductive layer 182b are surrounded by the conductive layer 184b and the conductive layer 122b. FIG. 31C shows that the conductive layer 112b has a single-layer structure. Thus, it was found that the structure of each sample in FIG. 8A, FIG. 5B, or FIG. 5A was fabricated as intended.

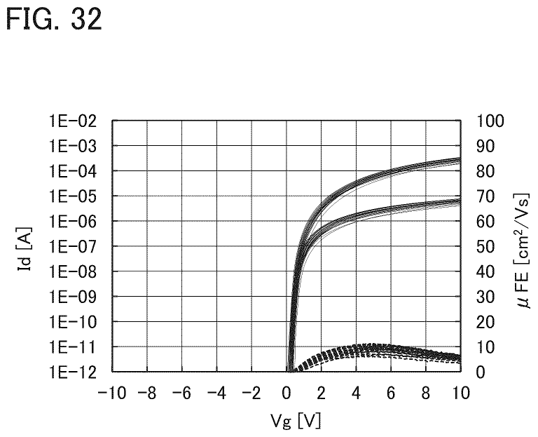

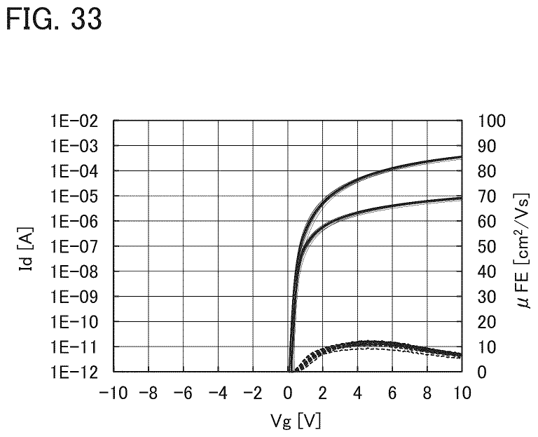

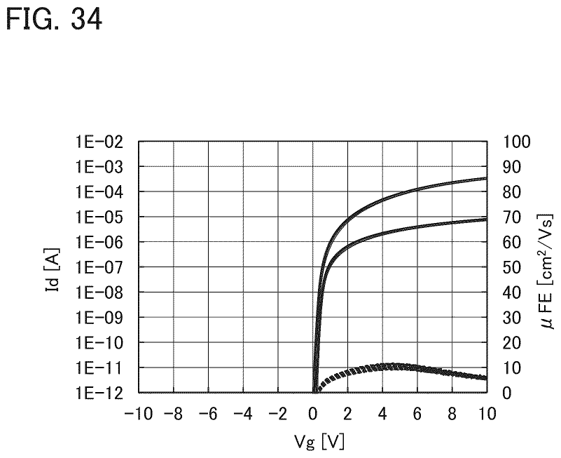

Next, the Id-Vg characteristics of the transistors fabricated in this example were measured. FIG. 32 shows the results of the Id-Vg characteristics of Sample A. FIG. 33 shows the results of the Id-Vg characteristics of Sample B. FIG. 34 shows the results of the Id-Vg characteristics of Sample C.

FIG. 32 to FIG. 34 show the results in the case where the conductive layer 112b served as a source electrode.

In FIG. 32 to FIG. 34, the vertical axes represent a drain current (Id (A)) and field-effect mobility (μFE (cm²/Vs)) and the horizontal axis represents a gate voltage (Vg (V)). In FIG. 32 to FIG. 34, the solid lines indicate the results of the Id-Vg characteristics and the dotted lines indicate the field-effect mobility. In FIG. 32 to FIG. 34, the results of the Id-Vg characteristics and the field-effect mobility of 20 transistors are superimposed.

Each of the transistors fabricated in this example was an n-channel transistor and was fabricated so that its channel length (L) was 0.5 μm and its channel width (W) was 6.3 μm (the opening diameter was 2 μmφ).

The Id-Vg characteristics of the transistors were measured under the following conditions. The voltage applied to the conductive layer 104 (gate voltage (Vg)) was changed from −10 V to+10 V in increments of 0.1 V. The voltage applied to the source electrode (source voltage (Vs)) was 0 V (common), and the voltage applied to the drain electrode (drain voltage (Vd)) was 0.1 V or 5.1V.

It was confirmed that the transistors fabricated in this example had favorable switching characteristics and high on-state currents as shown in FIG. 32 to FIG. 34.

As described above, in this example, two or more conductive layers containing different metals were used as at least one of the source electrode and the drain electrode, and the transistors having favorable characteristics were able to be fabricated.

### Example 2

This example shows manufacture and evaluation results of transistors of one embodiment of the present invention.

For the samples of this example, the insulating layer 110c was formed by performing the film formation step of the silicon oxynitride film divided into five steps.

Specific methods for manufacturing the transistors will be described below with reference to FIG. 19 to FIG. 21. Descriptions of portions similar to those in Example 1 might be omitted.

First, an approximately 300-nm-thick copper film was formed over a glass substrate (corresponding to the substrate 102) by a sputtering method and processed, so that the conductive layer 182a was formed. Next, an approximately 100-nm-thick ITSO film was formed over the glass substrate and the conductive layer 182a by a sputtering method and processed, so that the conductive layer 122a covering the top surface and the side surface of the conductive layer 182a was formed (FIG. 19A). In the above-described manner, the conductive layer 112a was formed.

Next, the insulating film 110af (not illustrated), the insulating film 110bf, and the insulating film 110cf were formed in this order over the substrate 102 and the conductive layer 112a (FIG. 19B). Each of the insulating films was formed under a condition with a substrate temperature of 350° C.

As the insulating film 110 af, an approximately 70-nm-thick silicon nitride film was formed by a PECVD method. As the insulating film 110bf, an approximately 100-nm-thick silicon nitride film was formed by a PECVD method. The insulating film 110af was formed under a condition with a higher proportion of the flow rate of a NH₃ gas with respect to the total flow rate of a film formation gas than that for the insulating film 110bf.

As the insulating film 110cf, a silicon oxynitride film having five layers was formed by a PECVD method. First, an approximately 50-nm-thick silicon oxynitride film was formed under a condition with an F ratio of 10; then, an approximately 100-nm-thick silicon oxynitride film was formed under a condition with an F ratio of 6; then, an approximately 200-nm-thick silicon oxynitride film was formed under a condition with an F ratio of 4; then, an approximately 100-nm-thick silicon oxynitride film was formed under a condition with an F ratio of 6; and then, an approximately 50-nm-thick silicon oxynitride film was formed under a condition with an F ratio of 10. That is, the total thickness of the insulating film 110cf is approximately 500 nm.

Next, plasma treatment was performed for 240 seconds in an atmosphere containing a N₂O gas.

Next, over the insulating film 110 cf, an approximately 20-nm-thick In—Ga—Zn oxide film was formed, so that the metal oxide layer 149 was formed (FIG. 19C). The In-Ga-Zn oxide film was formed by a sputtering method using a metal oxide target whose atomic ratio was In:Ga:Zn=1:1:1 with an oxygen flow rate ratio of 100% at a substrate temperature of room temperature. After the formation of the In—Ga—Zn oxide film, heat treatment was performed at 300° C. for one hour. After that, the metal oxide layer 149 was removed by a wet etching method.

Next, the insulating film 110df and the insulating film 110ef (not illustrated) were formed over the insulating film 110cf (FIG. 19D).

As the insulating film 110 df, an approximately 50-nm-thick silicon nitride film was formed by a PECVD method. As the insulating film 110 ef, an approximately 100-nm-thick silicon nitride film was formed by a PECVD method. The insulating film 110ef was formed under a condition with a higher proportion of the flow rate of a NH₃ gas with respect to the total flow rate of a film formation gas than that for the insulating film 110df. Each of the insulating films was formed under a condition with a substrate temperature of 350° C.

Next, for Sample A, an approximately 50-nm-thick copper film was formed over the silicon nitride film (see the conductive film 182f in (FIG. 20A)) and processed to form the conductive layer 182b (FIG. 20B). Next, an approximately 100-nm-thick ITSO film was formed over the silicon nitride film and the conductive layer 182b by a sputtering method (see the conductive film 122f in FIG. 20C) and processed to form the conductive layer 122b covering the top surface and the side surface of the conductive layer 182b (FIG. 21A). Through the above-described steps, the conductive layer 112b was formed. The opening 143 was provided in the conductive layer 112b by a wet etching method.

For Sample B, the conductive layer 112b as illustrated in FIG. 5B was formed. Specifically, an approximately 50-nm-thick ITSO film was used as the conductive layer 184 b, an approximately 50-nm-thick copper film was used as the conductive layer 182b, and an approximately 50-nm-thick ITSO film was used as the conductive layer 122b.

For Sample C, the conductive layer 112b as illustrated in FIG. 5A was formed. Specifically, an approximately 100-nm-thick ITSO film was used as the conductive layer 112b.

Furthermore, the insulating films were processed by a dry etching method to form the insulating layer 110 including the opening 141 (FIG. 21A).

Next, a metal oxide film was formed over the insulating layer 110 and the conductive layer 112b and processed to form the semiconductor layer 108 (FIG. 21B).

As the metal oxide film, an approximately 20-nm-thick In—Ga—Zn oxide film was formed. The In—Ga—Zn oxide film was formed by a sputtering method using a metal oxide target whose atomic ratio was In:Ga:Zn=1:1:1 with an oxygen flow rate ratio of 10% at a substrate temperature of room temperature. After the formation of the In—Ga—Zn oxide film, heat treatment was performed at 350° C. in a CDA atmosphere for one hour.

Next, plasma treatment was performed for 20 seconds in an atmosphere containing a N₂O gas and then, the insulating layer 106 was formed over the insulating layer 110, the conductive layer 112b, and the semiconductor layer 108.

As the insulating layer 106, an approximately 50-nm-thick silicon oxynitride film was formed by a PECVD method. The insulating layer 106 was formed under a condition with an F ratio of 5.

After that, the step of forming the conductive layer 104 and the steps thereafter were performed under conditions similar to those in Example 1, whereby the transistors of this example were fabricated (FIG. 21B).

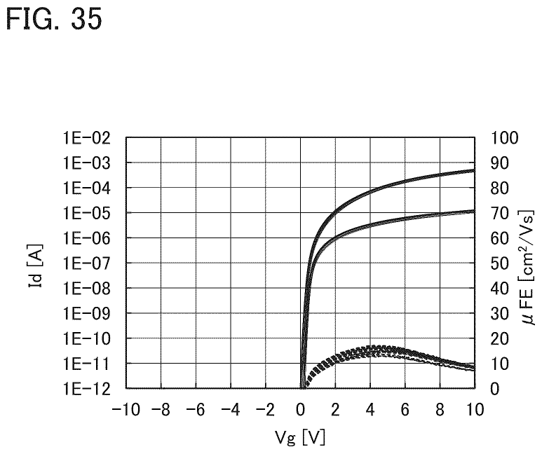

Next, the Id-Vg characteristics of the transistors fabricated in this example were measured. FIG. 35 shows the results of the Id-Vg characteristics of the samples of this example.

FIG. 35 shows the results in the case where the conductive layer 112b served as a source electrode.

In FIG. 35, the vertical axes represent a drain current (Id (A)) and field-effect mobility (μFE (cm²/Vs)) and the horizontal axis represents a gate voltage (Vg (V)). In FIG. 35, the solid lines indicate the results of the Id-Vg characteristics and the dotted lines indicate the field-effect mobility. In FIG. 35, the results of the Id-Vg characteristics and the field-effect mobility of 19 transistors are superimposed.

Each of the transistors fabricated in this example was an n-channel transistor and was fabricated so that its channel length (L) was 0.5 μm and its channel width (W) was 6.3 μm (the opening diameter was 2 μmφ).

The Id-Vg characteristics of the transistors were measured under the following conditions. The voltage applied to the conductive layer 104 (gate voltage (Vg)) was changed from −10 V to+10 V in increments of 0.1 V. The voltage applied to the source electrode (source voltage (Vs)) was 0 V (common), and the voltage applied to the drain electrode (drain voltage (Vd)) was 0.1 V or 5.1V.

It was confirmed that the transistors fabricated in this example had favorable switching characteristics and high on-state currents as shown in FIG. 35.

Next, stress tests were performed on the transistor fabricated in this example.

As the stress tests, gate bias stress tests (GBT tests) were employed. GBT tests are a kind of accelerated test and can measure a change in transistor characteristics due to long-term use, in a short time. Here, as the GBT tests, a substrate over which the transistor was formed was held at 60° C., a voltage of 0 V was applied to a source and a drain of the transistor, and a voltage of 10 V, 15 V, −10 V, or −15 V was applied to a gate; this state was held for 3600 seconds. At this time, a test in which a positive voltage is applied to the gate is referred to as PBTS (Positive Bias Temperature Stress), and a test in which a negative voltage is applied to the gate is referred to as NBTS (Negative Bias Temperature Stress). Moreover, a voltage of 10 V, 15V, −10 V, or −15 V was applied to the gate under light irradiation with a white LED at 5000 lx; this state was held for 3600 seconds. At this time, a test in which a positive voltage is applied to the gate is referred to as PBITS (Positive Bias Illumination Temperature Stress), and a test in which a negative voltage is applied to the gate is referred to as NBITS (Negative Bias Illumination Temperature Stress).

The amount of change in threshold value (ΔVth) in the PBTS test in which 10 V was applied to the gate was 0.09 V, ΔVth in the PBTS test in which 15 V was applied to the gate was 0.14 V, ΔVth in the NBITS test in which −10 V was applied to the gate was −0·29 V, and ΔVth in the NBITS test in which −15 V was applied to the gate was −0.33 V.

In the case where the whole insulating layer 110c is formed under a condition with a low F ratio (e.g., an F ratio of 4), ΔVth of the transistor tends to be large in the PBTS test. Meanwhile, in the case where the whole insulating layer 110c is formed under a condition with a high F ratio (e.g., an F ratio of 6), ΔVth of the transistor tends to be large in the NBITS test.

It was found that the transistor in this example had small ΔVth in both the PBTS test and the NBTIS test and had high reliability.

As described above, in this example, the insulating layer 110c was formed in the following manner: a center portion in the thickness direction was formed under a condition with a low F ratio and a region away from the center portion was formed under a condition with a higher F ratio. Such an insulating layer 110c has a structure that achieves both ease of diffusion of oxygen into the channel formation region of the semiconductor layer 108 and difficulty in diffusion of impurities including hydrogen and impurities including nitrogen into the channel formation region of the semiconductor layer 108, as compared with the insulating layer 110c formed under one condition. It is thus probable that a shift in the threshold voltage was inhibited and high reliability was obtained in the transistor.

### REFERENCE NUMERALS

10A: semiconductor device, 10B: semiconductor device, 10C: semiconductor device, 10D: semiconductor device, 10: semiconductor device, 11B: subpixel, 11G: subpixel, 11R: subpixel, 50A: display device, 50B: display device, 50C: display device, 50D: display device, 50E: display device, 50F: display device, 50G: display device, 100A: transistor, 100B: transistor, 100C: transistor, 100D: transistor, 100E: transistor, 100F: transistor, 100G: transistor, 100: transistor, 102: substrate, 103: conductive layer, 104a: conductive layer, 104: conductive layer, 106: insulating layer, 107a: conductive layer, 107b: conductive layer, 108a: semiconductor layer, 108: semiconductor layer, 110a: insulating layer, 110b: insulating layer, 110bf: insulating film, 110c: insulating layer, 110cf: insulating film, 110d: insulating layer, 110df: insulating film, 110e: insulating layer, 110f: insulating layer, 110f1: insulating layer, 110: insulating layer, 111B: pixel electrode, 111G: pixel electrode, 111R: pixel electrode, 111S: pixel electrode, 112a: conductive layer, 112b: conductive layer, 112c: conductive layer, 113B: EL layer, 113G: EL layer, 113R: EL layer, 113S: functional layer, 113: EL layer, 114: common layer, 115: common electrode, 117: light-blocking layer, 120: conductive layer, 121: insulating layer, 122a: conductive layer, 122b: conductive layer, 122c: conductive layer, 122D: conductive layer, 122f: conductive film, 122S: conductive layer, 123: conductive layer, 124B: conductive layer, 124G: conductive layer, 124R: conductive layer, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 131: protective layer, 132B: coloring layer, 132G: coloring layer, 132R: coloring layer, 133B: layer, 133G: layer, 133R: layer, 133: layer, 140: connection portion, 141: opening, 142: adhesive layer, 143: opening, 149: metal oxide layer, 150: transistor, 151: substrate, 152: substrate, 153: insulating layer, 162: display portion, 164: circuit portion, 165: conductive layer, 166: conductive layer, 172: FPC, 173: IC, 182a: conductive layer, 182b: conductive layer, 182c: conductive layer, 182D: conductive layer, 182f: conductive film, 182S: conductive layer, 184a: conductive layer, 184b: conductive layer, 186a: conductive layer, 186b: conductive layer, 190: capacitor, 195: insulating layer, 200B: transistor, 200: transistor, 201: pixel, 204: connection portion, 205B: transistor, 205D: transistor, 205G: transistor, 205R: transistor, 205S: transistor, 218: insulating layer, 235: insulating layer, 237: insulating layer, 242: connection layer, 250: transistor, 252: insulating layer, 253a: drain region, 253b: channel formation region, 253c: source region, 253: semiconductor layer, 254: insulating layer, 255: conductive layer, 256: insulating layer, 257a: opening, 257b: opening, 258a: conductive layer, 258b: conductive layer, 259: conductive layer, 352: finger, 353: layer, 355: circuit layer, 357: layer, 420: conductive layer, 430: insulating layer, 440D: wiring, 440S: wiring, 460: insulating layer, 470i: region, 470na: region, 470nb: region, 470: oxide semiconductor layer, 480: insulating layer, 490: opening portion, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first conductive layer;
a first insulating layer comprising a first opening over the first conductive layer;
a second conductive layer comprising a second opening overlapping with the first opening over the first insulating layer;
a semiconductor layer over the second conductive layer and in contact with a top surface of the first conductive layer via the first opening and the second opening;
a second insulating layer over the semiconductor layer; and
a third conductive layer overlapping with the semiconductor layer with the second insulating layer therebetween,
wherein the second conductive layer comprises a first conductive film and a second conductive film,
wherein the first conductive film and the second conductive film comprise different metals from each other,
wherein the second conductive film covers at least part of a top surface and a side surface of the first conductive film, and
wherein the semiconductor layer is in contact with a top surface of the second conductive film, a side surface of the second conductive film in the second opening, and a side surface of the first insulating layer in the first opening

2-4. (canceled)

5. The semiconductor device according to claim 1,
wherein the semiconductor layer comprises a metal oxide in a channel formation region, and
wherein the second conductive film comprises a first oxide conductor.

6. The semiconductor device according to claim 1,
wherein conductivity of the first conductive film is higher than conductivity of the second conductive film.

7-11. (canceled)

12. The semiconductor device according to claim 1,
wherein the first insulating layer comprises a first layer comprising nitrogen and silicon over the first conductive layer, a second layer comprising oxygen and silicon over the first layer, and a third layer comprising nitrogen and silicon over the second layer.

13. The semiconductor device according to claim 12,
wherein the first insulating layer comprises a fourth layer between the first conductive layer and the first layer and a fifth layer over the third layer,
wherein the fourth layer comprises a region having a higher hydrogen content than the first layer, and
wherein the fifth layer comprises a region having a higher hydrogen content than the third layer.

14. A semiconductor device comprising:
a first conductive layer;
a first insulating layer comprising a first opening over the first conductive layer;
a second conductive layer comprising a second opening overlapping with the first opening over the first insulating layer;
a semiconductor layer over the second conductive layer and in contact with a top surface of the first conductive layer via the first opening and the second opening;
a second insulating layer over the semiconductor layer; and
a third conductive layer overlapping with the semiconductor layer with the second insulating layer therebetween,
wherein the second conductive layer comprises a first conductive film and a second conductive film,
wherein the first conductive film and the second conductive film comprise different metals from each other,
wherein the second conductive film covers at least part of a top surface and a side surface of the first conductive film,
wherein the first conductive layer comprises a third conductive film and a fourth conductive film,
wherein the third conductive film and the fourth conductive film comprise different metals from each other,
wherein the fourth conductive film covers at least part of a top surface and a side surface of the third conductive film, and
wherein the semiconductor layer is in contact with a top surface of the second conductive film, a top surface of the fourth conductive film, a side surface of the second conductive film in the second opening, and a side surface of the first insulating layer in the first opening.

15. The semiconductor device according to claim 14,
wherein the semiconductor layer comprises a metal oxide in a channel formation region,
wherein the second conductive film comprises a first oxide conductor, and
wherein the fourth conductive film comprises a second oxide conductor.

16. The semiconductor device according to claim 14,
wherein conductivity of the first conductive film is higher than conductivity of the second conductive film, and
wherein conductivity of the third conductive film is higher than conductivity of the fourth conductive film.

17. The semiconductor device according to claim 14,
wherein the first insulating layer comprises a first layer comprising nitrogen and silicon over the first conductive layer, a second layer comprising oxygen and silicon over the first layer, and a third layer comprising nitrogen and silicon over the second layer.

18. The semiconductor device according to claim 17,
wherein the first insulating layer comprises a fourth layer between the first conductive layer and the first layer and a fifth layer over the third layer,
wherein the fourth layer comprises a region having a higher hydrogen content than the first layer, and
wherein the fifth layer comprises a region having a higher hydrogen content than the third layer.
